(19) United States
(12) Patent Application Publication
(10) Pub. No.: US 2023/0337538 A1
(43) Pub. Date: Oct. 19, 2023

(54) ORGANIC MOLECULES FOR OPTOELECTRONIC DEVICES

(71) Applicants: Samsung Display Co., LTD., Yongin-si, Gyeonggi-do (KR); CYNORA GMBH, Bruchsal (DE)

(72) Inventor: Qiang WANG, Weingarten (Baden) (DE)

(21) Appl. No.: 18/042,548

(22) PCT Filed: Aug. 26, 2021
(86) PCT No.: PCT/EP2021/073625

§ 371 Date: Feb. 22, 2023

(30) Foreign Application Priority Data
Aug. 27, 2020 (EP) 20193210.0

(51) Int. Cl. H10K 85/60; C07F 5/02; C09K 11/06

(52) U.S. Cl. CPC H10K 85/658; C07F 5/027; C09K 11/06; H10K 50/11

(57) ABSTRACT

An organic molecule for the use in optoelectronic devices is disclosed. The organic molecule has a structure of formula I. The features of the organic molecule having the structure of formula I are further described in the disclosure. The optoelectronic may be selected from the group consisting of organic light-emitting diodes (OLEDs), light-emitting electrochemical cells, OLED sensors, in gas and vapor sensors not hermetically shielded to the outside, organic diodes, organic solar cells, organic transistors, organic field-effect transistors, organic lasers, and down-conversion elements.

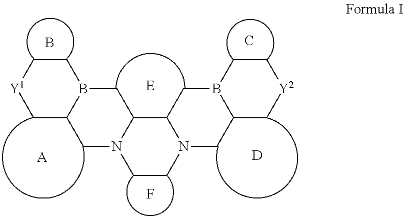

### CROSS-REFERENCE TO RELATED APPLICATIONS

This application is a U.S. National Phase Patent Application of International Patent Application Number PCT/EP2021/073625, filed on Aug. 26, 2021, which claims priority to European Patent Application Number 20193210.0, filed on Aug. 27, 2020, the entire content of all of which is incorporated herein by reference.

Embodiments of the present disclosure to light-emitting organic molecules and their use in organic light-emitting diodes (OLEDs) and in other optoelectronic devices.

### BACKGROUND

### 1. Field

The object of embodiments the present disclosure is to provide molecules which are suitable for use in optoelectronic devices.

This object is achieved by embodiments of the present disclosure which provide a new class of organic molecules.

### 2. Related Art

Optoelectronic devices containing one or more light-emitting layers based on organics such as, e.g., organic light emitting diodes (OLEDs), light emitting electrochemical cells (LECs) and light-emitting transistors have gained increasing importance. OLEDs are promising devices for electronic products such as screens, displays and illumination devices. In contrast to most electroluminescent devices essentially based on inorganics, optoelectronic devices based on organics are often rather flexible and producible in particularly thin layers. The OLED-based screens and displays already available today bear either good efficiencies and long lifetimes or good color purity and long lifetimes, but do not combine all three properties, e.g., good efficiency, long lifetime, and good color purity.

Thus, there is still an unmet technical need for optoelectronic devices which have a high quantum yield, a long lifetime, and good color purity.

The color purity and/or color point of an OLED is generally provided by CIEx and CIEy coordinates, whereas the color gamut for the next display generation is provided by so-called BT-2020 and DCPI3 values. Generally, in order to achieve these color coordinates, top emitting devices are used to adjust the color coordinates by changing the cavity. In order to achieve high efficiency in top emitting devices while targeting this color gamut, a narrow emission spectrum in bottom emitting devices is used.

### SUMMARY

Organic molecules according to embodiments of the present disclosure exhibit emission maxima in the deep blue, sky blue, green or yellow spectral range, in the deep blue, sky blue, and green spectral range, or, for example, in the deep blue or green spectral range. The organic molecules exhibit, for example, emission maxima between 420 and 580 nm, between 440 and 560 nm, between 440 and 480 nm or between 500 and 550 nm, between 440 and 465 nm or, for example, between 520 and 540 nm. In some embodiments, the molecules of embodiments of the present disclosure exhibit, for example, a narrow emission, expressed by a small full width at half maximum (FWHM). The emission spectra of the organic molecules may show a full width at half maximum (FWHM) of less than or equal to 0.30 eV (<; 0.30 eV), unless stated otherwise, measured with 2% by weight of emitter in poly(methyl methacrylate) PMMA at room temperature (e.g., at approximately 20° C.). The photoluminescence quantum yields of the organic molecules according to embodiments of the present disclosure are 10% or more, 30% or more, 50% or more, or, for example, 60% or more.

Use of the molecules according to embodiments of the present disclosure in an optoelectronic device, for example, an organic light-emitting diode (OLED), leads to a narrow emission and high efficiency of the device. Corresponding OLEDs have a higher stability than OLEDs including existing emitter materials and comparable color and/or by employing the molecules according to embodiments of the present disclosure in an OLED display, a more accurate reproduction of visible colors in nature, e.g., a higher resolution in the displayed image, is achieved. In some embodiments, the molecules can be used in combination with an energy pump to achieve hyper-fluorescence or hyper-phosphorescence. In these cases, another species included in an optoelectronic device transfers energy to the organic molecules of embodiments of the present disclosure which then emit light.

### DETAILED DESCRIPTION

Organic molecules of embodiments of the present disclosure include or consist of a structure of formula I:

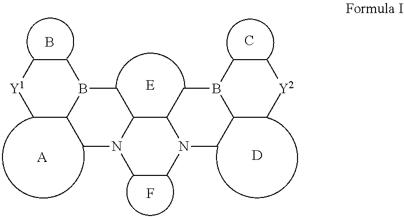

wherein
each of ring A, ring B, ring C, ring D, ring E, and ring F independently of each other represents an aromatic or heteroaromatic ring, each including 5 to 18 ring atoms, of which, in case of a heteroaromatic ring, 1 to 3 ring atoms are heteroatoms independently of each other selected from the group consisting of N, O, S, and Se.

One or more hydrogen atoms in each of the aromatic or heteroaromatic rings A, B, C, D, E, and F are optionally substituted by a substituent R¹, which is at each occurrence independently of each other selected from the group consisting of: hydrogen, deuterium, N(R²)₂, OR², SR², Si(R²)₃, B(OR²)₂, OSO₂R², CF₃, CN, halogen (F, Cl, Br, I),
C₁-C₄₀-alkyl,
which is optionally substituted with one or more substituents R² and
wherein one or more non-adjacent CH₂-groups are optionally substituted by R²C═CR², C≡C, Si(R²)₂, Ge(R²)₂, Sn(R²)₂, C═O, C═S, C═Se, C═NR², P(═O)(R²), SO, SO₂, NR², O, S or CONR²;
C₁-C₄₀-alkoxy,
which is optionally substituted with one or more substituents R² and
wherein one or more non-adjacent CH₂-groups are optionally substituted by R²C═CR², C≡C, Si(R²)₂, Ge(R²)₂, Sn(R²)₂, C═O, C═S, C═Se, C═NR², P(═O)(R²), SO, SO₂, NR², O, S or CONR²;
C₁-C₄₀-thioalkoxy,
which is optionally substituted with one or more substituents R² and
wherein one or more non-adjacent CH₂-groups are optionally substituted by R²C═CR², C≡C, Si(R²)₂, Ge(R²)₂, Sn(R²)₂, C═O, C═S, C═Se, C═NR², P(═O)(R²), SO, SO₂, NR², O, S or CONR²;
C₂-C₄₀-alkenyl,
which is optionally substituted with one or more substituents R² and
wherein one or more non-adjacent CH₂-groups are optionally substituted by R²C═CR², C≡C, Si(R²)₂, Ge(R²)₂, Sn(R²)₂, C═O, C═S, C═Se, C═NR², P(═O)(R²), SO, SO₂, NR², O, S or CONR²;
C₂-C₄₀-alkynyl,
which is optionally substituted with one or more substituents R² and
wherein one or more non-adjacent CH₂-groups are optionally substituted by R²C═CR², C≡C, Si(R²)₂, Ge(R²)₂, Sn(R²)₂, C═O, C═S, C═Se, C═NR², P(═O)(R²), SO, SO₂, NR², O, S or CONR²;
C₆-C₆₀-aryl,
which is optionally substituted with one or more substituents R²;
C₃-C₅₇-heteroaryl,
which is optionally substituted with one or more substituents R²;
and aliphatic, cyclic amines including 4 to 18 carbon atoms and 1 to 3 nitrogen atoms;
wherein two or more adjacent substituents R¹ optionally form an aliphatic or aromatic carbocyclic or heterocyclic ring system which is fused to the adjacent ring A, B, C, D, E or F of formula I and optionally substituted with one or more substituents R² wherein the optionally so formed fused ring system has in total 8 to 30 ring atoms, out of which, in case of a fused heterocyclic ring system, 1 to 5 ring atoms are heteroatoms, independently of each other selected from N, O, S, and Se;
Y¹ and Y² are at each occurrence independently of each other selected from NR³, O, S, and Se.
R³ is at each occurrence independently of each other selected from the group consisting of: hydrogen, deuterium,
C₁-C₄₀-alkyl,
which is optionally substituted with one or more substituents R⁴ and
wherein one or more non-adjacent CH₂-groups are optionally substituted by R⁴C═CR⁴, C≡C, Si(R⁴)₂, Ge(R⁴)₂, Sn(R⁴)₂, C═O, C═S, C═Se, C═NR⁴, P(═O)(R⁴), SO, SO₂, NR⁴, O, S or CONR⁴;
C₁-C₄₀-alkoxyl,
which is optionally substituted with one or more substituents R⁴ and
wherein one or more non-adjacent CH₂-groups are optionally substituted by R⁴C═CR⁴, C≡C, Si(R⁴)₂, Ge(R⁴)₂, Sn(R⁴)₂, C═O, C═S, C═Se, C═NR⁴, P(═O)(R⁴), SO, SO₂, NR⁴, O, S or CONR⁴;
C₁-C₄₀-thioalkoxy,
which is optionally substituted with one or more substituents R⁴ and
wherein one or more non-adjacent CH₂-groups are optionally substituted by R⁴C═CR⁴, C≡C, Si(R⁴)₂, Ge(R⁴)₂, Sn(R⁴)₂, C═O, C═S, C═Se, C═NR⁴, P(═O)(R⁴), SO, SO₂, NR⁴, O, S or CONR⁴;
C₂-C₄₀-alkenyl,
which is optionally substituted with one or more substituents R⁴ and
wherein one or more non-adjacent CH₂-groups are optionally substituted by R⁴C═CR⁴, C≡C, Si(R⁴)₂, Ge(R⁴)₂, Sn(R⁴)₂, C═O, C═S, C═Se, C═NR⁴, P(═O)(R⁴), SO, SO₂, NR⁴, O, S or CONR⁴;
C₂-C₄₀-alkynyl,
which is optionally substituted with one or more substituents R⁴ and
wherein one or more non-adjacent CH₂-groups are optionally substituted by R⁴C═CR⁴, C≡C, Si(R⁴)₂, Ge(R⁴)₂, Sn(R⁴)₂, C═O, C═S, C═Se, C═NR⁴, P(═O)(R⁴), SO, SO₂, NR⁴, O, S or CONR⁴;
C₆-C₁₈-aryl,
which is optionally substituted with one or more substituents R¹; and
C₃-C₁₈-heteroaryl,
which is optionally substituted with one or more substituents R¹.
R² and R⁴ are at each occurrence independently of each other selected from the group consisting of: hydrogen, deuterium, OPh (Ph=phenyl), SPh, CF₃, CN, F, Si(C₁-C₅-alkyl)₃, Si(Ph)₃,
C₁-C₅-alkyl,
wherein optionally one or more hydrogen atoms are independently substituted by deuterium, Ph, CN, CF₃, or F;
C₁-C₅-alkoxy,
wherein optionally one or more hydrogen atoms are independently substituted by deuterium, CN, CF₃, or F;
C₁-C₅-thioalkoxy,
wherein optionally one or more hydrogen atoms are independently substituted by deuterium, CN, CF₃, or F;
C₂-C₅-alkenyl,
wherein optionally one or more hydrogen atoms are independently substituted by deuterium, CN, CF₃, or F;
C₂-C₅-alkynyl,
wherein optionally one or more hydrogen atoms are independently substituted by deuterium, CN, CF₃, or F;
C₆-C₁₈-aryl,
wherein optionally one or more hydrogen atoms are independently substituted by deuterium, CN, CF₃, F, C₁-C₅-alkyl, SiMe₃, SiPh₃ or C₆-C₁₈-aryl substituents;
C₃-C₁₇-heteroaryl,
wherein optionally one or more hydrogen atoms are independently substituted by deuterium, CN, CF₃, F, C₁-C₅-alkyl, SiMe₃, SiPh₃ or C₆-C₁₈-aryl substituents;
N(C₆-C₁₈-aryl)₂,
   N(C₃-C₁₇-heteroaryl)₂; and
   N(C₃-C₁₇-heteroaryl)(C₆-C₁₈-aryl).

In embodiments where one or both of Y¹ and Y² is/are NR³, the one or the two substituents R³ may optionally and independently of each other bond to one or both of the adjacent rings A and B (for Y¹═NR³) or C and D (for Y²═NR³) with the provision that the connecting atom or atom group linking R³ to the respective ring A, B, C, or D is in each case independently selected from selenium (Se) and NR^{Y};
wherein R^{Y} is at each occurrence independently of each other selected from the group consisting of: hydrogen, deuterium,
C₁-C₅-alkyl,
wherein optionally one or more hydrogen atoms are independently substituted by deuterium, Ph, CN, CF₃, or F;
C₆-C₁₈-aryl,
wherein optionally one or more hydrogen atoms are independently substituted by deuterium, C₁-C₅-alkyl, SiMe₃, SiPh₃, CN, CF₃, F or C₆-C₁₈-aryl substituents;
C₃-C₁₇-heteroaryl,
wherein optionally one or more hydrogen atoms are independently substituted by deuterium, C₁-C₅-alkyl, SiMe₃, SiPh₃, CN, CF₃, F or C₆-C₁₈-aryl substituents.

According to embodiments of the present disclosure, at least one ring of A, B, C, D, E, and F is a heteroaromatic ring.

In one embodiment of the present disclosure,
R¹ and R³ are at each occurrence independently of each other selected from the group consisting of: hydrogen, deuterium, Oph, SPh, CF₃, CN, F, Si(C₁-C₅-alkyl)₃, Si(Ph)₃,
C₁-C₅-alkyl,
wherein optionally one or more hydrogen atoms are independently substituted by deuterium, Ph, CN, CF₃, or F;
C₁-C₅-alkoxy,
wherein optionally one or more hydrogen atoms are independently substituted by deuterium, CN, CF₃, or F;
C₁-C₅-thioalkoxy,
wherein optionally one or more hydrogen atoms are independently substituted by deuterium, CN, CF₃, or F;
C₂-C₅-alkenyl,
wherein optionally one or more hydrogen atoms are independently substituted by deuterium, CN, CF₃, or F;
C₂-C₅-alkynyl,
wherein optionally one or more hydrogen atoms are independently substituted by deuterium, CN, CF₃, or F;
C₆-C₁₈-aryl,
wherein optionally one or more hydrogen atoms are independently substituted by deuterium, CN, CF₃, F, C₁-C₅-alkyl, SiMe₃, SiPh₃ or C₆-C₁₈-aryl substituents;
C₃-C₁₇-heteroaryl,
wherein optionally one or more hydrogen atoms are independently substituted by deuterium, CN, CF₃, F, C₁-C₅-alkyl, SiMe₃, SiPh₃ or C₆-C₁₈-aryl substituents;
aliphatic, cyclic amines including 4 to 18 carbon atoms and 1 to 3 nitrogen atoms;
N(C₆-C₁₈-aryl)₂,
   N(C₃-C₁₇-heteroaryl)₂; and
   N(C₃-C₁₇-heteroaryl)(C₆-C₁₈-aryl);
wherein adjacent groups R¹ do not form an additional ring system;
and wherein R^{Y} is at each occurrence independently of each other selected from the group consisting of: hydrogen, deuterium,
C₁-C₅-alkyl,
wherein optionally one or more hydrogen atoms are independently substituted by deuterium, Ph, CN, CF₃, or F;
C₆-C₁-aryl,
wherein optionally one or more hydrogen atoms are independently substituted by deuterium, C₁-C₅-alkyl, SiMe₃, SiPh₃, CN, CF₃, F or C₆-C₁₈-aryl substituents.

In one embodiment of the present disclosure,
R¹ is at each occurrence independently of each other selected from the group consisting of: hydrogen, deuterium, OPh, SPh, CF₃, CN, F, Si(C₁-C₅-alkyl)₃, Si(Ph)₃, pyrrolidinyl, piperidinyl,
C₁-C₅-alkyl,
wherein optionally one or more hydrogen atoms are independently substituted by deuterium, Ph, CN, CF₃, or F;
C₁-C₅-alkoxy,
wherein optionally one or more hydrogen atoms are independently substituted by deuterium, CN, CF₃, or F;
C₁-C₅-thioalkoxy,
wherein optionally one or more hydrogen atoms are independently substituted by deuterium, CN, CF₃, or F;
C₂-C₅-alkenyl,
wherein optionally one or more hydrogen atoms are independently substituted by deuterium, CN, CF₃, or F;
C₂-C₅-alkynyl,
wherein optionally one or more hydrogen atoms are independently substituted by deuterium, CN, CF₃, or F;
C₆-C₁₈-aryl,
wherein optionally one or more hydrogen atoms are independently substituted by deuterium, CN, CF₃, F, C₁-C₅-alkyl, SiMe₃, SiPh₃ or C₆-C₁₈-aryl substituents;
C₃-C₁₇-heteroaryl,
wherein optionally one or more hydrogen atoms are independently substituted by deuterium, CN, CF₃, F, C₁-C₅-alkyl, SiMe₃, SiPh₃ or C₆-C₁₈-aryl substituents;
N(C₆-C₁₈-aryl)₂,
   N(C₃-C₁₇-heteroaryl)₂; and
   N(C₃-C₁₇-heteroaryl)(C₆-C₁₈-aryl);
wherein adjacent groups R¹ do not form an additional ring system;
wherein Y¹ and Y² are both NR³
wherein R³ is at each occurrence independently of each other selected from the group consisting of: hydrogen, deuterium,
C₁-C₅-alkyl,
wherein optionally one or more hydrogen atoms are independently substituted by deuterium, Ph, CN, CF₃, or F;
C₆-C₁₈-aryl,
wherein optionally one or more hydrogen atoms are independently substituted by deuterium, CN, CF₃, F, C₁-C₅-alkyl, SiMe₃, SiPh₃ or C₆-C₁₈-aryl substituents;
C₃-C₁₇-heteroaryl,
wherein optionally one or more hydrogen atoms are independently substituted by deuterium, CN, CF₃, F, C₁-C₅-alkyl, SiMe₃, SiPh₃ or C₆-C₁₈-aryl substituents;
and wherein R^{Y} is at each occurrence independently of each other selected from the group consisting of: hydrogen, deuterium, Me, benzyl, ⁱPr, ^{t}Bu, and
Ph, which is optionally substituted with one or more substituents independently of each other selected from deuterium, CN, CF₃, F, C₁-C₅-alkyl, SiMe₃, SiPh₃, and Ph.

In one embodiment of the present disclosure,
R¹ is at each occurrence independently of each other selected from the group consisting of: hydrogen, deuterium, OPh, SPh, CF₃, CN, F, Si(C₁-C₅-alkyl)₃, Si(Ph)₃, pyrrolidinyl, piperidinyl,
C₁-C₅-alkyl,
wherein optionally one or more hydrogen atoms are independently substituted by deuterium, Ph, CN, CF₃, or F;
C₆-C₁₈-aryl,
wherein optionally one or more hydrogen atoms are independently substituted by deuterium, CN, CF₃, F, C₁-C₅-alkyl, SiMe₃, SiPh₃ or C₆-C₁₈-aryl substituents;
C₃-C₁₇-heteroaryl,
wherein optionally one or more hydrogen atoms are independently substituted by deuterium, CN, CF₃, F, C₁-C₅-alkyl, SiMe₃, SiPh₃ or C₆-C₁₈-aryl substituents;
N(C₆-C₁₈-aryl)₂,
   N(C₃-C₁₇-heteroaryl)₂; and
   N(C₃-C₁₇-heteroaryl)(C₆-C₁₈-aryl);
wherein adjacent groups R¹ do not form an additional ring system;
wherein Y¹ and Y² are both NR³
wherein R³ is at each occurrence independently of each other selected from the group consisting of: hydrogen, deuterium,
C₁-C₅-alkyl,
wherein optionally one or more hydrogen atoms are independently substituted by deuterium, Ph, CN, CF₃, or F;
C₆-C₁₈-aryl,
wherein optionally one or more hydrogen atoms are independently substituted by deuterium, CN, CF₃, F, C₁-C₅-alkyl, SiMe₃, SiPh₃ or C₆-C₁₈-aryl substituents;
and wherein R^{Y} is at each occurrence independently of each other selected from the group consisting of: hydrogen, deuterium, Me, benzyl, ⁱPr, ^{t}Bu, and
Ph, which is optionally substituted with one or more substituents independently of each other selected from deuterium, CN, CF₃, F, C₁-C₅-alkyl, SiMe₃, SiPh₃, and Ph.

In an embodiment of the present disclosure,
R¹ is at each occurrence independently of each other selected from the group consisting of: hydrogen, deuterium, Me, benzyl, ⁱPr, ^{t}Bu, CN, CF₃, SiMe₃, SiPh₃, N(Ph)₂, pyrrolidinyl, piperidinyl,
Ph, which is optionally substituted with one or more substituents independently selected from the group consisting of deuterium, Me, ⁱPr, ^{t}Bu, CN, CF₃, and Ph;
carbazolyl, which is optionally substituted with one or more substituents independently selected from the group consisting of deuterium, Me, ⁱPr, ^{t}Bu, CN, CF₃, and Ph;
wherein adjacent groups R¹ do not form an additional ring system;
Y¹ and Y² are both NR³
R³ is at each occurrence independently of each other selected from the group consisting of: hydrogen, deuterium, Me, ⁱPr, ^{t}Bu,
C₆-C₁₈-aryl,
wherein optionally one or more hydrogen atoms are independently substituted by deuterium, CN, CF₃, F, C₁-C₅-alkyl, SiMe₃, SiPh₃ or Ph;
and R^{Y} is at each occurrence independently of each other selected from the group consisting of hydrogen, deuterium, Me, benzyl, ⁱPr, ^{t}Bu, and
Ph, which is optionally substituted with one or more substituents independently of each other selected from deuterium, CN, CF₃, Me, ⁱPr, ^{t}Bu, and Ph.

In an embodiment of the present disclosure,
R¹ is at each occurrence independently of each other selected from the group consisting of: hydrogen, deuterium, Me, benzyl, ⁱPr, ^{t}Bu, CN, CF₃, SiMe₃, SiPh₃, N(Ph)₂,
Ph, which is optionally substituted with one or more substituents independently selected from the group consisting of deuterium, Me, ⁱPr, ^{t}Bu, CN, CF₃, and Ph; and
carbazolyl, which is optionally substituted with one or more substituents independently selected from the group consisting of deuterium, Me, ⁱPr, ^{t}Bu, CN, CF₃, and Ph;
wherein adjacent groups R¹ do not form an additional ring system;
wherein Y¹ and Y² are both NR³
wherein R³ is at each occurrence independently of each other selected from the group consisting of: hydrogen, deuterium, Me, benzyl, ⁱPr, ^{t}Bu, and
Ph, which is optionally substituted with one or more substituents independently selected from the group consisting of deuterium, Me, ⁱPr, ^{t}Bu, CN, CF₃, and Ph;
and wherein R^{Y} is at each occurrence independently of each other selected from the group consisting of hydrogen, deuterium, Me, benzyl, ⁱPr, ^{t}Bu, and
Ph, which is optionally substituted with one or more substituents independently of each other selected from deuterium, CN, CF₃, Me, ⁱPr, ^{t}Bu, and Ph.

In an embodiment of the present disclosure,
R¹ is at each occurrence independently of each other selected from the group consisting of: hydrogen, deuterium, Me, benzyl, ⁱPr, ^{t}Bu, CN, CF₃, N(Ph)₂,

Ph, which is optionally substituted with one or more substituents independently selected from the group consisting of deuterium, Me, ⁱPr, ^{t}Bu, CN, CF₃, and Ph; and
carbazolyl, which is optionally substituted with one or more substituents independently selected from the group consisting of deuterium and Ph;
wherein adjacent groups R¹ do not form an additional ring system;
wherein Y¹ and Y² are both NR³
wherein R³ is at each occurrence independently of each other selected from the group consisting of: hydrogen, deuterium, Me, benzyl, ⁱPr, ^{t}Bu, and
Ph, which is optionally substituted with one or more substituents independently selected from the group consisting of deuterium, Me, ⁱPr, ^{t}Bu, CN, CF₃, and Ph;
and wherein R^{Y} is at each occurrence independently of each other selected from the group consisting of hydrogen, deuterium, Me, benzyl, ⁱPr, ^{t}Bu, and
Ph, which is optionally substituted with one or more substituents independently of each other selected from deuterium, CN, CF₃, Me, ⁱPr, ^{t}Bu, and Ph.

In one embodiment of the present disclosure, more than one ring of A, B, C, D, E, and F is a heteroaromatic ring.

In an embodiment of the present disclosure, exactly one ring of A, B, C, D, E, and F is a heteroaromatic ring.

In one embodiment of the present disclosure, ring A is a heteroaromatic ring, while rings B, C, D, E, and F are aromatic rings that do not include a heteroatom in their core structure.

In one embodiment of the present disclosure, ring B is a heteroaromatic ring, while rings A, C, D, E, and F are aromatic rings that do not include a heteroatom in their core structure.

In one embodiment of the present disclosure, ring C is a heteroaromatic ring, while rings A, B, D, E, and F are aromatic rings that do not include a heteroatom in their core structure.

In one embodiment of the present disclosure, ring D is a heteroaromatic ring, while rings A, B, C, E, and F are aromatic rings that do not include a heteroatom in their core structure.

In an embodiment of the present disclosure, ring E is a heteroaromatic ring, while rings A, B, C, D, and F are aromatic rings that do not include a heteroatom in their core structure.

In an embodiment of the present disclosure, ring F is a heteroaromatic ring, while rings A, B, C, D, and E are aromatic rings that do not include a heteroatom in their core structure.

In an embodiment of the present disclosure, ring E is a five-membered heteroaromatic ring including exactly one heteroatom selected from O, S, and Se (in other words: E includes or consists of a furan, thiophene or selenophene core), while rings A, B, C, D, and F in formula I are aromatic rings, each including up to 18 carbon atoms.

In an embodiment of the present disclosure, ring F is a five-membered heteroaromatic ring including exactly one heteroatom selected from O, S, and Se (in other words: F includes or consists of a furan, thiophene or selenophene core), while rings A, B, C, D, and E in formula I are aromatic rings, each including up to 18 carbon atoms.

In one embodiment of the present disclosure, Y¹ and Y² are both oxygen (O).

In one embodiment of the present disclosure, Y¹ and Y² are both sulfur (S).

In one embodiment of the present disclosure, Y¹ and Y² are both selenium (Se).

In an embodiment of the present disclosure, Y¹ and Y² are both NR³.

In one embodiment of the present disclosure, at least one selected from Y¹ and Y² is NR³, wherein at least one substituent R³ bonds to one or both of the adjacent rings A and B (for Y¹═NR³) or C and D (for Y²═NR³) with the provision that the connecting atom or atom group linking R³ to the respective ring A, B, C, or D is in each case independently selected from selenium (Se) and NR^{Y}.

In one embodiment of the present disclosure, Y¹ and Y² are both NR³, wherein both substituents R³ bond to one or both of the adjacent rings A and B (for Y¹ ═NR³) or C and D (for Y²═NR³) with the provision that the connecting atom or atom group linking R³ to the respective ring A, B, C, or D is in each case independently selected from selenium (Se) and NR^{Y}.

In one embodiment of the present disclosure, the organic molecules include or consist of a structure of formula II or formula III:

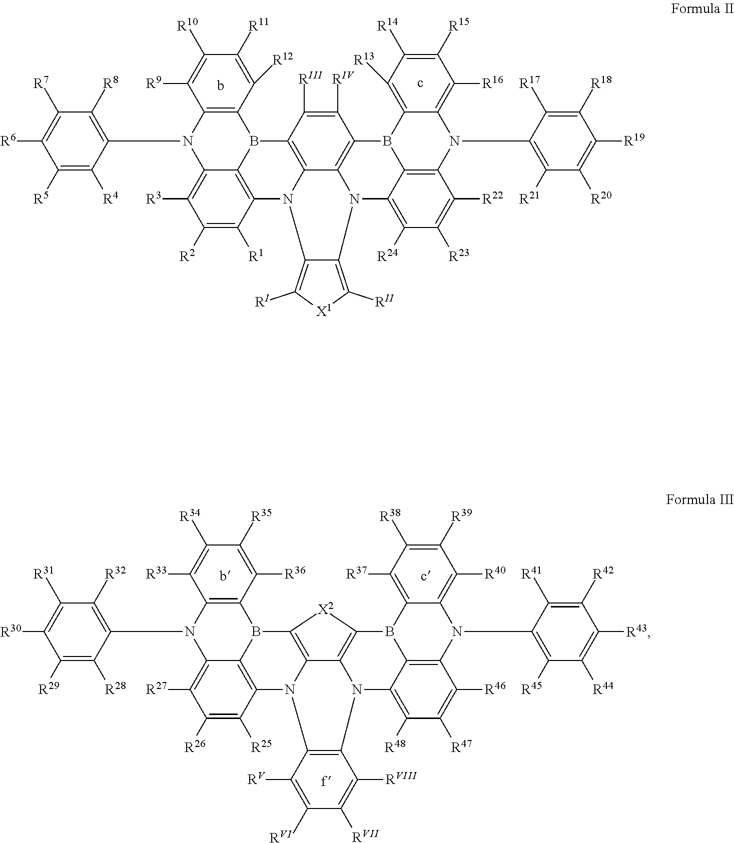

wherein
X¹ and X² are selected from the group consisting of 0, S, and Se,
R^{I}-R^{VIII} and R¹-R⁴⁸ are independently of each other selected from the group consisting of: hydrogen, deuterium, N(R⁴⁹)₂, OR⁴⁹, SR⁴⁹, Si(R⁴⁹)₃, B(OR⁴⁹)₂, OSO₂R⁴⁹, CF₃, CN, halogen (F, Cl, Br, I),
C₁-C₄₀-alkyl,
which is optionally substituted with one or more substituents R⁴⁹ and
wherein one or more non-adjacent CH₂-groups are optionally substituted by R⁴⁹C═CR⁴⁹, C≡C, Si(R⁴⁹)₂, Ge(R⁴⁹)₂, Sn(R⁴⁹)₂, C═O, C═S, C═Se, C═NR⁴⁹, P(═O)(R⁴⁹), SO, SO₂, NR⁴⁹, O, S or CONR⁴⁹;
C₁-C₄₀-alkoxy,
which is optionally substituted with one or more substituents R⁴⁹ and
wherein one or more non-adjacent CH₂-groups are optionally substituted by R⁴⁹C═CR⁴⁹, C≡C, Si(R⁴⁹)₂, Ge(R⁴⁹)₂, Sn(R⁴⁹)₂, C═O, C═S, C═Se, C═NR⁴⁹, P(═O)(R⁴⁹), SO, SO₂, NR⁴⁹, O, S or CONR⁴⁹;
C₁-C₄₀-thioalkoxy,
which is optionally substituted with one or more substituents R⁴⁹ and
wherein one or more non-adjacent CH₂-groups are optionally substituted by R⁴⁹C═CR⁴⁹, C≡C, Si(R⁴⁹)₂, Ge(R⁴⁹)₂, Sn(R⁴⁹)₂, C═O, C═S, C═Se, C═NR⁴⁹, P(═O)(R⁴⁹), SO, SO₂, NR⁴⁹, O, S or CONR⁴⁹;
C₂-C₄₀-alkenyl,
which is optionally substituted with one or more substituents R⁴⁹ and
wherein one or more non-adjacent CH₂-groups are optionally substituted by R⁴⁹C═CR⁴⁹, C≡C, Si(R⁴⁹)₂, Ge(R⁴⁹)₂, Sn(R⁴⁹)₂, C═O, C═S, C═Se, C═NR⁴⁹, P(═O)(R⁴⁹), SO, SO₂, NR⁴⁹, O, S or CONR⁴⁹;
C₂-C₄₀-alkynyl,
which is optionally substituted with one or more substituents R⁴⁹ and
wherein one or more non-adjacent CH₂-groups are optionally substituted by R⁴⁹C═CR⁴⁹, C≡C, Si(R⁴⁹)₂, Ge(R⁴⁹)₂, Sn(R⁴⁹)₂, C═O, C═S, C═Se, C═NR⁴⁹, P(═O)(R⁴⁹), SO, SO₂, NR⁴⁹, O, S or CONR⁴⁹;
C₆-C₆₀-aryl,
which is optionally substituted with one or more substituents R⁴⁹; and
C₃-C₅₇-heteroaryl,
which is optionally substituted with one or more substituents R⁴⁹;
and aliphatic, cyclic amines including 4 to 18 carbon atoms and 1 to 3 nitrogen atoms;
wherein one or both pairs of adjacent substituents R¹⁰ and R¹¹ as well as R¹⁴ and R¹⁵ in formula II optionally form an aromatic or heteroaromatic ring system, which is fused to the adjacent benzene ring b or c of formula II and optionally substituted with one or more substituents R⁴⁹; wherein the optionally so formed fused ring system has in total 8 to 24 ring atoms, out of which, in case of a fused heterocyclic ring system, 1 to 3 ring atoms are heteroatoms, independently of each other selected from N, O, S, and Se;
wherein one or both pairs of adjacent substituents R³⁴ and R³⁵ as well as R³⁸ and R³⁹ in formula III optionally form an aromatic or heteroaromatic ring system, which is fused to the adjacent benzene ring b′ or c′ of formula III and optionally substituted with one or more substituents R⁴⁹; wherein the optionally so formed fused ring system has in total 8 to 24 ring atoms, out of which, in case of a fused heterocyclic ring system, 1 to 3 ring atoms are heteroatoms, independently of each other selected from N, O, S, and Se;
wherein one or more pair of adjacent substituents R^{V} and R^{VI}, R^{VI} and R^{VII} as well as R^{VII} and R^{VIII} in formula III optionally form an aromatic ring system, which is fused to the adjacent benzene ring f′ of formula III and optionally substituted with one or more substituents R⁴⁹; wherein the optionally so formed fused ring system has in total 8 to 24 ring atoms;
R⁴⁹ is at each occurrence independently of each other selected from the group consisting of: hydrogen, deuterium, OPh, SPh, CF₃, CN, F, Si(C₁-C₅-alkyl)₃, Si(Ph)₃,
C₁-C₅-alkyl,
wherein optionally one or more hydrogen atoms are independently substituted by deuterium, Ph, CN, CF₃, or F;
C₁-C₅-alkoxy,
wherein optionally one or more hydrogen atoms are independently substituted by deuterium, CN, CF₃, or F;
C₁-C₅-thioalkoxy,
wherein optionally one or more hydrogen atoms are independently substituted by deuterium, CN, CF₃, or F;
C₂-C₅-alkenyl,
wherein optionally one or more hydrogen atoms are independently substituted by deuterium, CN, CF₃, or F;
C₂-C₅-alkynyl,
wherein optionally one or more hydrogen atoms are independently substituted by deuterium, CN, CF₃, or F;
C₆-C₁₈-aryl,
wherein optionally one or more hydrogen atoms are independently substituted by deuterium, CN, CF₃, F, C₁-C₅-alkyl, SiMe₃, SiPh₃ or C₆-C₁₈-aryl substituents;
C₃-C₁₇-heteroaryl,
wherein optionally one or more hydrogen atoms are independently substituted by deuterium, CN, CF₃, F, C₁-C₅-alkyl, SiMe₃, SiPh₃ or C₆-C₁₈-aryl substituents;
N(C₆-C₁₈-aryl)₂,
   N(C₃-C₁₇-heteroaryl)₂; and
   N(C₃-C₁₇-heteroaryl)(C₆-C₁₈-aryl);
wherein in formula II, one or more pair selected from R³ and R⁴, R⁸ and R⁹, R¹⁶ and R¹⁷, R²¹ and R²² optionally form a group Z¹, which is at each occurrence independently of each other selected from selenium (Se) and NR^{X};
wherein in formula III, one or more pair selected from R²⁷ and R²⁸, R³² and R³³, R⁴⁰ and R⁴¹, R⁴⁵ and R⁴⁶ optionally form a group Z², which is at each occurrence independently of each other selected from selenium (Se) and NR^{X};
wherein R^{X} is at each occurrence independently of each other selected from the group consisting of: hydrogen, deuterium,
C₁-C₅-alkyl,
wherein optionally one or more hydrogen atoms are independently substituted by deuterium, Ph, CN, CF₃, or F;
C₆-C₁₈-aryl,
wherein optionally one or more hydrogen atoms are independently substituted by deuterium, CN, CF₃, F, C₁-C₅-alkyl, SiMe₃, SiPh₃ or C₆-C₁₈-aryl substituents;
C₃-C₁₇-heteroaryl,
wherein optionally one or more hydrogen atoms are independently substituted by deuterium, CN, CF₃, F, C₁-C₅-alkyl, SiMe₃, SiPh₃ or C₆-C₁₈-aryl substituents.

In one embodiment of the present disclosure,
R^{I}-R^{VIII} and R¹-R⁴⁸ are independently of each other selected from the group consisting of: hydrogen, deuterium, Oph, SPh, CF₃, CN, F, Si(C₁-C₅-alkyl)₃, Si(Ph)₃, pyrrolidinyl, piperidinyl,
C₁-C₅-alkyl,
wherein optionally one or more hydrogen atoms are independently substituted by deuterium, Ph, CN, CF₃, or F;
C₁-C₅-alkoxy,
wherein optionally one or more hydrogen atoms are independently substituted by deuterium, CN, CF₃, or F;
C₁-C₅-thioalkoxy,
wherein optionally one or more hydrogen atoms are independently substituted by deuterium, CN, CF₃, or F;
C₂-C₅-alkenyl,
wherein optionally one or more hydrogen atoms are independently substituted by deuterium, CN, CF₃, or F;
C₂-C₅-alkynyl,
wherein optionally one or more hydrogen atoms are independently substituted by deuterium, CN, CF₃, or F;
C₆-C₁₈-aryl,
wherein optionally one or more hydrogen atoms are independently substituted by deuterium, CN, CF₃, F, C₁-C₅-alkyl, SiMe₃, SiPh₃ or C₆-C₁₈-aryl substituents;
C₃-C₁₇-heteroaryl,
wherein optionally one or more hydrogen atoms are independently substituted by deuterium, CN, CF₃, F, C₁-C₅-alkyl, SiMe₃, SiPh₃ or C₆-C₁₈-aryl substituents;
N(C₆-C₁₈-aryl)₂,
   N(C₃-C₁₇-heteroaryl)₂; and
   N(C₃-C₁₇-heteroaryl)(C₆-C₁₈-aryl);
wherein one or both pairs of adjacent substituents R¹⁰ and R¹¹ as well as R¹⁴ and R¹⁵ in formula II optionally form an aromatic or heteroaromatic ring system, which is fused to the adjacent benzene ring b or c of formula II and optionally substituted with one or more substituents independently selected from: hydrogen, deuterium, Me, ⁱPr, ^{t}Bu, CN, CF₃, and
Ph, wherein optionally one or more hydrogen atoms are independently substituted by deuterium, Me, ⁱPr, ^{t}Bu, CN, CF₃, and Ph;
wherein the optionally so formed fused ring system has in total 8 to 24 ring atoms, out of which, in case of a fused heterocyclic ring system, 1 to 3 ring atoms are heteroatoms, independently of each other selected from N, O, S, and Se;
wherein one or both pairs of adjacent substituents R³⁴ and R³⁵ as well as R³⁸ and R³⁹ in formula III optionally form an aromatic or heteroaromatic ring system, which is fused to the adjacent benzene ring b′ or c′ of formula III and optionally substituted with one or more substituents independently selected from: hydrogen, deuterium, Me, ⁱPr, ^{t}Bu, CN, CF₃, and
Ph, wherein optionally one or more hydrogen atoms are independently substituted by deuterium, Me, ⁱPr, ^{t}Bu, CN, CF₃, and Ph;
wherein the optionally so formed fused ring system has in total 8 to 24 ring atoms, out of which, in case of a fused heterocyclic ring system, 1 to 3 ring atoms are heteroatoms, independently of each other selected from N, O, S, and Se;
wherein one or more pair of adjacent substituents R^{V} and R^{VI}, R^{VI} and R^{VII} as well as R^{VII} and R^{VIII} in formula III optionally form an aromatic ring system, which is fused to the adjacent benzene ring f′ of formula III and optionally substituted with one or more substituents independently selected from: hydrogen, deuterium, Me, ⁱPr, ^{t}Bu, CN, CF₃, and
Ph, wherein optionally one or more hydrogen atoms are independently substituted by deuterium, Me, ⁱPr, ^{t}Bu, CN, CF₃, and Ph;
wherein the optionally so formed fused ring system has in total 8 to 24 ring atoms;
wherein in formula II, one or more pair selected from R³ and R⁴, R⁸ and R⁹, R¹⁶ and R¹⁷, R²¹ and R²² optionally form a group Z¹, which is at each occurrence independently of each other selected from selenium (Se) and NR^{X};
wherein in formula III, one or more pair selected from R²⁷ and R²⁸, R³² and R³³, R⁴⁰ and R⁴¹, R⁴⁵ and R⁴⁶ optionally form a group Z², which is at each occurrence independently of each other selected from selenium (Se) and NR^{X};
wherein R^{X} is at each occurrence independently of each other selected from the group consisting of: hydrogen, deuterium,
C₁-C₅-alkyl,
wherein optionally one or more hydrogen atoms are independently substituted by deuterium, Ph, CN, CF₃, or F;
C₆-C₁₈-aryl,
wherein optionally one or more hydrogen atoms are independently substituted by deuterium, CN, CF₃, F, C₁-C₅-alkyl, SiMe₃, SiPh₃ or C₆-C₁₈-aryl substituents.

In one embodiment of the present disclosure,
R^{I} and R^{II} are independently of each other selected from the group consisting of: Me, ⁱPr, ^{t}Bu, CN, CF₃, SiMe₃, SiPh₃, and
Ph, wherein optionally one or more hydrogen atoms are independently substituted by deuterium, Me, ⁱPr, ^{t}Bu, CN, or CF₃;
R^{III}-R^{VIII} and R¹-R⁴⁸ are independently of each other selected from the group consisting of: hydrogen, deuterium, CF₃, CN, F, Si(C₁-C₅-alkyl)₃, Si(Ph)₃, pyrrolidinyl, piperidinyl,
C₁-C₅-alkyl,
wherein optionally one or more hydrogen atoms are independently substituted by deuterium, Ph, CN, CF₃, or F;
C₆-C₁₈-aryl,
wherein optionally one or more hydrogen atoms are independently substituted by deuterium, CN, CF₃, F, C₁-C₅-alkyl, SiMe₃, SiPh₃ or C₆-C₁₈-aryl substituents;
C₃-C₁₇-heteroaryl,
wherein optionally one or more hydrogen atoms are independently substituted by deuterium, CN, CF₃, F, C₁-C₅-alkyl, SiMe₃, SiPh₃ or C₆-C₁₈-aryl substituents;
N(C₆-C₁₈-aryl)₂, N(C₃-C₁₇-heteroaryl)₂; and N(C₃-C₁₇-heteroaryl)(C₆-C₁₈-aryl);
wherein one or both pairs of adjacent substituents R¹⁰ and R¹¹ as well as R¹⁴ and R¹⁵ in formula II optionally form an aromatic or heteroaromatic ring system, which is fused to the adjacent benzene ring b or c of formula II and optionally substituted with one or more substituents independently selected from: hydrogen, deuterium, Me, ⁱPr, ^{t}Bu, CN, CF₃, and
Ph, wherein optionally one or more hydrogen atoms are independently substituted by deuterium, Me, ⁱPr, ^{t}Bu, CN, CF₃, and Ph;
wherein the optionally so formed fused ring system has in total 8 to 24 ring atoms, out of which, in case of a fused heterocyclic ring system, 1 to 3 ring atoms are heteroatoms, independently of each other selected from N, O, S, and Se;
wherein one or both pairs of adjacent substituents R³⁴ and R³⁵ as well as R³⁸ and R³⁹ in formula III optionally form an aromatic or heteroaromatic ring system, which is fused to the adjacent benzene ring b′ or c′ of formula III and optionally substituted with one or more substituents independently selected from: hydrogen, deuterium, Me, ⁱPr, ^{t}Bu, CN, CF₃, and
Ph, wherein optionally one or more hydrogen atoms are independently substituted by deuterium, Me, ⁱPr, ^{t}Bu, CN, CF₃, and Ph;
wherein the optionally so formed fused ring system has in total 8 to 24 ring atoms, out of which, in case of a fused heterocyclic ring system, 1 to 3 ring atoms are heteroatoms, independently of each other selected from N, O, S, and Se;
wherein one or more pair of adjacent substituents R^{V} and R^{VI}, R^{VI} and R^{VII} as well as R^{VII} and R^{VIII} in formula III optionally form an aromatic ring system, which is fused to the adjacent benzene ring f′ of formula III and optionally substituted with one or more substituents independently selected from: hydrogen, deuterium, Me, ⁱPr, ^{t}Bu, CN, CF₃, and
Ph, wherein optionally one or more hydrogen atoms are independently substituted by deuterium, Me, ⁱPr, ^{t}Bu, CN, CF₃, and Ph;
wherein the optionally so formed fused ring system has in total 8 to 24 ring atoms;
wherein in formula II, one or more pair selected from R³ and R⁴, R⁸ and R⁹, R¹⁶ and R¹⁷, R²¹ and R²² optionally form a group Z¹, which is at each occurrence independently of each other selected from selenium (Se) and NR^{X};
wherein in formula III, one or more pair selected from R²⁷ and R²⁸, R³² and R³³, R⁴⁰ and R⁴¹, R⁴⁵ and R⁴⁶ optionally form a group Z², which is at each occurrence independently of each other selected from selenium (Se) and NR^{X};
wherein R^{X} is at each occurrence independently of each other selected from the group consisting of: hydrogen, deuterium,
C₁-C₅-alkyl,
wherein optionally one or more hydrogen atoms are independently substituted by deuterium, Ph, CN, CF₃, or F;
C₆-C₁₈-aryl,
wherein optionally one or more hydrogen atoms are independently substituted by deuterium, CN, CF₃, F, C₁-C₅-alkyl, SiMe₃, SiPh₃ or C₆-C₁₈-aryl substituents.

In one embodiment of the present disclosure,
R^{I} and R^{II} are independently of each other selected from the group consisting of: Me, ⁱPr, ^{t}Bu, CN, CF₃, and
Ph, wherein optionally one or more hydrogen atoms are independently substituted by deuterium, Me, ⁱPr, ^{t}Bu, CN, or CF₃;
R^{III}-R^{VIII} and R¹-R⁴⁸ are independently of each other selected from the group consisting of: hydrogen, deuterium, Me, benzyl, ⁱPr, ^{t}Bu, CF₃, CN, F, SiMe₃, Si(Ph)₃, pyrrolidinyl, piperidinyl,
C₆-C₁-aryl,
wherein optionally one or more hydrogen atoms are independently substituted by deuterium, CN, CF₃, F, C₁-C₅-alkyl, SiMe₃, SiPh₃ or C₆-C₁₈-aryl substituents,
carbazolyl,
wherein optionally one or more hydrogen atoms are independently substituted by deuterium, CN, CF₃, F, C₁-C₅-alkyl, SiMe₃, SiPh₃ or C₆-C₁₈-aryl substituents;
N(C₆-C₁₈-aryl)₂, N(C₃-C₁₇-heteroaryl)₂; and N(C₃-C₁₇-heteroaryl)(C₆-C₁₈-aryl);
wherein one or both pairs of adjacent substituents R¹⁰ and R¹¹ as well as R¹⁴ and R¹⁵ in formula II optionally form an aromatic ring system, which is fused to the adjacent benzene ring b or c of formula II and optionally substituted with one or more substituents independently selected from: hydrogen, deuterium, Me, ⁱPr, ^{t}Bu, CN, CF₃, and
Ph, wherein optionally one or more hydrogen atoms are independently substituted by deuterium, Me, ⁱPr, ^{t}Bu, CN, CF₃, and Ph;
wherein the optionally so formed fused ring system has in total 8 to 24 ring atoms;
wherein one or both pairs of adjacent substituents R³⁴ and R³⁵ as well as R³⁸ and R³⁹ in formula III optionally form an aromatic system, which is fused to the adjacent benzene ring b′ or c′ of formula III and optionally substituted with one or more substituents independently selected from: hydrogen, deuterium, Me, ⁱPr, ^{t}Bu, CN, CF₃, and
Ph, wherein optionally one or more hydrogen atoms are independently substituted by deuterium, Me, ⁱPr, ^{t}Bu, CN, CF₃, and Ph;
wherein the optionally so formed fused ring system has in total 8 to 24 ring atoms;
wherein one or more pair of adjacent substituents R^{V} and R^{VI}, R^{VI} and R^{VII} as well as R^{VII} and R^{VIII} in formula III optionally form an aromatic ring system, which is fused to the adjacent benzene ring f′ of formula III and optionally substituted with one or more substituents independently selected from: hydrogen, deuterium, Me, ⁱPr, ^{t}Bu, CN, CF₃, and
Ph, wherein optionally one or more hydrogen atoms are independently substituted by deuterium, Me, ⁱPr, ^{t}Bu, CN, CF₃, and Ph;
wherein the optionally so formed fused ring system has in total 8 to 24 ring atoms;
wherein in formula II, one or more pair selected from R³ and R⁴, R⁸ and R⁹, R¹⁶ and R¹⁷, R²¹ and R²² optionally form a group Z¹, which is at each occurrence independently of each other selected from selenium (Se) and NR^{X};
wherein in formula III, one or more pair selected from R²⁷ and R²⁸, R³² and R³³, R⁴⁰ and R⁴¹, R⁴⁵ and R⁴⁶ optionally form a group Z², which is at each occurrence independently of each other selected from selenium (Se) and NR^{X};
wherein R^{X} is at each occurrence independently of each other selected from the group consisting of: hydrogen, deuterium, Me, benzyl, ⁱPr, ^{t}Bu, and
Ph, wherein optionally one or more hydrogen atoms are independently substituted by deuterium, CN, CF₃, F, Me, ⁱPr, ^{t}Bu, SiMe₃, SiPh₃ or Ph substituents.

In an embodiment of the present disclosure,
R^{I} and R^{II} are independently of each other selected from the group consisting of: Me, ⁱPr, ^{t}Bu, CN, CF₃, and
Ph, wherein optionally one or more hydrogen atoms are independently substituted by deuterium, Me, ⁱPr, ^{t}Bu, CN, or CF₃;
R^{III}-R^{VIII} and R¹-R⁴⁸ are independently of each other selected from the group consisting of: hydrogen, deuterium, Me, benzyl, ⁱPr, ^{t}Bu, CF₃, CN, F, SiMe₃, Si(Ph)₃, N(Ph)₂, pyrrolidinyl, piperidinyl,
Ph, wherein optionally one or more hydrogen atoms are independently substituted by deuterium, CN, CF₃, Me, ⁱPr, ^{t}Bu or Ph substituents;
carbazolyl, wherein optionally one or more hydrogen atoms are independently substituted by deuterium, CN, CF₃, Me, ⁱPr, ^{t}Bu, or Ph substituents;
wherein one or both pairs of adjacent substituents R¹⁰ and R¹¹ as well as R¹⁴ and R¹⁵ in formula II optionally form an aromatic ring system, which is fused to the adjacent benzene ring b or c of formula II and optionally substituted with one or more substituents independently selected from: hydrogen, deuterium, Me, ⁱPr, ^{t}Bu, CN, CF₃, and Ph; wherein the optionally so formed fused ring system has in total 8 to 24 ring atoms;
wherein one or both pairs of adjacent substituents R³⁴ and R³⁵ as well as R³⁸ and R³⁹ in formula III optionally form an aromatic system, which is fused to the adjacent benzene ring b′ or c′ of formula III and optionally substituted with one or more substituents independently selected from: hydrogen, deuterium, Me, ⁱPr, ^{t}Bu, CN, CF₃, and Ph; wherein the optionally so formed fused ring system has in total 8 to 24 ring atoms;
wherein one or more pair of adjacent substituents R^{V} and R^{VI}, R^{VI} and R^{VII} as well as R^{VII} and R^{VIII} in formula III optionally form an aromatic ring system, which is fused to the adjacent benzene ring f′ of formula III and optionally substituted with one or more substituents independently selected from: hydrogen, deuterium, Me, ⁱPr, ^{t}Bu, CN, CF₃, and Ph; wherein the optionally so formed fused ring system has in total 8 to 24 ring atoms;
wherein in formula II, one or more pair selected from R³ and R⁴, R⁸ and R⁹, R¹⁶ and R¹⁷, R²¹ and R²² optionally form a group Z¹, which is selected from selenium (Se) and NR^{X}, with the provision that all optionally so formed groups Z¹ are identical;
wherein in formula III, one or more pair selected from R²⁷ and R²⁸, R³² and R³³, R⁴⁰ and R⁴¹, R⁴⁵ and R⁴⁶ optionally form a group Z², which is selected from selenium (Se) and NR^{X}, with the provision that all optionally so formed groups Z² are identical;
wherein R^{X} is selected from the group consisting of: hydrogen, deuterium, Me, benzyl, ⁱPr, ^{t}Bu, and
Ph, wherein optionally one or more hydrogen atoms are independently substituted by deuterium, Me, ⁱPr, ^{t}Bu, or Ph substituents.

In an embodiment of the present disclosure,
R^{I} and R^{II} are independently of each other selected from the group consisting of: Me, ⁱPr, ^{t}Bu, and
Ph, wherein optionally one or more hydrogen atoms are independently substituted by deuterium, Me, ⁱPr, ^{t}Bu, and Ph;
R^{III}-R^{VIII} and R¹-R⁴⁸ are independently of each other selected from the group consisting of: hydrogen, deuterium, Me, ⁱPr, ^{t}Bu, CN, CF₃, N(Ph)₂,
Ph, wherein optionally one or more hydrogen atoms are independently substituted by deuterium, Me, ⁱPr, ^{t}Bu or Ph substituents;
wherein one or both pairs of adjacent substituents R¹⁰ and R¹¹ as well as R¹⁴ and R¹⁵ in formula II optionally form an aromatic ring system, which is fused to the adjacent benzene ring b or c of formula II and optionally substituted with one or more substituents independently selected from: hydrogen, deuterium, Me, ⁱPr, ^{t}Bu, CN, CF₃, and Ph; wherein the optionally so formed fused ring system has in total 8 to 24 ring atoms;
wherein one or both pairs of adjacent substituents R³⁴ and R³⁵ as well as R³⁸ and R³⁹ in formula III optionally form an aromatic system, which is fused to the adjacent benzene ring b′ or c′ of formula III and optionally substituted with one or more substituents independently selected from: hydrogen, deuterium, Me, ⁱPr, ^{t}Bu, CN, CF₃, and Ph; wherein the optionally so formed fused ring system has in total 8 to 24 ring atoms;
wherein one or more pair of adjacent substituents R^{V} and R^{VI}, R^{VI} and R^{VII} as well as R^{VII} and R^{VIII} in formula III optionally form an aromatic ring system, which is fused to the adjacent benzene ring f′ of formula III and optionally substituted with one or more substituents independently selected from: hydrogen, deuterium, Me, ⁱPr, ^{t}Bu, CN, CF₃, and Ph; wherein the optionally so formed fused ring system has in total 8 to 24 ring atoms;
wherein in formula II, one or more pair selected from R³ and R⁴, R⁸ and R⁹, R¹⁶ and R¹⁷, R²¹ and R²² optionally form a group Z¹, which is selected from selenium (Se) and NR^{X}, with the provision that all optionally so formed groups Z¹ are identical;
wherein in formula III, one or more pair selected from R²⁷ and R²⁸, R³² and R³³, R⁴⁰ and R⁴¹, R⁴⁵ and R⁴⁶ optionally form a group Z², which is selected from selenium (Se) and NR^{X}, with the provision that all optionally so formed groups Z² are identical;
wherein R^{X} is selected from the group consisting of: hydrogen, deuterium, Me, ⁱPr, ^{t}Bu, and
Ph, wherein optionally one or more hydrogen atoms are independently substituted by deuterium, Me, ⁱPr, ^{t}Bu or Ph substituents.

In one embodiment of the present disclosure,
none of the pairs selected from R³ and R⁴, R⁸ and R⁹, R¹⁶ and R¹⁷, R²¹ and R²² in formula II forms a group Z¹; and
none of the pairs selected from R²⁷ and R²⁸, R³² and R³³, R⁴⁰ and R⁴¹, R⁴⁵ and R⁴⁶ in formula III forms a group Z².

In one embodiment of the present disclosure, R⁸ and R⁹ as well as R¹⁶ and R¹⁷ in formula II form a group Z¹, which is selected from selenium (Se) and NR^{X}, with the provision that both Z¹ are identical.

In one embodiment of the present disclosure, R³ and R⁴ as well as R²¹ and R²² in formula II form a group Z¹, which is selected from selenium (Se) and NR^{X}, with the provision that both Z¹ are identical.

In one embodiment of the present disclosure, all of the pairs R³ and R⁴, R⁸ and R⁹, R¹⁶ and R¹⁷ as well as R²¹ and R²² in formula II form a group Z¹, which is selected from selenium (Se) and NR^{X}, with the provision that all four Z¹ are identical.

In one embodiment of the present disclosure, R³² and R³³ as well as R⁴⁰ and R⁴¹ in formula III form a group Z², which is selected from selenium (Se) and NR^{X}, with the provision that both Z² are identical.

In one embodiment of the present disclosure, R²⁷ and R²⁸ as well as R⁴⁵ and R⁴⁶ in formula II form a group Z², which is selected from selenium (Se) and NR^{X}, with the provision that both Z² are identical.

In one embodiment of the present disclosure, all of the pairs R²⁷ and R²⁸, R³² and R³³, R⁴⁰ and R⁴¹ as well as R⁴⁵ and R⁴⁶ in formula II form a group Z², which is selected from selenium (Se) and NR^{X}, with the provision that all four Z² are identical.

In one embodiment of the present disclosure, X¹ is oxygen (O).

In an embodiment of the present disclosure, X¹ is sulfur (S).

In an embodiment of the present disclosure, X¹ is selenium (Se).

In one embodiment of the present disclosure, X² is oxygen (O).

In an embodiment of the present disclosure, X² is sulfur (S).

In an embodiment of the present disclosure, X² is selenium (Se).

In one embodiment of the present disclosure, the organic molecules include or consist of a structure according to formula II, wherein the aforementioned definitions apply.

In one embodiment of the present disclosure, the organic molecules include or consist of a structure according to formula III, wherein the aforementioned definitions apply.

In an embodiment of the present disclosure,
in formula II, R¹=R²⁴, R²=R²³, R³=R²², R⁴=R²¹, R⁵=R²⁰, R⁶=R¹⁹, R⁷=R¹⁸, R⁸=R¹⁷, R⁹=R¹⁶, R¹⁰=R¹⁵, R¹¹=R¹⁴, R¹²=R¹³, and
in formula III, R²⁵=R⁴⁸, R²⁶=R⁴⁷, R²⁷=R⁴⁶, R²⁸=R⁴⁵, R²⁹=R⁴⁴, R³⁰=R⁴³, R³¹=R⁴², R³²=R⁴¹, R³³=R⁴⁰, R³⁴=R³⁹, R³⁵=R³⁸, R³⁶=R³⁷

In an embodiment of the present disclosure, the organic molecules include or consist of a structure according to any of formulas II-a, II-b, II-c, II-d, II-e, II-f, II-g, II-h, III-a, III-b, III-c, III-d, III-e, III-f, III-g, and III-h:

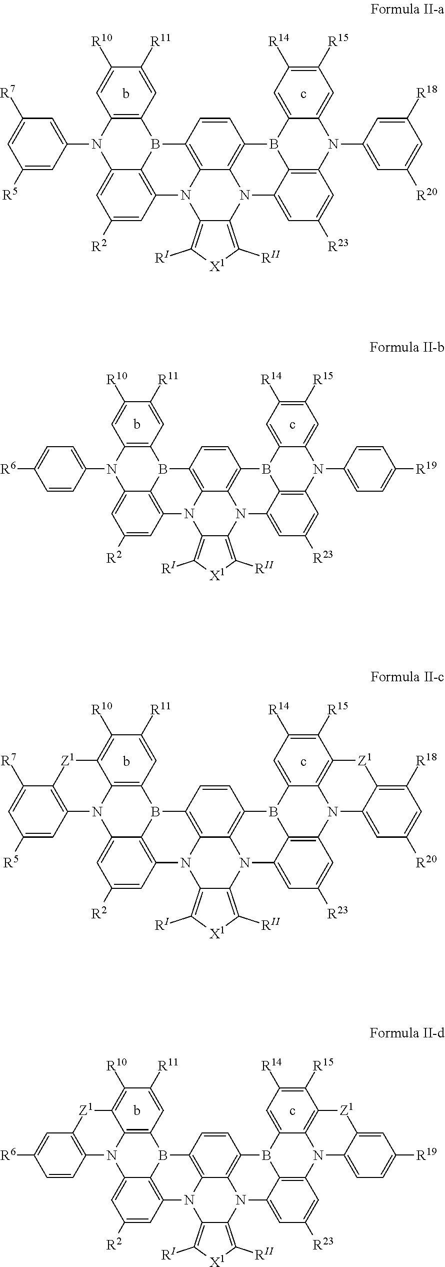

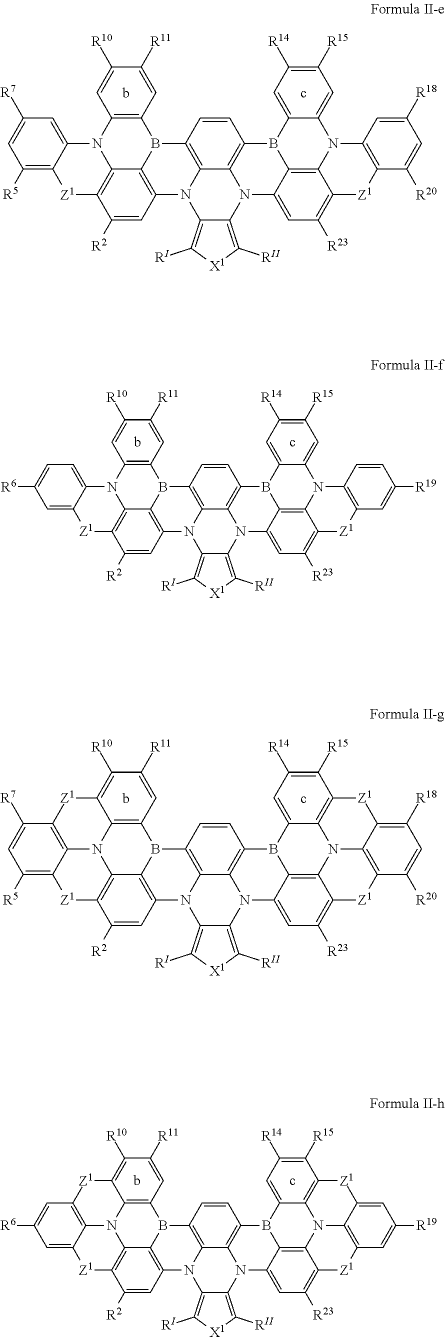

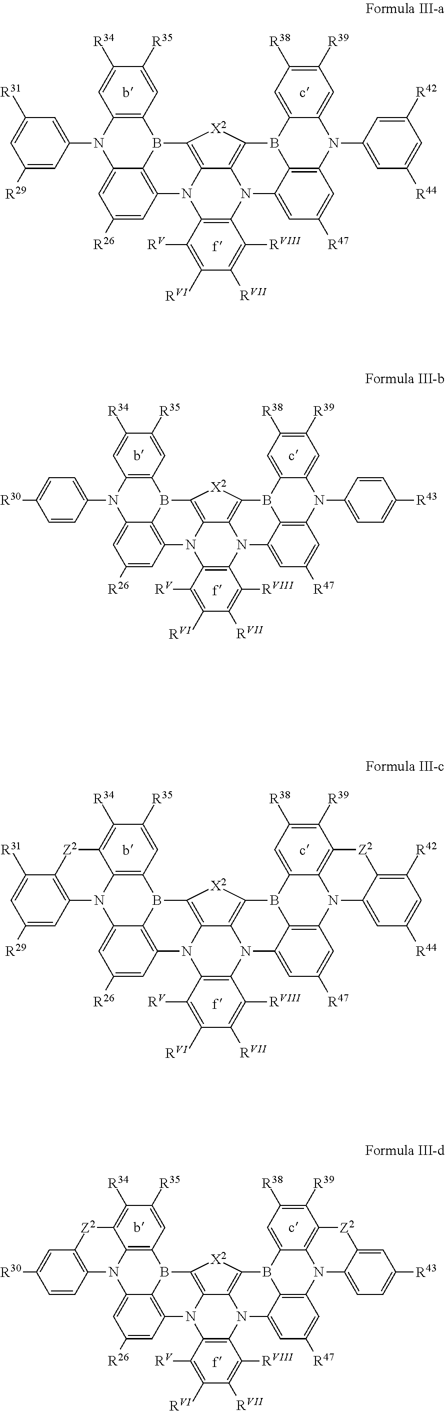

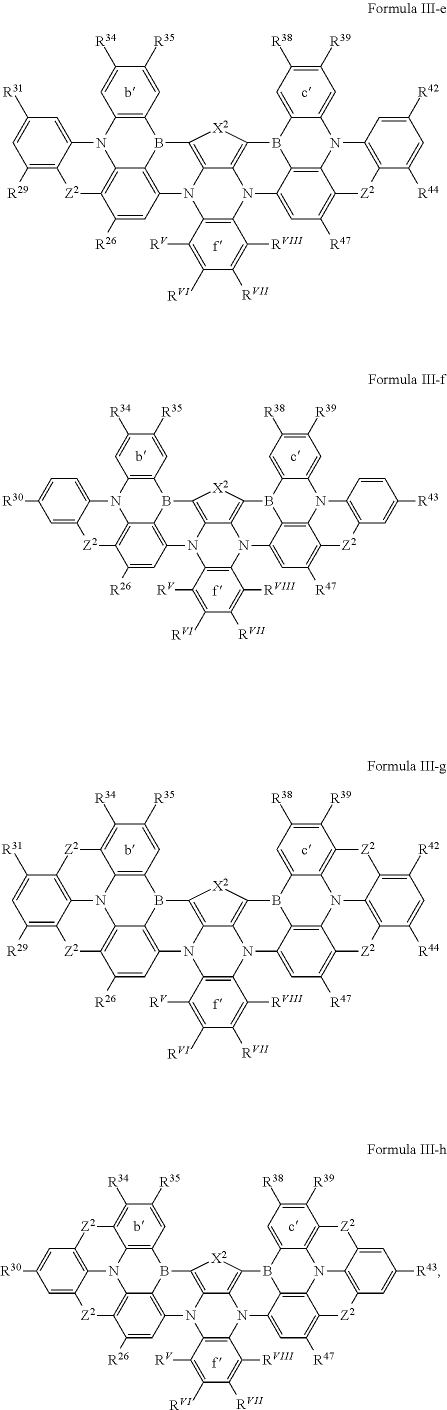

wherein the aforementioned definitions apply.

It is understood that all definitions given within certain embodiments of the present disclosure referring to formula II may also apply to formulas II-a, II-b, II-c, II-d, II-e, II-f, II-g, and II-h. It is also understood that formulas II-a, II-b, II-c, II-d, II-e, II-f, II-g, II-h each represent a fraction of the scope of molecules represented by formula II so that not all parts of the abovementioned definitions related to formula II can apply to formulas II-a, II-b, II-c, II-d, II-e, II-f, II-g, and II-h. For example, formula II-a excludes that one or more pair selected from R³ and R⁴, R⁸ and R⁹, R¹⁶ and R¹⁷, R²¹ and R²² within formula II optionally form a group Z¹. On the other hand, for example, all previously given definitions for the groups X¹ and Z¹ as well as for the substituents R^{I}, R^{II}, R², R⁵, R⁷, R¹⁰, R¹¹, R¹⁴, R¹⁵, R¹⁸, R²⁰, and R²³ may apply to formulas II-a, II-b, II-c, II-d, II-e, II-f, II-g, and II-h.

Accordingly, it is also understood that definitions given within certain embodiments of the present disclosure referring to formula III may also apply to formulas III-a, III-b, III-c, III-d, III-e, III-f, III-g, and III-h. Furthermore, it is understood that formulas III-a, III-b, III-c, III-d, III-e, III-f, III-g, III-h each represent a fraction of the scope of molecules represented by formula III so that not all parts of the abovementioned definitions related to formula III can apply to formulas III-a, III-b, III-c, III-d, III-e, III-f, III-g, and III-h. For example, formula III-a excludes that one or more pair selected from R²⁷ and R²⁸, R³² and R³³, R⁴⁰ and R⁴¹, R⁴⁵ and R⁴⁶ within formula III optionally form a group Z². On the other hand, for example, all previously given definitions for the groups X² and Z² as well as for the substituents R^{V}-R^{VII}, R²⁶, R²⁹, R³¹, R³⁴, R³⁵, R³⁸, R³⁹, R⁴², R⁴⁴ and R⁴⁷ may apply to formulas III-a, II-b, III-c, III-d, III-e, III-f, III-g, and III-h.

In one embodiment of the present disclosure, the organic molecules include or consist of a structure according to any of formulas II-a, II-b, II-c, II-d, II-e, II-f, II-g, II-h, III-a, III-b, III-c, III-d, III-e, III-f, III-g, and III-h, wherein X¹ and X² are oxygen (O) and wherein apart from that the aforementioned definitions apply.

In an embodiment of the present disclosure, the organic molecules include or consist of a structure according to any of formulas II-a, II-b, II-c, II-d, II-e, II-f, II-g, II-h, III-a, III-b, III-c, III-d, III-e, III-f, III-g, and III-h, wherein X¹ and X² are sulfur (S) and wherein apart from that the aforementioned definitions apply.

In an embodiment of the present disclosure, the organic molecules include or consist of a structure according to any of formulas II-a, II-b, II-c, II-d, II-e, II-f, II-g, II-h, III-a, III-b, III-c, III-d, III-e, III-f, III-g, and III-h, wherein X¹ and X² are selenium (Se), and wherein apart from that the aforementioned definitions apply.

In one embodiment of the present disclosure, the organic molecules include or consist of a structure according to any of formulas II-a, II-b, II-c, II-d, II-e, II-f, II-g, II-h, III-a, III-b, III-c, III-d, III-e, III-f, III-g, and III-h, wherein Z¹ and Z² are selected from selenium (Se) and NR^{X}, with the provision that all groups Z¹ or Z² contained in a molecule according to the named formulas are identical, and wherein apart from that the aforementioned definitions apply.

In one embodiment of the present disclosure, the organic molecules include or consist of a structure according to any of formulas II-a, II-b, II-c, II-d, II-e, II-f, II-g, II-h, III-a, III-b, III-c, III-d, III-e, III-f, III-g, and III-h, wherein Z¹ and Z² are at each occurrence selenium (Se), and wherein apart from that the aforementioned definitions apply.

In one embodiment of the present disclosure, the organic molecules include or consist of a structure according to any of formulas II-a, II-b, II-c, II-d, II-e, II-f, II-g, II-h, III-a, III-b, III-c, III-d, III-e, III-f, III-g, and III-h, wherein Z¹ and Z² are at each occurrence NR^{X}, and wherein apart from that the aforementioned definitions apply.

In one embodiment of the present disclosure, the organic molecules include or consist of a structure according to any of formulas II-a, II-b, III-a, and III-b, wherein the aforementioned definitions apply.

In an embodiment of the present disclosure, the organic molecules include or consist of a structure according to any of formulas II-a, II-b, II-c, II-d, II-e, II-f, II-g, II-h, III-a, III-b, III-c, III-d, III-e, III-f, III-g, and III-h, wherein
X¹ and X² are selected from oxygen (O), sulfur (S), and selenium (Se);
R^{I}, R^{II}, R^{V}, R^{VI}, R^{VII}, and R^{VIII} are independently of each other selected from the group consisting of: Me, ⁱPr, ^{t}Bu, CN, CF₃, and
Ph, wherein optionally one or more hydrogen atoms are independently substituted by deuterium, Me, ⁱPr, ^{t}Bu, CN, or CF₃;
R², R⁵, R⁷, R¹⁰, R¹¹, R¹⁴, R¹⁵, R¹⁸, R²⁰, R²³, R²⁶, R²⁹, R³¹, R³⁴, R³⁵, R³⁸, R³⁹, R⁴², R⁴⁴, and R⁴⁷ are independently of each other selected from the group consisting of: hydrogen, deuterium, Me, benzyl, ⁱPr, ^{t}Bu, CF₃, CN, F, SiMe₃, Si(Ph)₃, N(Ph)₂, pyrrolidinyl, piperidinyl,
Ph, wherein optionally one or more hydrogen atoms are independently substituted by deuterium, CN, CF₃, Me, ⁱPr, ^{t}Bu or Ph substituents;
carbazolyl, wherein optionally one or more hydrogen atoms are independently substituted by deuterium, CN, CF₃, Me, ⁱPr, ^{t}Bu, or Ph substituents;
wherein one or both pairs of adjacent substituents R¹⁰ and R¹¹ as well as R¹⁴ and R¹⁵ in formula II-a, II-b, II-c, II-d, II-e, II-f, II-g or II-h optionally form an aromatic ring system, which is fused to the adjacent benzene ring b or c of formula II-a, II-b, II-c, II-d, II-e, II-f, II-g, or II-h and optionally substituted with one or more substituents independently selected from: hydrogen, deuterium, Me, ⁱPr, ^{t}Bu, CN, CF₃, and Ph; wherein the optionally so formed fused ring system has in total 8 to 24 ring atoms;
wherein one or both pairs of adjacent substituents R³⁴ and R³⁵ as well as R³⁸ and R³⁹ in formula III-a, III-b, III-c, III-d, III-e, III-f, III-g, or III-h optionally form an aromatic system, which is fused to the adjacent benzene ring b′ or c′ of III-a, III-b, III-c, III-d, III-e, III-f, III-g, or III-h and optionally substituted with one or more substituents independently selected from: hydrogen, deuterium, Me, ⁱPr, ^{t}Bu, CN, CF₃, and Ph; wherein the optionally so formed fused ring system has in total 8 to 24 ring atoms;
wherein one or more pair of adjacent substituents R^{V} and R^{VI}, R^{VI} and R^{VII} as well as R^{VII} and R^{VIII} in formula III optionally form an aromatic ring system, which is fused to the adjacent benzene ring f′ of formula III and optionally substituted with one or more substituents independently selected from: hydrogen, deuterium, Me, ⁱPr, ^{t}Bu, CN, CF₃, and Ph; wherein the optionally so formed fused ring system has in total 8 to 24 ring atoms;
Z¹ is selected from selenium (Se) and NR^{X}, with the provision that all groups Z¹ included in a molecule according to embodiments of the present disclosure are identical;
Z² is selected from selenium (Se) and NR^{X}, with the provision that all groups Z² included in a molecule according to embodiments of the present disclosure are identical;
wherein R^{X} is selected from the group consisting of: hydrogen, deuterium, Me, benzyl, ⁱPr, ^{t}Bu, and
Ph, wherein optionally one or more hydrogen atoms are independently substituted by deuterium, Me, ⁱPr, ^{t}Bu, or Ph substituents.

In an embodiment of the present disclosure, the organic molecules include or consist of a structure according to any of formulas II-a, II-b, II-c, II-d, II-e, II-f, II-g, II-h, III-a, III-b, III-c, III-d, III-e, III-f, III-g, and III-h, wherein
X¹ and X² are selected from oxygen (O), sulfur (S), and selenium (Se);
R^{I}, R^{II}, R^{V}, R^{VI}, R^{VI}, and R^{VIII} are independently of each other selected from the group consisting of: Me, ⁱPr, ^{t}Bu, and
Ph, wherein optionally one or more hydrogen atoms are independently substituted by deuterium, Me, ⁱPr, ^{t}Bu, and Ph;
R², R⁵, R⁷, R¹⁰, R¹¹, R¹⁴, R¹⁵, R¹⁸, R²⁰, R²³, R²⁶, R²⁹, R³¹, R³⁴, R³⁵, R³⁸, R³⁹, R⁴², R⁴⁴, and R⁴⁷ are independently of each other selected from the group consisting of: hydrogen, deuterium, Me, ⁱPr, ^{t}Bu, CF₃, CN, N(Ph)₂,
Ph, wherein optionally one or more hydrogen atoms are independently substituted by deuterium, Me, ⁱPr, ^{t}Bu or Ph substituents;
wherein one or both pairs of adjacent substituents R¹⁰ and R¹¹ as well as R⁴ and R¹⁵ in formula II-a, II-b, II-c, II-d, II-e, II-f, II-g or II-h optionally form an aromatic ring system, which is fused to the adjacent benzene ring b or c of formula II-a, II-b, II-c, II-d, II-e, II-f, II-g, or II-h and optionally substituted with one or more substituents independently selected from: hydrogen, deuterium, Me, ⁱPr, ^{t}Bu, CN, CF₃, and Ph; wherein the optionally so formed fused ring system has in total 8 to 24 ring atoms;
wherein one or both pairs of adjacent substituents R³⁴ and R³⁵ as well as R³⁸ and R³⁹ in formula III-a, III-b, III-c, III-d, III-e, III-f, III-g, or III-h optionally form an aromatic system, which is fused to the adjacent benzene ring b′ or c′ of III-a, III-b, III-c, III-d, III-e, III-f, III-g, or III-h and optionally substituted with one or more substituents independently selected from: hydrogen, deuterium, Me, ⁱPr, ^{t}Bu, CN, CF₃, and Ph; wherein the optionally so formed fused ring system has in total 8 to 24 ring atoms;
wherein one or more pair of adjacent substituents R^{V} and R^{VI}, R^{VI} and R^{VII} as well as R^{VII} and R^{VIII} in formula III optionally form an aromatic ring system, which is fused to the adjacent benzene ring f′ of formula III and optionally substituted with one or more substituents independently selected from: hydrogen, deuterium, Me, ⁱPr, ^{t}Bu, CN, CF₃, and Ph; wherein the optionally so formed fused ring system has in total 8 to 24 ring atoms;
Z¹ is selected from selenium (Se) and NR^{X}, with the provision that all groups Z¹ included in a molecule according to embodiments of the present disclosure are identical;
Z² is selected from selenium (Se) and NR^{X}, with the provision that all groups Z² included in a molecule according to embodiments of the present disclosure are identical;
wherein R^{X} is selected from the group consisting of: hydrogen, deuterium, Me, ⁱPr, ^{t}Bu, and
Ph, wherein optionally one or more hydrogen atoms are independently substituted by deuterium, Me, ⁱPr, ^{t}Bu or Ph substituents.

In an embodiment of the present disclosure, the organic molecules include or consist of a structure according to any of formulas II-a, II-b, II-c, II-d, II-e, II-f, II-g, II-h, III-a, III-b, III-c, III-d, III-e, III-f, III-g, and III-h, wherein
X¹ and X² are selected from oxygen (O), sulfur (S), and selenium (Se);
R^{I}, R^{II}, R^{V}, R^{VI}, R^{VII}, and R^{VIII} are independently of each other selected from the group consisting of: Me, ⁱPr, ^{t}Bu, and
Ph, wherein optionally one or more hydrogen atoms are independently substituted by deuterium, Me, ⁱPr, ^{t}Bu, and Ph;
R², R⁵, R⁷, R¹⁰, R¹¹, R¹⁴, R¹⁵, R¹⁸, R²⁰, R²³, R²⁶, R²⁹, R³¹, R³⁴, R³⁵, R³⁸, R³⁹, R⁴², R⁴⁴, and R⁴⁷ are independently of each other selected from the group consisting of: hydrogen, deuterium, Me, ⁱPr, ^{t}Bu, CF₃, CN, N(Ph)₂,
Ph, wherein optionally one or more hydrogen atoms are independently substituted by deuterium, Me, ⁱPr, ^{t}Bu or Ph substituents;
wherein one or both pairs of adjacent substituents R¹⁰ and R¹¹ as well as R¹⁴ and R¹⁵ in formula II-a, II-b, II-c, II-d, II-e, II-f, II-g or II-h optionally form an aromatic ring system, which is fused to the adjacent benzene ring b or c of formula II-a, II-b, II-c, II-d, II-e, II-f, II-g, or II-h and optionally substituted with one or more substituents independently selected from: hydrogen, deuterium, Me, ⁱPr, ^{t}Bu, and Ph; wherein the optionally so formed fused ring system has in total 8 to 24 ring atoms;
wherein one or both pairs of adjacent substituents R³⁴ and R³⁵ as well as R³⁸ and R³⁹ in formula III-a, III-b, III-c, III-d, III-e, III-f, III-g, or III-h optionally form an aromatic system, which is fused to the adjacent benzene ring b′ or c′ of III-a, III-b, III-c, III-d, III-e, III-f, III-g, or III-h and optionally substituted with one or more substituents independently selected from: hydrogen, deuterium, Me, ⁱPr, ^{t}Bu, and Ph; wherein the optionally so formed fused ring system has in total 8 to 24 ring atoms;
wherein R^{V} and R^{VI}, R^{VI} and R^{VII} as well as R^{VII} and R^{VIII} in formula III do not form an aromatic ring system which is fused to the adjacent benzene ring f′;
Z¹ is selected from selenium (Se) and NR^{X}, with the provision that all groups Z¹ included in a molecule according to embodiments of the present disclosure are identical;
Z² is selected from selenium (Se) and NR^{X}, with the provision that all groups Z² included in a molecule according to embodiments of the present disclosure are identical;
wherein R^{X} is selected from the group consisting of: hydrogen, deuterium, Me, ⁱPr, ^{t}Bu, and
Ph, wherein optionally one or more hydrogen atoms are independently substituted by deuterium, Me, ⁱPr, ^{t}Bu or Ph substituents.

In an embodiment of the present disclosure, the organic molecules include or consist of a structure according to any of formulas II-a, II-b, II-c, II-d, II-e, II-f, II-g, II-h, III-a, III-b, III-c, III-d, III-e, III-f, III-g, and III-h, wherein
X¹ and X² are selected from oxygen (O), sulfur (S), and selenium (Se);
R^{I}, R^{II}, R^{V}, R^{VI}, R^{VI}, and R^{VIII} are independently of each other selected from the group consisting of: Me, ⁱPr, ^{t}Bu, and
Ph, wherein optionally one or more hydrogen atoms are independently substituted by deuterium, Me, ⁱPr, ^{t}Bu, and Ph;
R², R⁵, R⁷, R¹⁰, R¹¹, R¹⁴, R¹⁵, R¹⁸, R²⁰, R²³, R²⁶, R²⁹, R³¹, R³⁴, R³⁵, R³⁸, R³⁹, R⁴², R⁴⁴, and R⁴⁷ are independently of each other selected from the group consisting of: hydrogen, deuterium, Me, ⁱPr, ^{t}Bu, N(Ph)₂, and
Ph, wherein optionally one or more hydrogen atoms are independently substituted by deuterium, Me, ⁱPr, ^{t}Bu or Ph substituents;
wherein one or both pairs of adjacent substituents R¹⁰ and R¹¹ as well as R¹ and R¹⁵ in formula II-a, II-b, II-c, II-d, II-e, II-f, II-g or II-h optionally form an unsubstituted aromatic ring system, which is fused to the adjacent benzene ring b or c of formula II-a, II-b, II-c, II-d, II-e, II-f, II-g, or II-h; wherein the optionally so formed fused ring system has in total 8 to 24 ring atoms;
wherein one or both pairs of adjacent substituents R³⁴ and R³⁵ as well as R³⁸ and R³⁹ in formula III-a, III-b, III-c, III-d, III-e, III-f, III-g, or III-h optionally form an unsubstituted aromatic system, which is fused to the adjacent benzene ring b′ or c′ of formula III-a, III-b, III-c, III-d, III-e, III-f, III-g, or III-h; wherein the optionally so formed fused ring system has in total 8 to 24 ring atoms;
wherein R^{V} and R^{VI}, R^{VI} and R^{VII} as well as R^{VII} and R^{VIII} in formula III do not form an aromatic ring system which is fused to the adjacent benzene ring f′;
Z¹ is selected from selenium (Se) and NR^{X}, with the provision that all groups Z¹ included in a molecule according to embodiments of the present disclosure are identical;
Z² is selected from selenium (Se) and NR^{X}, with the provision that all groups Z² included in a molecule according to embodiments of the present disclosure are identical;
wherein R^{X} is selected from the group consisting of: hydrogen, deuterium, Me, ⁱPr, ^{t}Bu, and Ph.

As used throughout the present application, the term “cyclic group” may be understood in the broadest sense as any mono-, bi- or polycyclic moieties.

In one embodiment of the present disclosure, adjacent substituents R^{V} and R^{VI}, R^{VI} and R^{VII} as well as R^{VII} and R^{VIII} in formula III do not form an aromatic ring system which is fused to the adjacent benzene ring f′ of formula III.

As used throughout the present application, the terms “ring” and “ring system” may be understood in the broadest sense as any mono-, bi- or polycyclic moieties.

The term “ring atom” refers to any atom which is part of the cyclic core of a ring or a ring structure, and not part of a substituent optionally attached to it.

As used throughout the present application, the term “carbocycle” may be understood in the broadest sense as any cyclic group in which the cyclic core structure includes only carbon atoms that may of course be substituted with hydrogen or any other substituents defined in the example embodiments of the present disclosure. It is understood that the term “carbocyclic” as an adjective refers to cyclic groups in which the cyclic core structure includes only carbon atoms that may of course be substituted with hydrogen or any other substituents defined in the example embodiments of the present disclosure.

As used throughout the present application, the term “heterocycle” may be understood in the broadest sense as any cyclic group in which the cyclic core structure includes not just carbon atoms, but also at least one heteroatom. It is understood that the term “heterocyclic” as an adjective refers to cyclic groups in which the cyclic core structure includes not just carbon atoms, but also at least one heteroatom. The heteroatoms may, unless stated otherwise in specific embodiments, at each occurrence be the same or different and be individually selected from the group consisting of N, O, S, and Se. All carbon atoms or heteroatoms included in a heterocycle in the context of the present disclosure may of course be substituted with hydrogen or any other substituents defined in the example embodiments of the present disclosure.

As used throughout the present application, the term “aromatic ring system” may be understood in the broadest sense as any bi- or polycyclic aromatic moiety.

As used throughout the present application, the term “heteroaromatic ring system” may be understood in the broadest sense as any bi- or polycyclic heteroaromatic moiety.

As used throughout the present application, the term “fused” when referring to aromatic or heteroaromatic ring systems means that the aromatic or heteroaromatic rings that are “fused” share at least one bond that is part of both ring systems. For example, naphthalene (or naphthyl when referred to as substituent) or benzothiophene (or benzothiophenyl when referred to as substituent) are considered fused aromatic ring systems in the context of the present disclosure, in which two benzene rings (for naphthalene) or a thiophene and a benzene (for benzothiophene) share one bond. It is also understood that sharing a bond in this context includes sharing the two atoms that build up the respective bond and that fused aromatic or heteroaromatic ring systems can be understood as one aromatic or heteroaromatic system. Additionally, it is understood, that more than one bond may be shared by the aromatic or heteroaromatic rings building up a fused aromatic or heteroaromatic ring system (e.g., in pyrene). Furthermore, it will be understood that aliphatic ring systems may also be fused and that this has the same meaning as for aromatic or heteroaromatic ring systems, with the exception of course, that fused aliphatic ring systems are not aromatic.

As used throughout the present application, the terms “aryl” and “aromatic” may be understood in the broadest sense as any mono-, bi- or polycyclic aromatic moieties. Accordingly, unless specified differently in example embodiments of the present disclosure, an aryl group contains 6 to 60 aromatic ring atoms, and a heteroaryl group contains 5 to 60 aromatic ring atoms, of which at least one is a heteroatom. Notwithstanding, throughout the application the number of aromatic ring carbon atoms may be given as subscripted number in the definition of certain substituents. In some embodiments, the heteroaromatic ring includes one to three heteroatoms. Again, the terms “heteroaryl” and “heteroaromatic” may be understood in the broadest sense as any mono-, bi- or polycyclic hetero-aromatic moieties that include at least one heteroatom. The heteroatoms may, unless stated otherwise in specific embodiments, at each occurrence be the same or different and be individually selected from the group consisting of N, O, S, and Se. Accordingly, the term “arylene” refers to a divalent substituent that bears two binding sites to other molecular structures and thereby serves as a linker structure. In case a group in the example embodiments is defined differently from the definitions given here, for example, the number of aromatic ring atoms or number of heteroatoms differs from the given definition, the definition in the example embodiments is to be applied. According to embodiments of the present disclosure, a condensed (annulated) aromatic or heteroaromatic polycycle is built of two or more single aromatic or heteroaromatic cycles, which formed the polycycle via a condensation reaction.

In some embodiments, as used throughout the present application the term “aryl group” or “heteroaryl group” includes groups which can be bound via any suitable position of the aromatic or heteroaromatic group, derived from benzene, naphthalene, anthracene, phenanthrene, pyrene, dihydropyrene, chrysene, perylene, fluoranthene, benzanthracene, benzphenanthrene, tetracene, pentacene, benzpyrene, furan, benzofuran, isobenzofuran, dibenzofuran, thiophene, benzothiophene, isobenzothiophene, dibenzothiophene, selenophene, benzoselenophene, isobenzoselenophene, dibenzoselenophene; pyrrole, indole, isoindole, carbazole, indolocarbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthoimidazole, phenanthroimidazole, pyridoimidazole, pyrazinoimidazole, quinoxalinoimidazole, oxazole, benzoxazole, naphthooxazole, anthroxazole, phenanthroxazole, isoxazole, 1,2-thiazole, 1,3-thiazole, benzothiazole, pyridazine, benzopyridazine, pyrimidine, benzopyrimidine, 1,3,5-triazine, quinoxaline, pyrazine, phenazine, naphthyridine, carboline, benzocarboline, phenanthroline, 1,2,3-triazole, 1,2,4-triazole, benzotriazole, 1,2,3-oxadiazole, 1,2,4-oxadiazole, 1,2,5-oxadiazole, 1,2,3,4-tetrazine, purine, pteridine, indolizine and benzothiadiazole or combinations of the abovementioned groups.

In certain embodiments of the present disclosure, adjacent substituents bonded to an aromatic or heteroaromatic ring may together form an additional aliphatic or aromatic, carbocyclic or heterocyclic ring system which is fused to the aromatic or heteroaromatic ring to which the substituents are bonded. It is understood that the optionally so formed fused ring system will be larger (meaning it includes more ring atoms) than the aromatic or heteroaromatic ring to which the adjacent substituents are bonded. In these cases, the “total” amount of ring atoms included in the fused ring system is to be understood as the sum of ring atoms included in the aromatic or heteroaromatic ring to which the adjacent substituents are bonded and the ring atoms of the additional ring system formed by the adjacent substituents, wherein, however, the carbon atoms that are shared by the ring systems which are fused are counted once and not twice. For example, a benzene ring may have two adjacent substituents that form another benzene ring so that a naphthalene core is built. This naphthalene core then includes 10 ring atoms as two carbon atoms are shared by the two benzene rings and thus only counted once and not twice. The term “adjacent substituents” in this context refers to substituents attached to neighboring ring atoms of a ring system.

As used throughout the present application, the term “aliphatic” when referring to ring systems may be understood in the broadest sense and means that none of the rings that build up the ring system is an aromatic or heteroaromatic ring. It is understood that such an aliphatic ring system may be fused to one or more aromatic rings so that some (but not all) carbon- or heteroatoms included in the core structure of the aliphatic ring system are part of an attached aromatic ring.

As used above and herein, the term “alkyl group” may be understood in the broadest sense as any suitable linear, branched, or cyclic alkyl substituent. In some embodiments, the term alkyl includes the substituents methyl (Me), ethyl (Et), n-propyl (ⁿPr), i-propyl (ⁱPr), cyclopropyl, n-butyl (ⁿBu), i-butyl (ⁱBu), s-butyl (^{s}Bu), t-butyl (^{t}Bu), cyclobutyl, 2-methylbutyl, n-pentyl, s-pentyl, t-pentyl, 2-pentyl, neo-pentyl, cyclopentyl, n-hexyl, s-hexyl, t-hexyl, 2-hexyl, 3-hexyl, neo-hexyl, cyclohexyl, 1-methylcyclopentyl, 2-methylpentyl, n-heptyl, 2-heptyl, 3-heptyl, 4-heptyl, cycloheptyl, 1-methylcyclohexyl, n-octyl, 2-ethylhexyl, cyclooctyl, 1-bicyclo[2,2,2]octyl, 2-bicyclo[2,2,2]-octyl, 2-(2,6-dimethyl)octyl, 3-(3,7-dimethyl)octyl, adamantyl, 2,2,2-trifluoroethyl, 1,1-dimethyl-n-hex-1-yl, 1,1-dimethyl-n-hept-1-yl, 1,1-dimethyl-n-oct-1-yl, 1,1-dimethyl-n-dec-1-yl, 1,1-dimethyl-n-dodec-1-yl, 1,1-dimethyl-n-tetradec-1-yl, 1,1-dimethyl-n-hexadec-1-yl, 1,1-dimethyl-n-octadec-1-yl, 1,1-diethyl-n-hex-1-yl, 1,1-diethyl-n-hept-1-yl, 1,1-diethyl-n-oct-1-yl, 1,1-diethyl-n-dec-1-yl, 1,1-diethyl-n-dodec-1-yl, 1,1-diethyl-n-tetradec-1-yl, 1,1-diethyl-n-hexadec-1-yl, 1,1-diethyl-n-octadec-1-yl, 1-(n-propyl)-cyclohex-1-yl, 1-(n-butyl)-cyclohex-1-yl, 1-(n-hexyl)-cyclohex-1-yl, 1-(n-octyl)-cyclohex-1-yl, and 1-(n-decyl)-cyclohex-1-yl.

As used above and herein, the term “alkenyl” includes linear, branched, and cyclic alkenyl substituents. The term alkenyl group includes, for example, the substituents ethenyl, propenyl, butenyl, pentenyl, cyclopentenyl, hexenyl, cyclohexenyl, heptenyl, cycloheptenyl, octenyl, cyclooctenyl, or cyclooctadienyl.

As used above and herein, the term “alkynyl” includes linear, branched, and cyclic alkynyl substituents. The term alkynyl group includes, for example, ethynyl, propynyl, butynyl, pentynyl, hexynyl, heptynyl, or octynyl.

As used above and herein, the term “alkoxy” includes linear, branched, and cyclic alkoxy substituents. The term alkoxy group includes, for example, methoxy, ethoxy, n-propoxy, i-propoxy, n-butoxy, i-butoxy, s-butoxy, t-butoxy, and 2-methylbutoxy.

As used above and herein, the term “thioalkoxy” includes linear, branched, and cyclic thioalkoxy substituents, in which the O of the alkoxy groups is replaced by, for example, S.

As used above and herein, the terms “halogen” and “halo” may be understood in the broadest sense as being fluorine, chlorine, bromine or iodine.

It is understood that when a molecular fragment is described as being a substituent or otherwise attached to another moiety, its name may be written as if it were a fragment (e.g., naphthyl, dibenzofuryl) or as if it were the whole molecule (e.g., naphthalene, dibenzofuran). As used herein, these different ways of designating a substituent or attached fragment are considered to be equivalent.

All hydrogen atoms (H) included in any structure referred to herein may at each occurrence independently of each other, and without this being indicated specifically, be replaced by deuterium (D). The replacement of hydrogen by deuterium should be readily understood by a person of ordinary in the art upon reviewing this disclosure.

In one embodiment, the organic molecules according to embodiments of the present disclosure have an excited state lifetime of not more than 250 μs, of not more than 150 μs, of not more than 100 μs, of not more than 80 μs or not more than 60 μs, or, for example, of not more than 40 μs in a film of poly(methyl methacrylate) (PMMA) with 2% by weight of organic molecule at room temperature (e.g., approximately 25° C.).

In one embodiment of the present disclosure, the organic molecules according to embodiments of the present disclosure represent thermally-activated delayed fluorescence (TADF) emitters, which exhibit a ΔE_{ST} value, which corresponds to the energy difference between the first excited singlet state (S1) and the first excited triplet state (T1), of less than 5000 cm⁻¹, less than 3000 cm¹, less than 1500 cm¹, less than 1000 cm¹, or, for example, less than 500 cm¹.

In a further embodiment of the present disclosure, the organic molecules according to embodiments of the present disclosure have an emission peak in the visible or nearest ultraviolet range, e.g., in the range of a wavelength of from 420 to 580 nm, with a full width at half maximum of less than 0.30 eV, less than 0.28 eV, less than 0.25 eV, less than 0.23 eV, or, for example, less than 0.20 eV in a film of poly(methyl methacrylate) (PMMA) with 2% by weight of organic molecule at room temperature (e.g., approximately 25° C.).

Orbital and excited state energies can be determined either by means of experimental methods or by calculations employing quantum-chemical methods, for example, density functional theory calculations. The energy of the highest occupied molecular orbital E^{HOMO} is determined by any suitable method generally used in the art, including, but not limited to, cyclic voltammetry measurements having an accuracy of 0.1 eV. The energy of the lowest unoccupied molecular orbital E^{LUMO} is determined as the onset of the absorption spectrum.

The onset of an absorption spectrum is determined by computing the intersection of the tangent to the absorption spectrum with the x-axis. The tangent to the absorption spectrum is set at the low-energy side of the absorption band and at the point at half maximum of the maximum intensity of the absorption spectrum.

Unless stated otherwise, the energy of the first excited triplet state T1 is determined from the onset the phosphorescence spectrum at 77K (steady-state spectrum; film of 2% by weight of emitter in PMMA).

Unless stated otherwise, the energy of the first excited singlet state S1 is determined from the onset the fluorescence spectrum at room temperature (e.g., approx. 25° C.; steady-state spectrum; film of 2% by weight of emitter in PMMA).

The onset of an emission spectrum is determined by computing the intersection of the tangent to the emission spectrum with the x-axis. The tangent to the emission spectrum is set at the high-energy side of the emission band and at the point at half maximum of the maximum intensity of the emission spectrum.

The ΔE_{ST} value, which corresponds to the energy difference between the first excited singlet state (S1) and the first excited triplet state (T1), is determined based on the first excited singlet state energy and the first excited triplet state energy, which were determined as stated above.

A further aspect of embodiments of the present disclosure relates to the use of an organic molecule according to embodiments of the present disclosure as a luminescent emitter or as an absorber, and/or as host material and/or as electron transport material, and/or as hole injection material, and/or as hole blocking material in an optoelectronic device.

The optoelectronic device may be understood in the broadest sense as any suitable device based on organic materials that is suitable for emitting light in the visible or nearest ultraviolet (UV) range, e.g., in the wavelength range from 380 nm to 800 nm. For example, the optoelectronic device may be able to emit light in the visible range, e.g., of from 400 nm to 800 nm.

In the context of such use, the optoelectronic device is selected from the group consisting of:
organic light-emitting diodes (OLEDs),
light-emitting electrochemical cells,
OLED sensors, for example, in gas and vapor sensors not hermetically shielded to the outside,
organic diodes,
organic solar cells,
organic transistors,
organic field-effect transistors,
organic lasers, and
down-conversion elements.

A light-emitting electrochemical cell includes three layers, namely a cathode, an anode, and an active layer, which contains the organic molecule according to embodiments of the present disclosure.

In an example embodiment in the context of such use, the optoelectronic device is a device selected from the group consisting of an organic light emitting diode (OLED), a light emitting electrochemical cell (LEC), an organic laser, and a light-emitting transistor.

In one embodiment, the light-emitting layer of an organic light-emitting diode includes the organic molecules according to embodiments of the present disclosure.

In one embodiment, the light-emitting layer of an organic light-emitting diode includes not only the organic molecules according to embodiments of the present disclosure but also a host material whose triplet (T1) and singlet (S1) energy levels are energetically higher than the triplet (T1) and singlet (S1) energy levels of the organic molecule.

A further aspect of embodiments of the present disclosure relates to a composition including or consisting of:
(a) the organic molecule of embodiments of the present disclosure, for example, in the form of an emitter and/or a host, and
(b) one or more emitter and/or host materials, which differ from the organic molecule of embodiments of the present disclosure, and
(c) optionally, one or more dyes and/or one or more solvents.

In a further embodiment of the present disclosure, the composition has a photoluminescence quantum yield (PLQY) of more than 10%, more than 20%, more than 40%, more than 60%, or, for example, even more than 70% at room temperature.

### Compositions Including at Least One Further Emitter

One embodiment of the present disclosure relates to a composition including or consisting of:
(i) 0.5-50% by weight, 0.5-20% by weight, or, for example, 0.5-10% by weight, of the organic molecule according to the embodiments of the present disclosure;
(ii) 5-98% by weight, 30-93.9% by weight, or, for example, 40-88% by weight, of one host compound H;
(iii) 1-30% by weight, 1-20% by weight, or, for example, 1-5% by weight, of at least one further emitter molecule F having a structure differing from the structure of the molecules according to embodiments of the present disclosure; and
(iv)optionally 0-93.5% by weight, of one or more further host compound D having a structure differing from the structure of the molecules according to embodiments of the present disclosure; and
(v) optionally 0-93.5% by weight, 0-65% by weight, or, for example, 0-50% by weight, of a solvent.

The components or the compositions are chosen such that the sum of the weight of the components add up to 100%.

In a further embodiment of the present disclosure, the composition has an emission peak in the visible or nearest ultraviolet range, e.g., in the range of a wavelength of from 380 to 800 nm.

In one embodiment of the present disclosure, the at least one further emitter molecule F is a purely organic emitter.

In one embodiment of the present disclosure, the at least one further emitter molecule F is a purely organic TADF emitter. Any suitable purely organic TADF emitters generally available in the art may be used.

In one embodiment of the present disclosure, the at least one further emitter molecule F is a fluorescence emitter, for example, a blue, a green, a yellow or a red fluorescence emitter.

In a further embodiment of the present disclosure, the composition, containing the at least one further emitter molecule F shows an emission peak in the visible or nearest ultraviolet range, e.g., in the range of a wavelength of from 380 to 800 nm, with a full width at half maximum of less than 0.30 eV, less than 0.25 eV, less than 0.22 eV, less than 0.19 eV, or, for example, less than 0.17 eV at room temperature, with a lower limit of 0.05 eV.

Composition wherein the at least one further emitter molecule F is a green fluorescence emitter

In a further embodiment of the present disclosure, the at least one further emitter molecule F is a fluorescence emitter, for example, a green fluorescence emitter.

In one embodiment, the at least one further emitter molecule F is a fluorescence emitter selected from the following group:

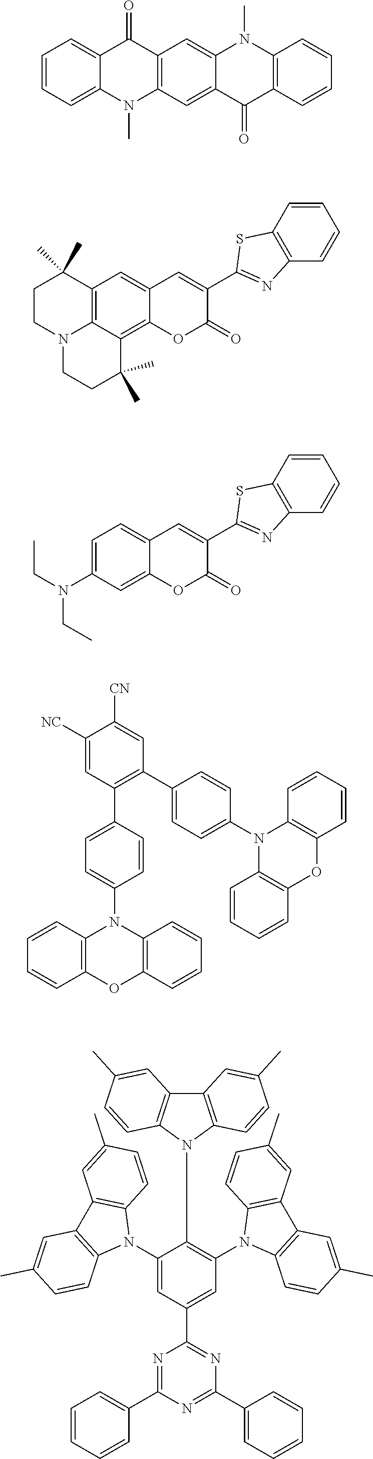

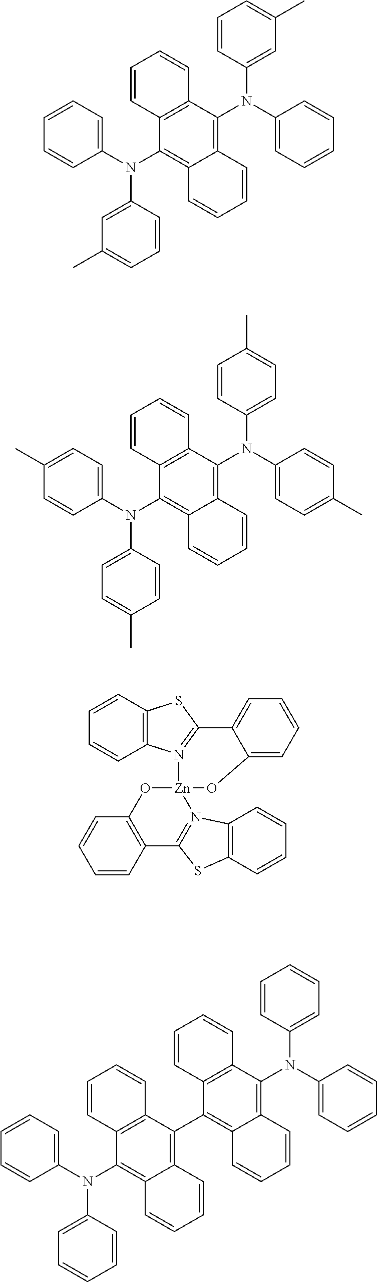

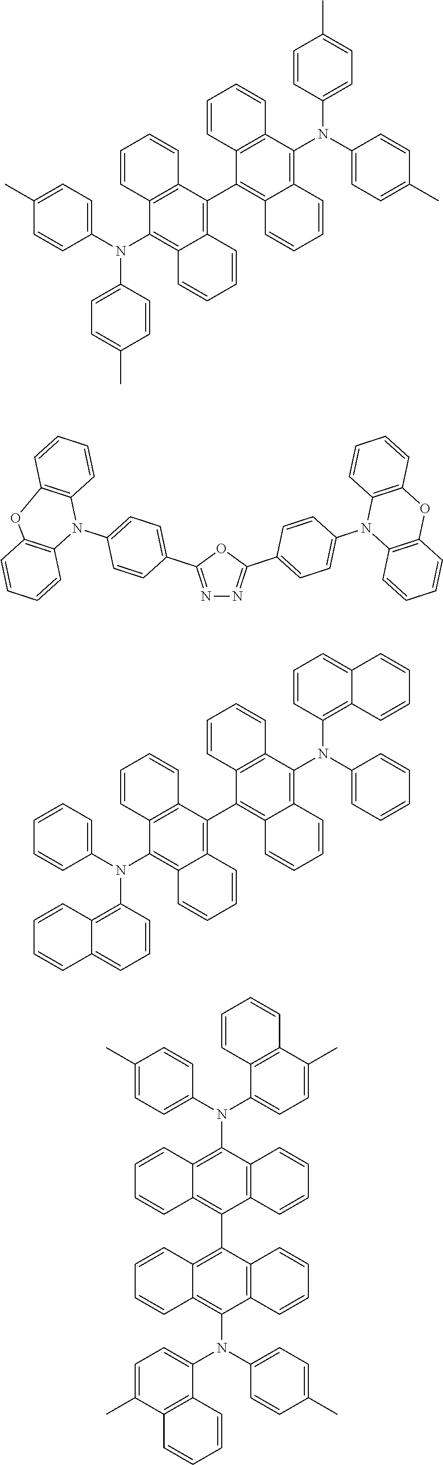

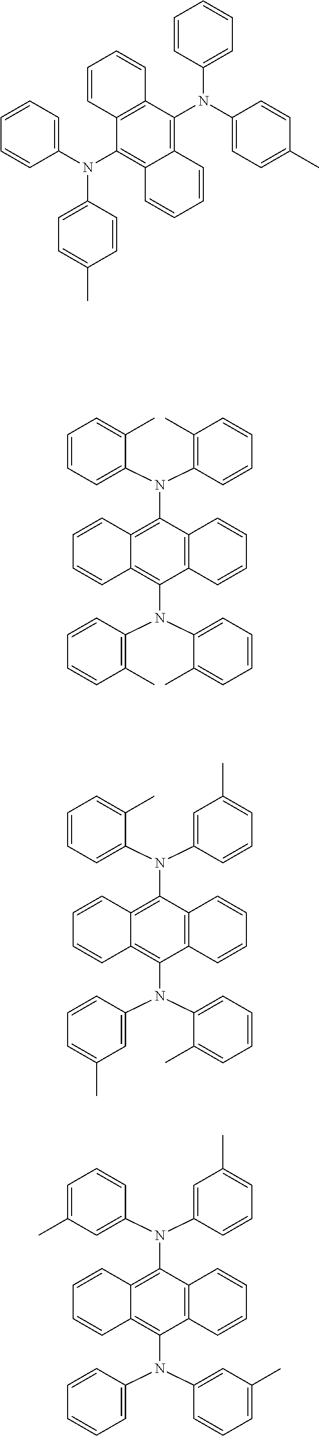

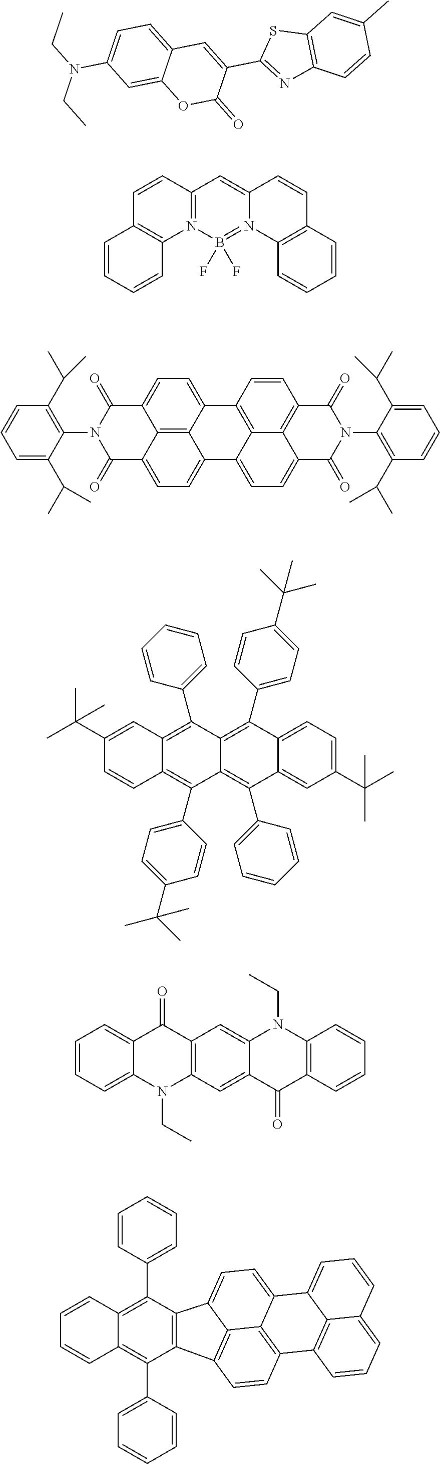

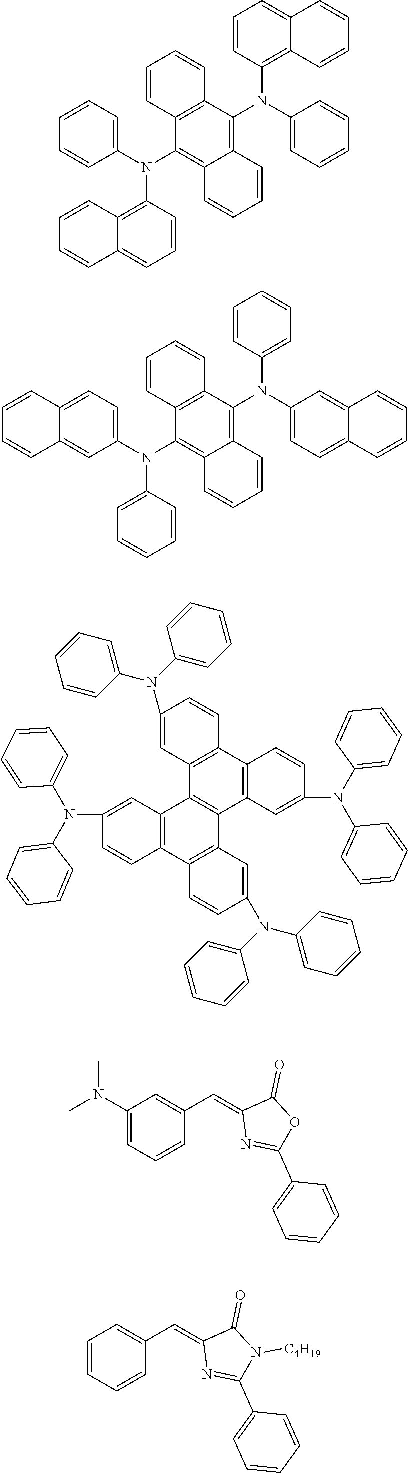

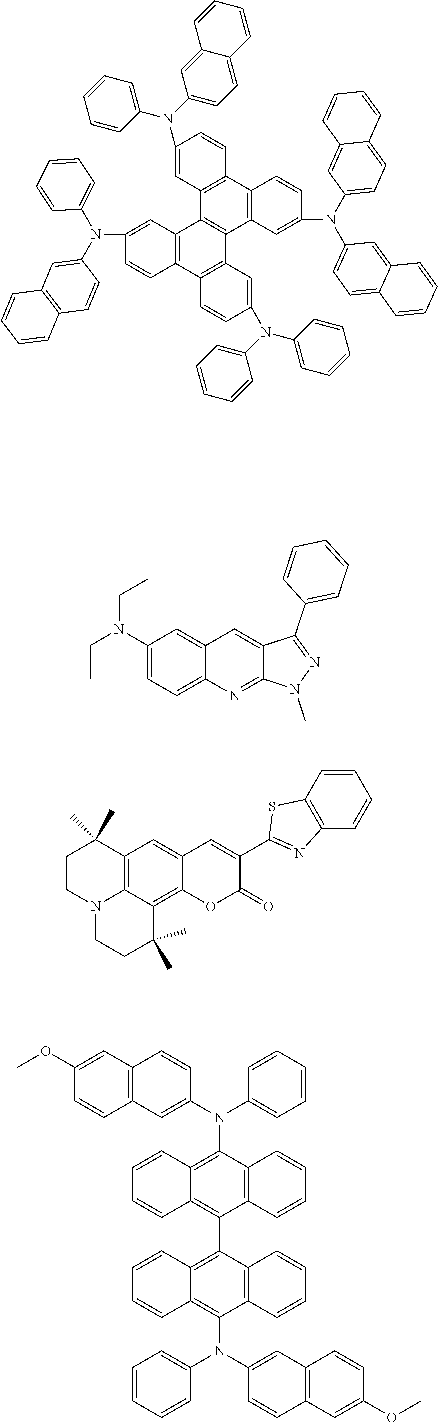

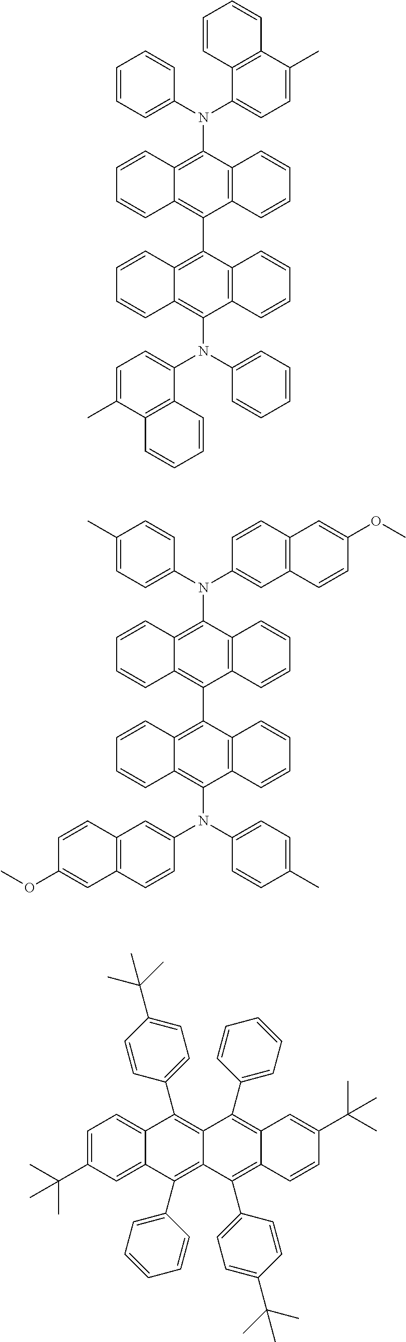

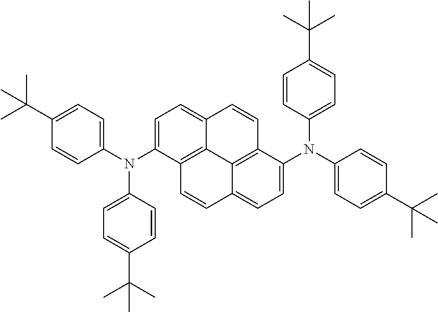 [SMILES: CC(C)(C)c1ccc(N(c2ccc(C(C)(C)C)cc2)c2ccc3ccc4c(N(c5ccc(C(C)(C)C)cc5)c5ccc(C(C)(C)C)cc5)ccc5ccc2c3c54)cc1]

In a further embodiment of the present disclosure, the composition has an emission peak in the visible or nearest ultraviolet range, e.g., in the range of a wavelength of from 380 to 800 nm, between 485 nm and 590 nm, between 505 nm and 565 nm, or, for example, between 515 nm and 545 nm.

### Composition Wherein the at Least One Further Emitter Molecule F is a Red Fluorescence Emitter

In a further embodiment of the present disclosure, the at least one further emitter molecule F is a fluorescence emitter, for example, a red fluorescence emitter.

In one embodiment, the at least one further emitter molecule F is a fluorescence emitter selected from the following group:

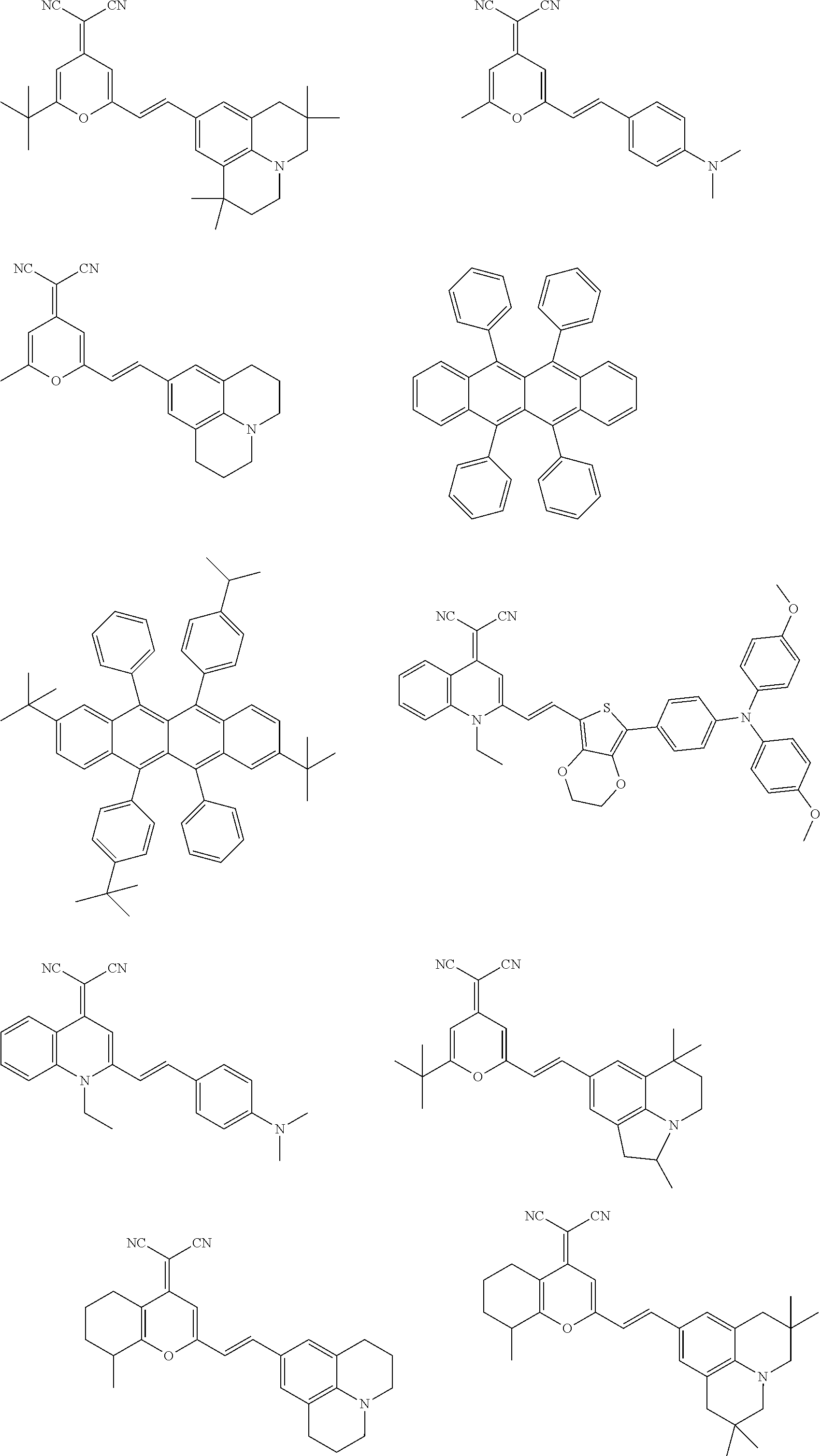

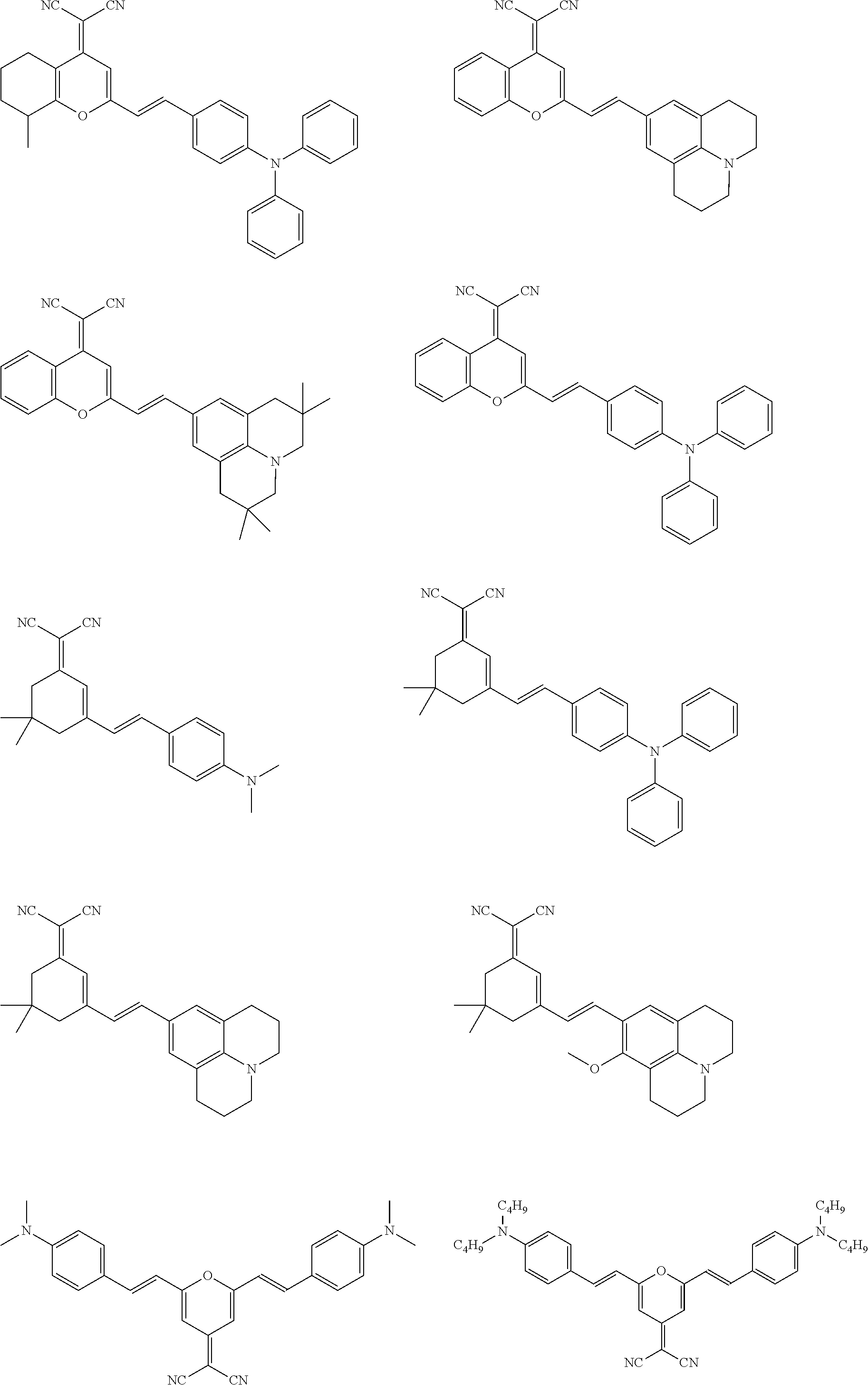

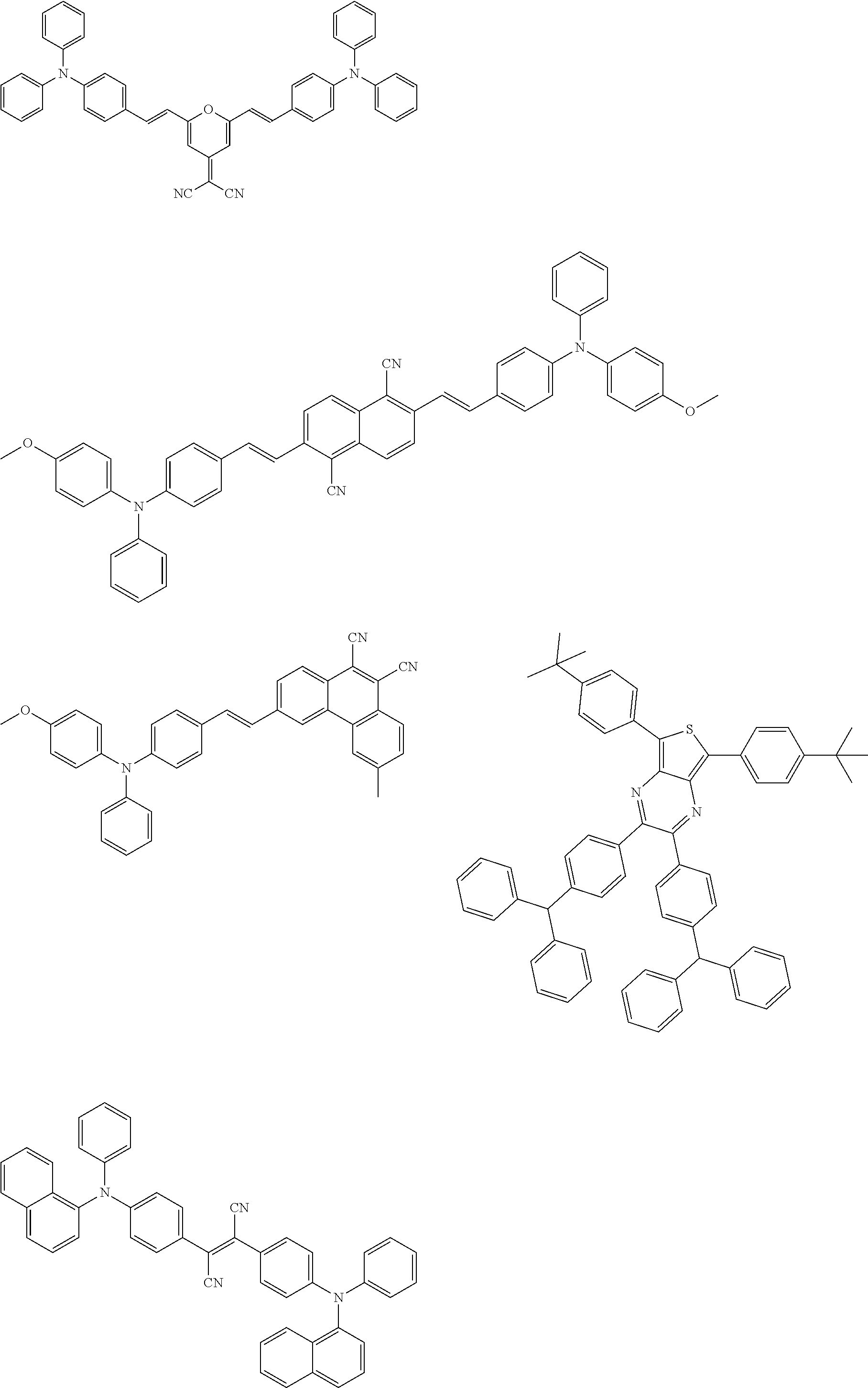

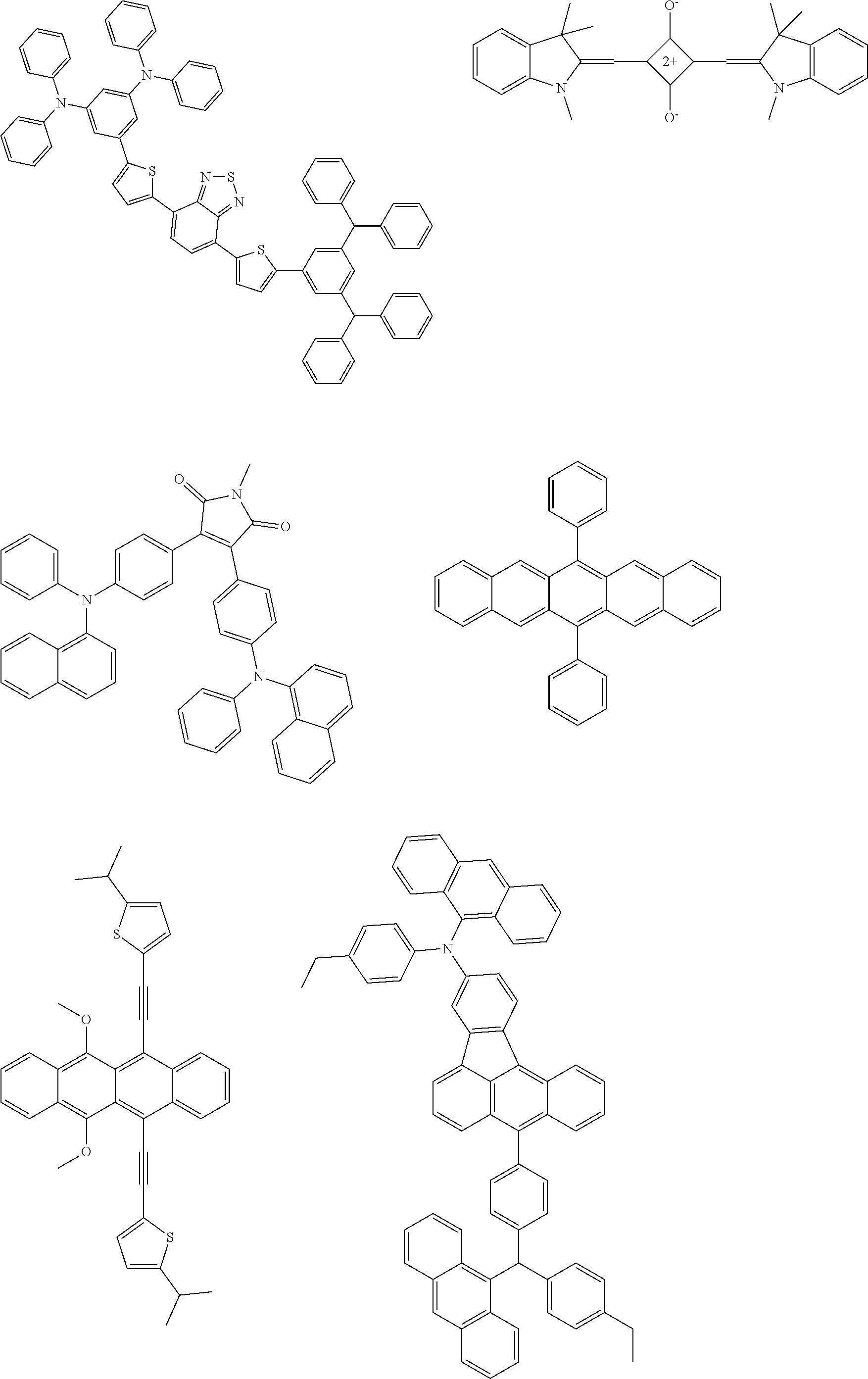

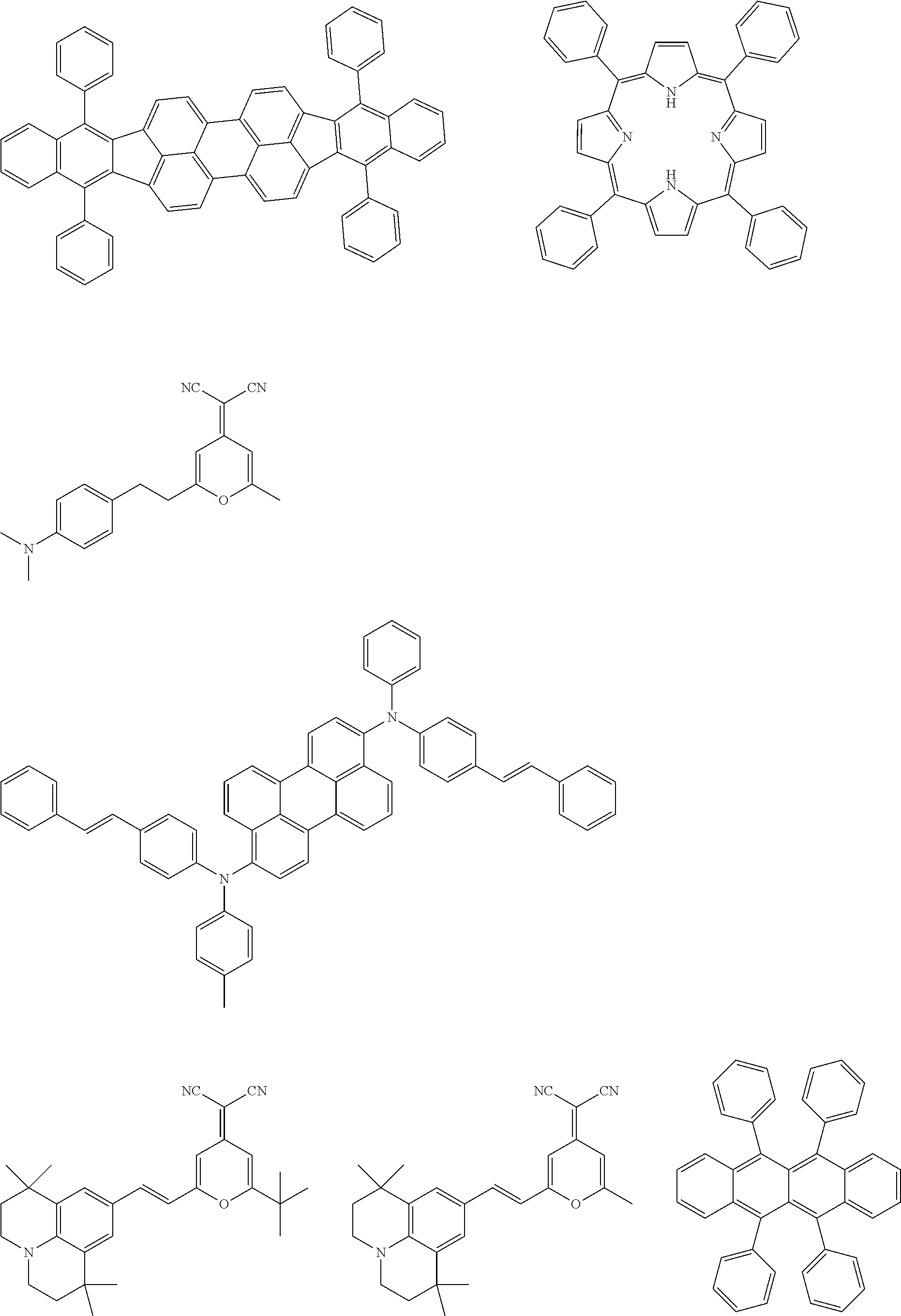

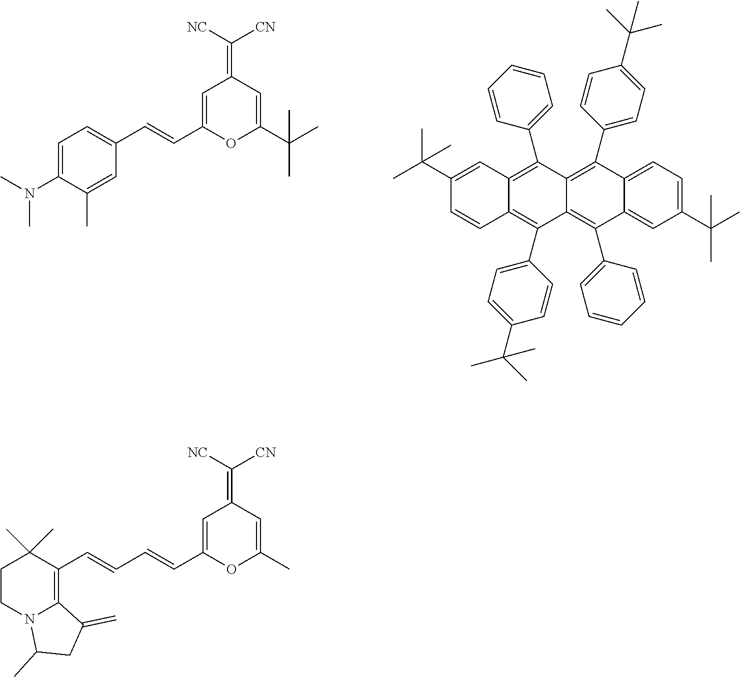

In a further embodiment of the present disclosure, the composition has an emission peak in the visible or nearest ultraviolet range, e.g., in the range of a wavelength of from 380 to 800 nm, between 590 nm and 690 nm, between 610 nm and 665 nm, or, for example, between 620 nm and 640 nm.

### Light-Emitting Layer EML

In one embodiment, the light-emitting layer EML of an organic light-emitting diode of embodiments of the present disclosure includes (or essentially consists of) a composition including or consisting of:
(i) 0.5-50% by weight, 0.5-20% by weight, or, for example, 0.5-10% by weight, of one or more organic molecules according to embodiments of the present disclosure,
(ii) 5-99% by weight, 30-94.9% by weight, or, for example, 40-89% by weight, of at least one host compound H; and
(iii) optionally 0-94% by weight of or more further host compound D having a structure differing from the structure of the molecules according to embodiments of the present disclosure; and
(iv)optionally 0-94% by weight, 0-65% by weight, or, for example, 0-50% by weight, of a solvent; and
(v) optionally 0-30% by weight, 0-20% by weight, or, for example, 0-5% by weight, of at least one further emitter molecule F having a structure differing from the structure of the molecules according to embodiments of the present disclosure.

In some embodiments, energy can be transferred from the host compound H to the one or more organic molecules of embodiments of the present disclosure, for example, transferred from the first excited triplet state T1 (H) of the host compound H to the first excited triplet state (E) of the one or more organic molecules according to embodiments of the present disclosure and/or from the first excited singlet state S1(H) of the host compound H to the first excited singlet state S1(E) of the one or more organic molecules according to embodiments of the present disclosure.

In one embodiment, the host compound H has a highest occupied molecular orbital HOMO(H) having an energy E^{HOMO}(H) in the range of from −5 eV to −6.5 eV and one organic molecule according to embodiments of the present disclosure E has a highest occupied molecular orbital HOMO(E) having an energy E^{HOMO}(E), wherein E^{HOMO}(H)>E^{HOMO}(E).

In a further embodiment, the host compound H has a lowest unoccupied molecular orbital LUMO(H) having an energy E^{LUMO}(H) and the one organic molecule according to embodiments of the present disclosure E has a lowest unoccupied molecular orbital LUMO(E) having an energy E^{LUMO}(E), wherein E^{LUMO}(H)>E^{LUMO}(E). Light-emitting layer EML including at least one further host compound D

In a further embodiment, the light-emitting layer EML of an organic light-emitting diode of embodiments of the present disclosure includes (or essentially consists of) a composition including or consisting of:
(i) 0.5-50% by weight, 0.5-20% by weight, or, for example, 0.5-10% by weight, of one organic molecule according to embodiments of the present disclosure;
(ii) 5-99% by weight, 30-94.9% by weight, or, for example, 40-89% by weight, of one host compound H; and
(iii) 0-94.5% by weight of one or more further host compounds D having a structure differing from the structure of the molecules according to embodiments of the present disclosure; and
(iv)optionally 0-94% by weight, 0-65% by weight, or, for example, 0-50% by weight, of a solvent; and
(v) optionally 0-30% by weight, 0-20% by weight, or, for example, 0-5% by weight, of at least one further emitter molecule F having a structure differing from the structure of the molecules according to embodiments of the present disclosure.

In one embodiment of the organic light-emitting diode of embodiments of the present disclosure, the host compound H has a highest occupied molecular orbital HOMO(H) having an energy E^{HOMO}(H) in the range of from −5 eV to −6.5 eV and the at least one further host compound D has a highest occupied molecular orbital HOMO(D) having an energy E^{HOMO}(D), wherein E^{HOMO}(H)>E^{HOMO}(D). The relation E^{HOMO}(H)>E^{HOMO}(D) favors efficient hole transport.

In a further embodiment, the host compound H has a lowest unoccupied molecular orbital LUMO(H) having an energy E^{LUMO}(H) and the at least one further host compound D has a lowest unoccupied molecular orbital LUMO(D) having an energy E^{LUMO}(D), wherein E^{LUMO}(H)>E^{LUMO}(D). The relation E^{LUMO}(H)>E^{LUMO}(D) favors efficient electron transport.

In one embodiment of the organic light-emitting diode of embodiments of the present disclosure, the host compound H has a highest occupied molecular orbital HOMO(H) having an energy E^{HOMO}(H) and a lowest unoccupied molecular orbital LUMO(H) having an energy E^{LUMO}(H), and
the at least one further host compound D has a highest occupied molecular orbital HOMO(D) having an energy E^{HOMO}(D) and a lowest unoccupied molecular orbital LUMO(D) having an energy E^{LUMO}(D)
the organic molecule E of embodiments of the present disclosure has a highest occupied molecular orbital HOMO(E) having an energy E^{HOMO}(E) and a lowest unoccupied molecular orbital LUMO(E) having an energy E^{LUMO}(E),
wherein
E^{HOMO}(H)>E^{HOMO}(D) and the difference between the energy level of the highest occupied molecular orbital HOMO(E) of organic molecule according to embodiments of the present disclosure (E^{HOMO}(E)) and the energy level of the highest occupied molecular orbital HOMO(H) of the host compound H (E^{HOMO}(H)) is between 0.5 eV and 0.5 eV, between −0.3 eV and 0.3 eV, between −0.2 eV and 0.2 eV, or, for example, between −0.1 eV and 0.1 eV; and
E^{LUMO}(H)>E^{LUMO}(D) and the difference between the energy level of the lowest unoccupied molecular orbital LUMO(E) of organic molecule according to embodiments of the present disclosure (E^{LUMO}(E)) and the lowest unoccupied molecular orbital LUMO(D) of the at least one further host compound D (E^{LUMO}(D)) is between −0.5 eV and 0.5 eV, between −0.3 eV and 0.3 eV, between −0.2 eV and 0.2 eV, or, for example, between −0.1 eV and 0.1 eV.

### Light-Emitting Layer EML Including at Least One Further Emitter Molecule F

In a further embodiment, the light-emitting layer EML includes (or (essentially) consists of) a composition including or consisting of:
(i) 0.5-50% by weight, 0.5-20% by weight, or, for example, 0.5-10% by weight, of one organic molecule according to embodiments of the present disclosure;
(ii) 5-98% by weight, 30-93.9% by weight, or, for example, 40-88% by weight, of one host compound H;
(iii) 1-30% by weight, 1-20% by weight, or, for example, 1-5% by weight, of at least one further emitter molecule F having a structure differing from the structure of the molecules according to embodiments of the present disclosure; and
(iv)optionally 0-93.5% by weight, of one or more further host compound D having a structure differing from the structure of the molecules according to embodiments of the present disclosure; and
(v) optionally 0-93.5% by weight, 0-65% by weight, or, for example, 0-50% by weight, of a solvent.

In a further embodiment, the light-emitting layer EML includes (or (essentially) consists of) a composition as described in Compositions including at least one further emitter, with the at least one further emitter molecule F as defined in Composition wherein the at least one further emitter molecule F is a green fluorescence emitter.

In a further embodiment, the light-emitting layer EML includes (or (essentially) consists of) a composition as described in Compositions including at least one further emitter, with the at least one further emitter molecule F as defined in Composition wherein the at least one further emitter molecule F is a red fluorescence emitter.

In one embodiment of the light-emitting layer EML including at least one further emitter molecule F, energy can be transferred from the one or more organic molecules of embodiments of the present disclosure E to the at least one further emitter molecule F, for example, transferred from the first excited singlet state S1(E) of one or more organic molecules of embodiments of the present disclosure E to the first excited singlet state S1(F) of the at least one further emitter molecule F.

In one embodiment, the first excited singlet state S1(H) of one host compound H of the light-emitting layer is higher in energy than the first excited singlet state S1(E) of the one or more organic molecules of embodiments of the present disclosure E: S1(H)>S1(E), and the first excited singlet state S1(H) of one host compound H is higher in energy than the first excited singlet state S1(F) of the at least one emitter molecule F: S1(H)>S1(F).

In one embodiment, the first excited triplet state T1 (H) of one host compound H is higher in energy than the first excited triplet state T1(E) of the one or more organic molecules of embodiments of the present disclosure E: T1 (H)>T1(E), and the first excited triplet state T1 (H) of one host compound H is higher in energy than the first excited triplet state T1(F) of the at least one emitter molecule F: T1(H)>T1(F).

In some embodiments, the first excited singlet state S1(E) of the one or more organic molecules of embodiments of the present disclosure E is higher in energy than the first excited singlet state S1(F) of the at least one emitter molecule F: S1(E)>S1(F).

In some embodiments, the first excited triplet state T1(E) of the one or more organic molecules E of embodiments of the present disclosure is higher in energy than the first excited singlet state T1 (F) of the at least one emitter molecule F: T1(E)>T1(F).

In some embodiments, the first excited triplet state T1(E) of the one or more organic molecules E of embodiments of the present disclosure is higher in energy than the first excited singlet state T1 (F) of the at least one emitter molecule F: T1(E)>T1(F), wherein the absolute value of the energy difference between T1 (E) and T1 (F) is larger than 0.3 eV, larger than 0.4 eV, or, for example, larger than 0.5 eV.

In some embodiments, the host compound H has a highest occupied molecular orbital HOMO(H) having an energy E^{HOMO}(H) and a lowest unoccupied molecular orbital LUMO(H) having an energy E^{LUMO}(H), and
the one organic molecule according to embodiments of the present disclosure E has a highest occupied molecular orbital HOMO(E) having an energy E^{HOMO}(E) and a lowest unoccupied molecular orbital LUMO(E) having an energy E^{LUMO}(E),
the at least one further emitter molecule F has a highest occupied molecular orbital HOMO(F) having an energy E^{HOMO}(F) and a lowest unoccupied molecular orbital LUMO(E) having an energy E^{LUMO}(F),
wherein
E^{HOMO}(H)>E^{HOMO}(E) and the difference between the energy level of the highest occupied molecular orbital HOMO(F) of the at least one further emitter molecule (E^{HOMO}(F)) and the energy level of the highest occupied molecular orbital HOMO(H) of the host compound H (E^{HOMO}(H)) is between 0.5 eV and 0.5 eV, between −0.3 eV and 0.3 eV, between −0.2 eV and 0.2 eV, or, for example, between −0.1 eV and 0.1 eV; and
E^{LUMO}(H)>E^{LUMO}(E) and the difference between the energy level of the lowest unoccupied molecular orbital LUMO(F) of the at least one further emitter molecule (E^{LUMO}(F)) and the lowest unoccupied molecular orbital LUMO(E) of the one organic molecule according to the embodiments of the present disclosure (E^{LUMO}(E)) is between −0.5 eV and 0.5 eV, between −0.3 eV and 0.3 eV, between −0.2 eV and 0.2 eV, or, for example, between −0.1 eV and 0.1 eV.

### Optoelectronic Devices

In a further aspect, embodiments of the present disclosure relate to an optoelectronic device including an organic molecule or a composition as described herein, for example, in the form of a device selected from the group consisting of organic light-emitting diode (OLED), light-emitting electrochemical cell, OLED sensor (for example, gas and vapor sensors not hermetically externally shielded), organic diode, organic solar cell, organic transistor, organic field-effect transistor, organic laser and down-conversion element.

In an example embodiment, the optoelectronic device is a device selected from the group consisting of an organic light emitting diode (OLED), a light emitting electrochemical cell (LEC), and a light-emitting transistor.

In some embodiments of the optoelectronic device of the present disclosure, the organic molecule according to embodiments of the present disclosure is used as emission material in a light-emitting layer EML.

In some embodiments of the optoelectronic device of the present disclosure, the light-emitting layer EML consists of the composition according to embodiments of the present disclosure described herein.

When the optoelectronic device is an OLED, it may, for example, exhibit the following layer structure:
1. substrate
2. anode layer A
3. hole injection layer, HIL
4. hole transport layer, HTL
5. electron blocking layer, EBL
6. emitting layer, EML
7. hole blocking layer, HBL
8. electron transport layer, ETL
9. electron injection layer, EIL
10. cathode layer,
wherein the OLED includes each layer only optionally, different layers may be merged and the OLED may include more than one layer of each layer type defined above.

Furthermore, the optoelectronic device may include one or more protective layers protecting the device from damaging exposure to harmful species in the environment including, for example, moisture, vapor and/or gases.

In one embodiment of the present disclosure, the optoelectronic device is an OLED, which exhibits the following inverted layer structure:
1. Substrate
2. cathode layer
3. electron injection Layer, EIL
4. electron transport layer, ETL
5. hole blocking Layer, HBL
6. emitting layer, B
7. electron blocking layer, EBL
8. hole transport layer, HTL
9. hole injection layer, HIL
10. anode layer A,
wherein the OLED including an inverted layer structure includes each layer only optionally, different layers may be merged and the OLED may include more than one layer of each layer types defined above.

In one embodiment of the present disclosure, the optoelectronic device is an OLED, which may exhibit stacked architecture. In this architecture, contrary to other arrangements, where the OLEDs are placed side by side, the individual units are stacked on top of each other. Blended light may be generated with OLEDs exhibiting a stacked architecture, for example, white light may be generated by stacking blue, green and red OLEDs. Furthermore, the OLED exhibiting a stacked architecture may include a charge generation layer (CGL), which is generally between two OLED subunits and generally includes (or consists of) a n-doped and p-doped layer with the n-doped layer of one CGL being generally located closer to the anode layer.

In one embodiment of the present disclosure, the optoelectronic device is an OLED, which includes two or more emission layers between anode and cathode. In some embodiments, this so-called tandem OLED includes three emission layers, wherein one emission layer emits red light, one emission layer emits green light and one emission layer emits blue light, and optionally may include further layers such as charge generation layers, blocking or transporting layers between the individual emission layers. In a further embodiment, the emission layers are adjacently stacked. In a further embodiment, the tandem OLED includes a charge generation layer between each two emission layers. In addition, adjacent emission layers or emission layers separated by a charge generation layer may be merged.

The substrate may be formed by any suitable material or composition of materials. Most frequently, glass slides are used as substrates. In some embodiments, thin metal layers (e.g., copper, gold, silver and/or aluminum films) and/or plastic films and/or slides may be used. This may allow a higher degree of flexibility. The anode layer A is mostly composed of materials allowing to obtain an (essentially) transparent film. As at least one selected from both electrodes should be (essentially) transparent in order to allow light emission from the OLED, either the anode layer A or the cathode layer C is transparent. In some embodiments, the anode layer A includes a large content or even consists of transparent conductive oxides (TCOs). Such anode layer A may include, for example, indium tin oxide, aluminum zinc oxide, fluorine doped tin oxide, indium zinc oxide, PbO, SnO, zirconium oxide, molybdenum oxide, vanadium oxide, wolfram oxide, graphite, doped Si, doped Ge, doped GaAs, doped polyaniline, doped polypyrrole and/or doped polythiophene.

In some embodiments, the anode layer A (essentially) consists of indium tin oxide (ITO) (e.g., (InO₃)_{0.9}(SnO₂)_{0.1}). The roughness of the anode layer A caused by the transparent conductive oxides (TCOs) may be compensated by using a hole injection layer (HIL). Further, the HIL may facilitate the injection of quasi charge carriers (e.g., holes) in that the transport of the quasi charge carriers from the TCO to the hole transport layer (HTL) is facilitated. The hole injection layer (HIL) may include poly-3,4-ethylendioxy thiophene (PEDOT), polystyrene sulfonate (PSS), MoO₂, V₂O₅, CuPC or CuI, for example, a mixture of PEDOT and PSS. The hole injection layer (HIL) may also prevent or reduce the diffusion of metals from the anode layer A into the hole transport layer (HTL). The HIL may include, for example, PEDOT:PSS (poly-3,4-ethylendioxy thiophene: polystyrene sulfonate), PEDOT (poly-3,4-ethylendioxy thiophene), mMTDATA (4,4′,4″-tris[phenyl(m-tolyl)amino]triphenylamine), Spiro-TAD (2,2′,7,7′-tetrakis(n,n-diphenylamino)-9,9′-spirobifluorene), DNTPD (N1,N1′-(biphenyl-4,4′-diyl)bis(N1-phenyl-N4,N4-di-m-tolylbenzene-1,4-diamine), NPB (N,N′-nis-(1-naphthalenyl)-N,N′-bis-phenyl-(1,1′-biphenyl)-4,4′-diamine), NPNPB (N,N′-diphenyl-N,N′-di-[4-(N,N-diphenyl-amino)phenyl]benzidine), MeO-TPD (N,N,N′,N′-tetrakis(4-methoxyphenyl)benzidine), HAT-CN (1,4,5,8,9,11-hexaazatriphenylen-hexacarbonitrile) and/or Spiro-NPD (N,N′-diphenyl-N,N′-bis-(1-naphthyl)-9,9′-spirobifluorene-2,7-diamine).

Adjacent to the anode layer A or hole injection layer (HIL) generally a hole transport layer (HTL) is located. Herein, any suitable hole transport compound generally available in the art may be used. For example, electron-rich heteroaromatic compounds such as triarylamines and/or carbazoles may be used as hole transport compound. The HTL may decrease the energy barrier between the anode layer A and the light-emitting layer EML. The hole transport layer (HTL) may also be an electron blocking layer (EBL). In some embodiments, hole transport compounds bear comparably high energy levels of their triplet states T1. For example, the hole transport layer (HTL) may include a star-shaped heterocycle such as tris(4-carbazoyl-9-ylphenyl)amine (TCTA), poly-TPD (poly(4-butylphenyl-diphenyl-amine)), [alpha]-NPD (poly(4-butylphenyl-diphenyl-amine)), TAPC (4,4′-cyclohexyliden-bis[N,N-bis(4-methylphenyl)benzeneamine]), 2-TNATA (4,4′,4″-tris[2-naphthyl(phenyl)amino]triphenylamine), Spiro-TAD, DNTPD, NPB, NPNPB, MeO-TPD, HAT-CN and/or TrisPcz (9,9′-diphenyl-6-(9-phenyl-9H-carbazol-3-yl)-9H,9′H-3,3′-bicarbazole). In addition, the HTL may include a p-doped layer, which may be composed of an inorganic or organic dopant in an organic hole-transporting matrix. Transition metal oxides such as vanadium oxide, molybdenum oxide or tungsten oxide may, for example, be used as an inorganic dopant. Tetrafluorotetracyanoquinodimethane (F4-TCNQ), copper-pentafluorobenzoate (Cu(I)pFBz) or transition metal complexes may, for example, be used as an organic dopant.

The EBL may, for example, include mCP (1,3-bis(carbazol-9-yl)benzene), TCTA, 2-TNATA, mCBP (3,3-di(9H-carbazol-9-yl)biphenyl), tris-Pcz, CzSi (9-(4-tert-butylphenyl)-3,6-bis(triphenylsilyl)-9H-carbazole), and/or DCB (N,N′-dicarbazolyl-1,4-dimethylbenzene).

Adjacent to the hole transport layer (HTL), generally, the light-emitting layer EML is located. The light-emitting layer EML includes at least one light emitting molecule. In some embodiments, the EML includes at least one light emitting molecule according to embodiments of the present disclosure. In some embodiments, the EML additionally includes one or more host material. For example, the host material is selected from CBP (4,4′-Bis-(N-carbazolyl)-biphenyl), mCP, mCBP Sif87 (dibenzo[b,d]thiophen-2-yltriphenylsilane), CzSi, Sif88 (dibenzo[b,d]thiophen-2-yl)diphenylsilane), DPEPO (bis[2-(diphenylphosphino)phenyl] ether oxide), 9-[3-(dibenzofuran-2-yl)phenyl]-9H-carbazole, 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole, 9-[3,5-bis(2-dibenzothiophenyl)phenyl]-9H-carbazole, T2T (2,4,6-tris(biphenyl-3-yl)-1,3,5-triazine), T3T (2,4,6-tris(triphenyl-3-yl)-1,3,5-triazine) and/or TST (2,4,6-tris(9,9′-spirobifluorene-2-yl)-1,3,5-triazine). The host material generally should be selected to exhibit first triplet (T1) and first singlet (S1) energy levels, which are energetically higher than the first triplet (T1) and first singlet (S1) energy levels of the organic molecule.

In one embodiment of the present disclosure, the EML includes a so-called mixed-host system including at least one hole-dominant host and one electron-dominant host. In some embodiments, the EML includes exactly one light emitting molecule species according to embodiments of the present disclosure and a mixed-host system including T2T as electron-dominant host and a host selected from CBP, mCP, mCBP, 9-[3-(dibenzofuran-2-yl)phenyl]-9H-carbazole, 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole and 9-[3,5-bis(2-dibenzothiophenyl)phenyl]-9H-carbazole as hole-dominant host. In a further embodiment the EML includes 50-80% by weight, or, for example, 60-75% by weight of a host selected from CBP, mCP, mCBP, 9-[3-(dibenzofuran-2-yl)phenyl]-9H-carbazole, 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole and 9-[3,5-bis(2-dibenzothiophenyl)phenyl]-9H-carbazole; 10-45% by weight, 15-30% by weight of T2T and 5-40% by weight, or, for example, 10-30% by weight of light emitting molecule according to embodiments of the present disclosure.

Adjacent to the light-emitting layer EML an electron transport layer (ETL) may be located. Herein, any suitable electron transporter generally available in the art may be used. For example, compounds poor of electrons such as, e.g., benzimidazoles, pyridines, triazoles, oxadiazoles (e.g., 1,3,4-oxadiazole), phosphinoxides and sulfone, may be used. An electron transporter may also be a star-shaped heterocycle such as 1,3,5-tri(1-phenyl-1H-benzo[d]imidazol-2-yl)phenyl (TPBi). The ETL may include NBphen (2,9-bis(naphthalen-2-yl)-4,7-diphenyl-1,10-phenanthroline), Alq3 (Aluminum-tris(8-hydroxyquinoline)), TSPO1 (diphenyl-4-triphenylsilylphenyl-phosphinoxide), BpyTP2 (2,7-di(2,2′-bipyridin-5-yl)triphenyle), Sif87 (dibenzo[b,d]thiophen-2-yltriphenylsilane), Sif88 (dibenzo[b,d]thiophen-2-yl)diphenylsilane), BmPyPhB (1,3-bis[3,5-di(pyridin-3-yl)phenyl]benzene) and/or BTB (4,4′-bis-[2-(4,6-diphenyl-1,3,5-triazinyl)]-1,1′-biphenyl). Optionally, the ETL may be doped with materials such as Liq. The electron transport layer (ETL) may also block holes or a hole blocking layer (HBL) is introduced.

The HBL may, for example, include BCP (2,9-dimethyl-4,7-diphenyl-1,10-phenanthroline=Bathocuproine), Balq (bis(8-hydroxy-2-methylquinoline)-(4-phenylphenoxy)aluminum), Nbphen (2,9-bis(naphthalen-2-yl)-4,7-diphenyl-1,10-phenanthroline), Alq3 (Aluminum-tris(8-hydroxyquinoline)), TSPO1 (diphenyl-4-triphenylsilylphenyl-phosphinoxide), T2T (2,4,6-tris(biphenyl-3-yl)-1,3,5-triazine), T3T (2,4,6-tris(triphenyl-3-yl)-1,3,5-triazine), TST (2,4,6-tris(9,9′-spirobifluorene-2-yl)-1,3,5-triazine), and/or TCB/TCP (1,3,5-tris(N-carbazolyl)benzol/1,3,5-tris(carbazol)-9-yl) benzene).

A cathode layer C may be located adjacent to the electron transport layer (ETL). For example, the cathode layer C may include or may consist of a metal (e.g., Al, Au, Ag, Pt, Cu, Zn, Ni, Fe, Pb, LiF, Ca, Ba, Mg, In, W, or Pd) or a metal alloy. For practical reasons, the cathode layer may also consist of (essentially) non-transparent metals such as Mg, Ca or Al. In some embodiments, the cathode layer C may also include graphite and or carbon nanotubes (CNTs). In some embodiments, the cathode layer C may also consist of nanoscalic silver wires.

An OLED may further, optionally, include a protection layer between the electron transport layer (ETL) and the cathode layer C (which may be designated as electron injection layer (EIL)). This layer may include lithium fluoride, cesium fluoride, silver, Liq (8-hydroxyquinolinolatolithium), Li₂O, BaF₂, MgO and/or NaF.

Optionally, also the electron transport layer (ETL) and/or a hole blocking layer (HBL) may include one or more host compounds.

In order to modify the emission spectrum and/or the absorption spectrum of the light-emitting layer EML further, the light-emitting layer EML may further include one or more further emitter molecule F. Such an emitter molecule F may be any suitable emitter molecule generally available in the art. For example, such an emitter molecule F is a molecule having a structure differing from the structure of the molecules according to embodiments of the present disclosure. The emitter molecule F may be a TADF emitter. In some embodiments, the emitter molecule F may be a fluorescent and/or phosphorescent emitter molecule which is able to shift the emission spectrum and/or the absorption spectrum of the light-emitting layer EML. For example, the triplet and/or singlet excitons may be transferred from the emitter molecule according to embodiments of the present disclosure to the emitter molecule F before relaxing to the ground state S0 by emitting light generally red-shifted in comparison to the light emitted by emitter molecule E. Optionally, the emitter molecule F may also provoke two-photon effects (e.g., the absorption of two photons of half the energy of the absorption maximum).

Optionally, an optoelectronic device (e.g., an OLED) may, for example, be an essentially white optoelectronic device. For example, such white optoelectronic device may include at least one (deep) blue emitter molecule and one or more emitter molecules emitting green and/or red light. Then, there may also optionally be energy transmittance between two or more molecules as described above.

As used herein, if not defined more specifically in the particular context, the designation of the colors of emitted and/or absorbed light is as follows:
violet: wavelength range of >380-420 nm;
deep blue: wavelength range of >420-480 nm;
sky blue: wavelength range of >480-500 nm;
green: wavelength range of >500-560 nm;
yellow: wavelength range of >560-580 nm;
orange: wavelength range of >580-620 nm;
red: wavelength range of >620-800 nm.

With respect to emitter molecules, such colors refer to the emission maximum. Therefore, for example, a deep blue emitter has an emission maximum in the range of from >420 to 480 nm, a sky-blue emitter has an emission maximum in the range of from >480 to 500 nm, a green emitter has an emission maximum in a range of from >500 to 560 nm, a red emitter has an emission maximum in a range of from >620 to 800 nm.

A further aspect of embodiments of the present disclosure relates to an OLED, which emits light with CIEx and CIEy color coordinates close to the CIEx (=0.131) and CIEy (=0.046) color coordinates of the primary color blue (CIEx=0.131 and CIEy=0.046) as defined by ITU-R Recommendation BT.2020 (Rec. 2020) and thus is suited for the use in Ultra High Definition (UHD) displays, e.g. UHD-TVs. Accordingly, a further aspect of embodiments of the present disclosure relates to an OLED, whose emission exhibits a CIEx color coordinate of between 0.02 and 0.30, between 0.03 and 0.25, between 0.05 and 0.20, between 0.08 and 0.18, or, for example, between 0.10 and 0.15 and/or a CIEy color coordinate of between 0.00 and 0.45, between 0.01 and 0.30, between 0.02 and 0.20, between 0.03 and 0.15, or, for example, between 0.04 and 0.10.

A further embodiment of the present disclosure relates to an OLED, which emits light with CIEx and CIEy color coordinates close to the CIEx (=0.170) and CIEy (=0.797) color coordinates of the primary color green (CIEx=0.170 and CIEy=0.797) as defined by ITU-R Recommendation BT.2020 (Rec. 2020) and thus is suited for the use in Ultra High Definition (UHD) displays, e.g., UHD-TVs. In this context, the term “close to” refers to the ranges of CIEx and CIEy coordinates provided at the end of this paragraph. In commercial applications, generally top-emitting (top-electrode is transparent) devices are used, whereas test devices as used throughout the present application represent bottom-emitting devices (bottom-electrode and substrate are transparent). Accordingly, a further aspect of embodiments of the present disclosure relates to an OLED, whose emission exhibits a CIEx color coordinate of between 0.15 and 0.45 between 0.15 and 0.35, between 0.15 and 0.30, between 0.15 and 0.25, or, for example, between 0.15 and 0.20 and/or a CIEy color coordinate of between 0.60 and 0.92, between 0.65 and 0.90, between 0.70 and 0.88, between 0.75 and 0.86, or, for example, between 0.79 and 0.84.

A further embodiment of the present disclosure relates to an OLED, which emits light with CIEx and CIEy color coordinates close to the CIEx (=0.708) and CIEy (=0.292) color coordinates of the primary color red (CIEx=0.708 and CIEy=0.292) as defined by ITU-R Recommendation BT.2020 (Rec. 2020) and thus is suited for the use in Ultra High Definition (UHD) displays, e.g., UHD-TVs. In this context, the term “close to” refers to the ranges of CIEx and CIEy coordinates provided at the end of this paragraph. In commercial applications, generally top-emitting (top-electrode is transparent) devices are used, whereas test devices as used throughout the present application represent bottom-emitting devices (bottom-electrode and substrate are transparent). Accordingly, a further aspect of embodiments of the present disclosure relates to an OLED, whose emission exhibits a CIEx color coordinate of between 0.60 and 0.88, between 0.61 and 0.83, between 0.63 and 0.78, between 0.66 and 0.76, or, for example, between 0.68 and 0.73 and/or a CIEy color coordinate of between 0.25 and 0.70, between 0.26 and 0.55, between 0.27 and 0.45, between 0.28 and 0.40, or, for example, between 0.29 and 0.35.

A further aspect of embodiments of the present disclosure relates to an OLED, which exhibits an external quantum efficiency at 14500 cd/m² of more than 10%, of more than 13%, of more than 15%, of more than 17%, or, for example, of more than 20% and/or exhibits an emission maximum between 500 and 560 nm, between 510 and 550 nm, or, for example, between 520 and 540 nm and/or exhibits an LT97 value at 14500 cd/m² of more than 100 h, more than 250 h, more than 50 h, more than 750 h, or, for example, more than 1000 h.

A further aspect of embodiments of the present disclosure relates to an OLED, which exhibits an external quantum efficiency at 1000 cd/m² of more than 8%, of more than 10%, of more than 13%, of more than 15%, or, for example, of more than 20% and/or exhibits an emission maximum between 420 and 500 nm, between 430 and 490 nm, or, for example between 440 and 480 nm and/or exhibits an LT80 value at 500 cd/m2 of more than 100 h, more than 200 h, more than 400 h, more than 750 h, or, for example, more than 1000 h.

The optoelectronic device, for example, the OLED according to embodiments of the present disclosure can be manufactured by any suitable means of vapor deposition and/or liquid processing. Accordingly, at least one layer is:
prepared by a sublimation process,
prepared by an organic vapor phase deposition process,
prepared by a carrier gas sublimation process,
solution processed or
printed.

The methods used to manufacture the optoelectronic device, for example, the OLED according to embodiments of the present disclosure, may be any suitable method generally available in the art. The different layers are individually and successively deposited on a suitable substrate by means of subsequent deposition processes. The individual layers may be deposited using the same or differing deposition methods.

Vapor deposition processes include, for example, thermal (co)evaporation, chemical vapor deposition and physical vapor deposition. For active matrix OLED display, an AMOLED backplane is used as substrate. The individual layer may be processed from solutions or dispersions employing adequate solvents. Solution deposition process include, for example, spin coating, dip coating and jet printing. Liquid processing may be carried out in an inert atmosphere (e.g., in a nitrogen atmosphere) and the solvent may be completely or partially removed by any suitable means generally available in the state of the art.

### EXAMPLES

### General Synthesis Scheme

The general synthesis scheme Ia provides a synthesis scheme for organic molecules according to formula II, wherein R¹=R²⁴, R²=R²³, R³=R²², R⁴=R²¹, R⁵=R²⁰, R⁶=R¹⁹, R⁷=R¹⁸, R^{a}=R¹⁷, R⁹=R¹⁶, R¹⁰=R¹⁵, R¹¹=R¹⁴, R¹²=R¹³:

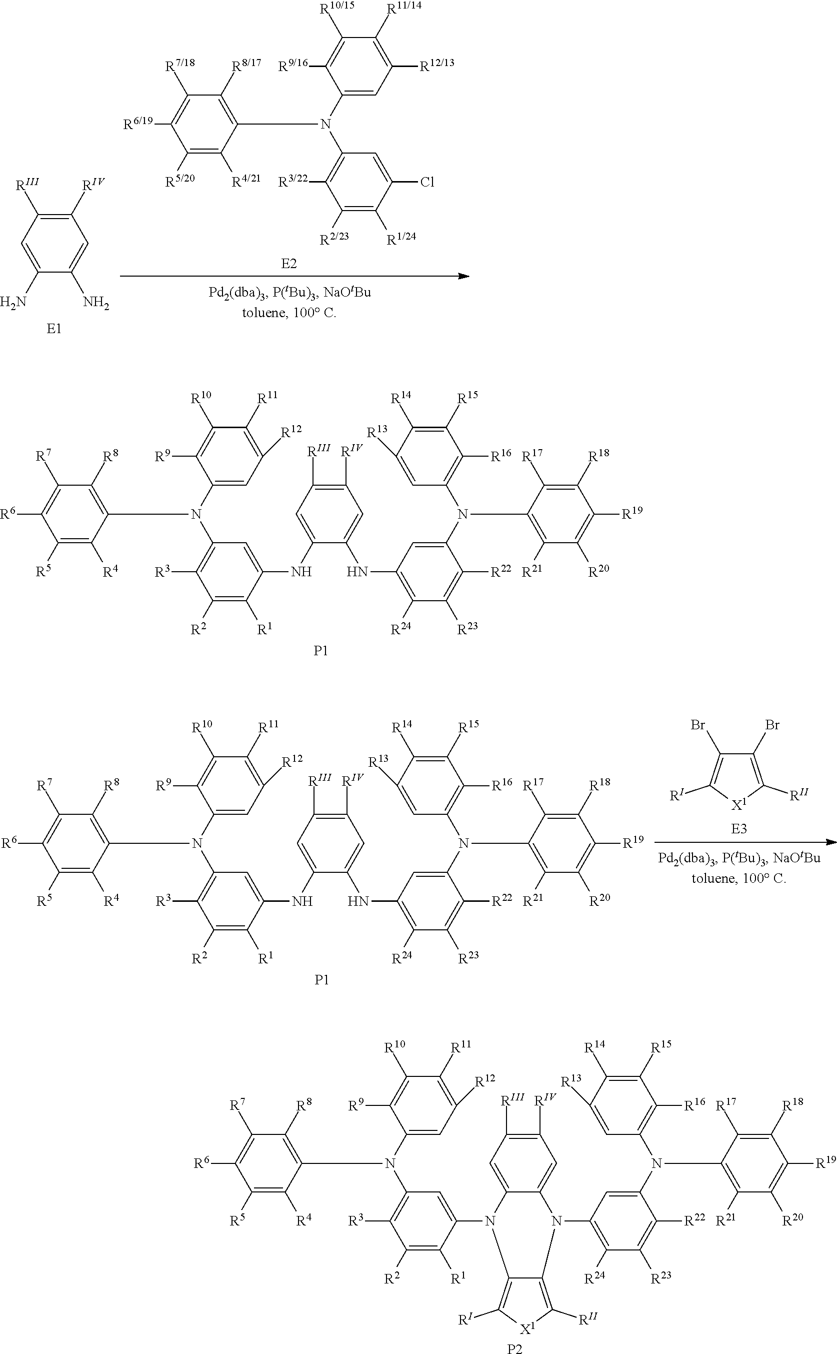

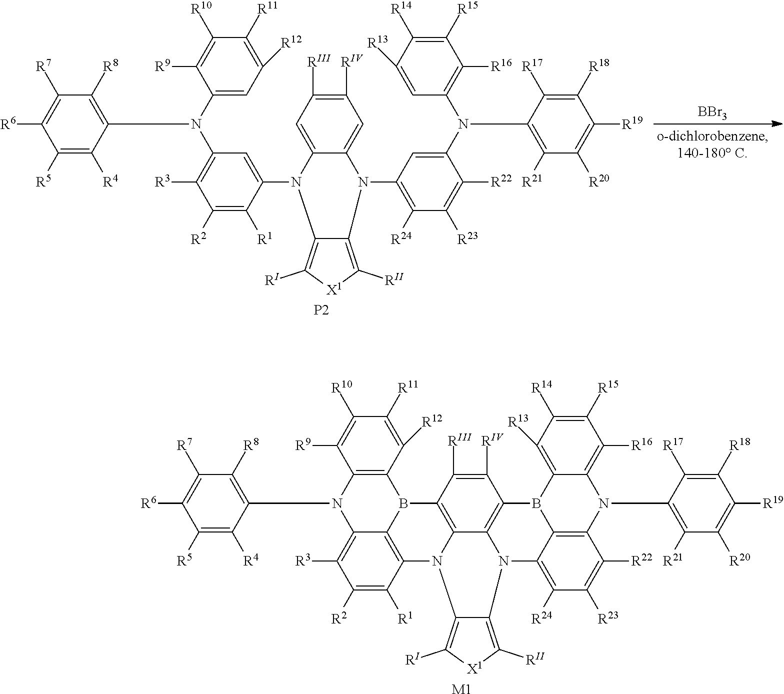

The general synthesis scheme Ib provides a synthesis scheme for organic molecules according to formula II, wherein at least one selected from the equations R¹=R²⁴,R²=R²³, R³=R²², R⁴=R²¹, R⁵=R²⁰, R⁶=R¹⁹, R⁷=R¹⁸, R⁸=R¹⁷, R⁹=R¹⁶, R¹⁰=R¹⁵, R¹¹=R¹⁴, R¹²=R¹³ is not fulfilled:

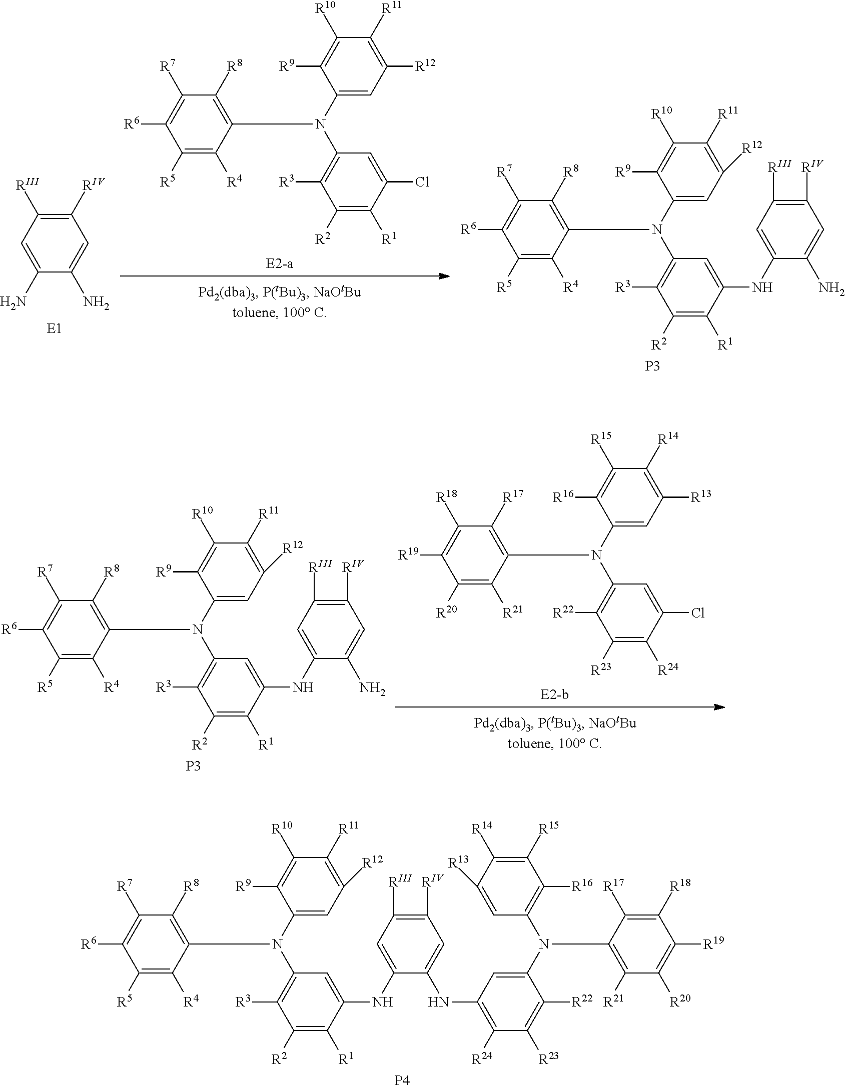

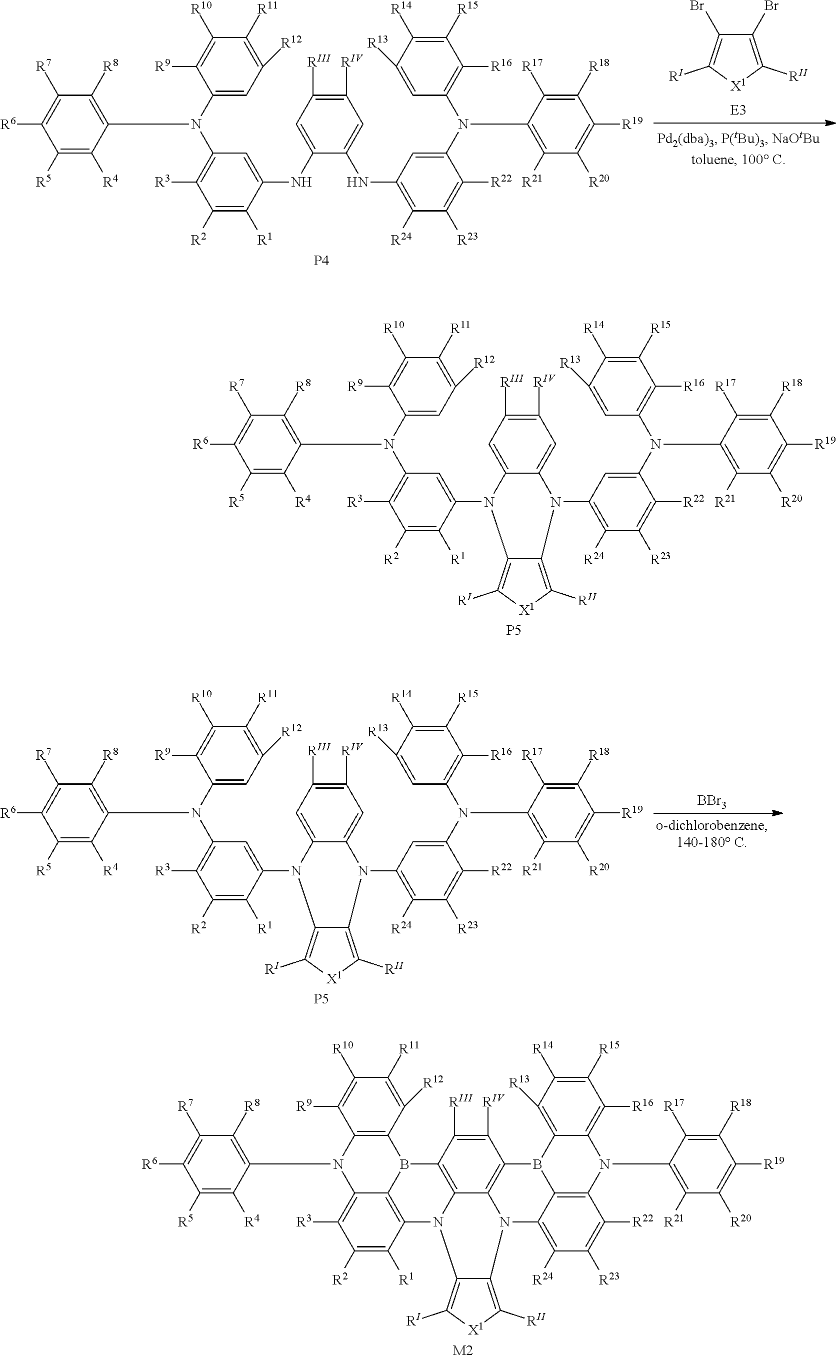

The general synthesis scheme IIa provides a synthesis scheme for organic molecules according to formula III, wherein R²⁵=R⁴⁸, R²⁶=R⁴⁷, R²⁷=R⁴⁶, R²⁸=R⁴⁵, R²⁹=R⁴⁴, R³⁰=R⁴³, R³¹=R⁴², R³²=R⁴¹, R³³=R⁴⁰, R³⁴=R³⁹, R³⁵=R³⁸, R³⁶=R³⁷:

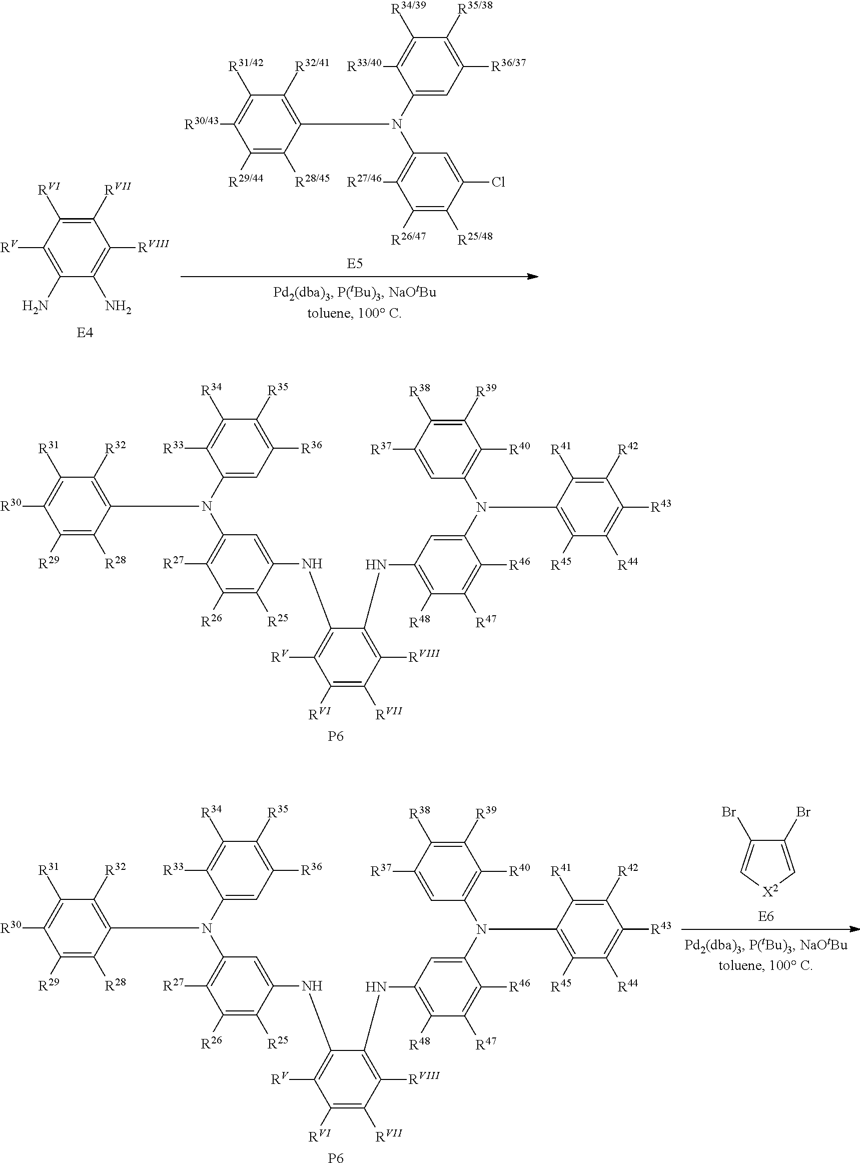

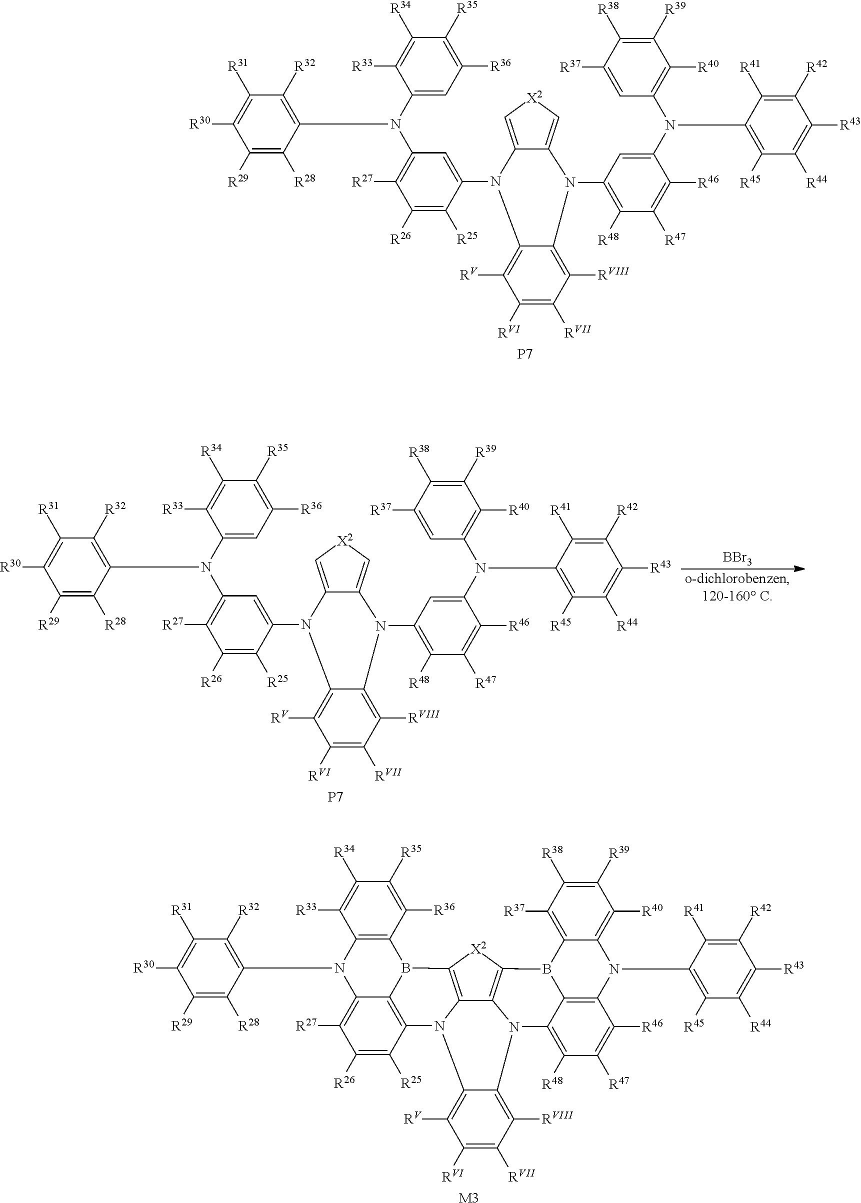

The general synthesis scheme IIb provides a synthesis scheme for organic molecules according to formula III, wherein at least one selected from the equations R²⁵=R⁴⁸, R²⁶=R⁴⁷, R²⁷=R⁴⁶, R²⁸=R⁴⁵, R²⁹=R⁴⁴, R³⁰=R⁴³, R³¹=R⁴², R³²=R⁴¹, R³³=R⁴⁰, R³⁴=R³⁹, R³⁵=R³⁸, R³⁶=R³⁷ is not fulfilled:

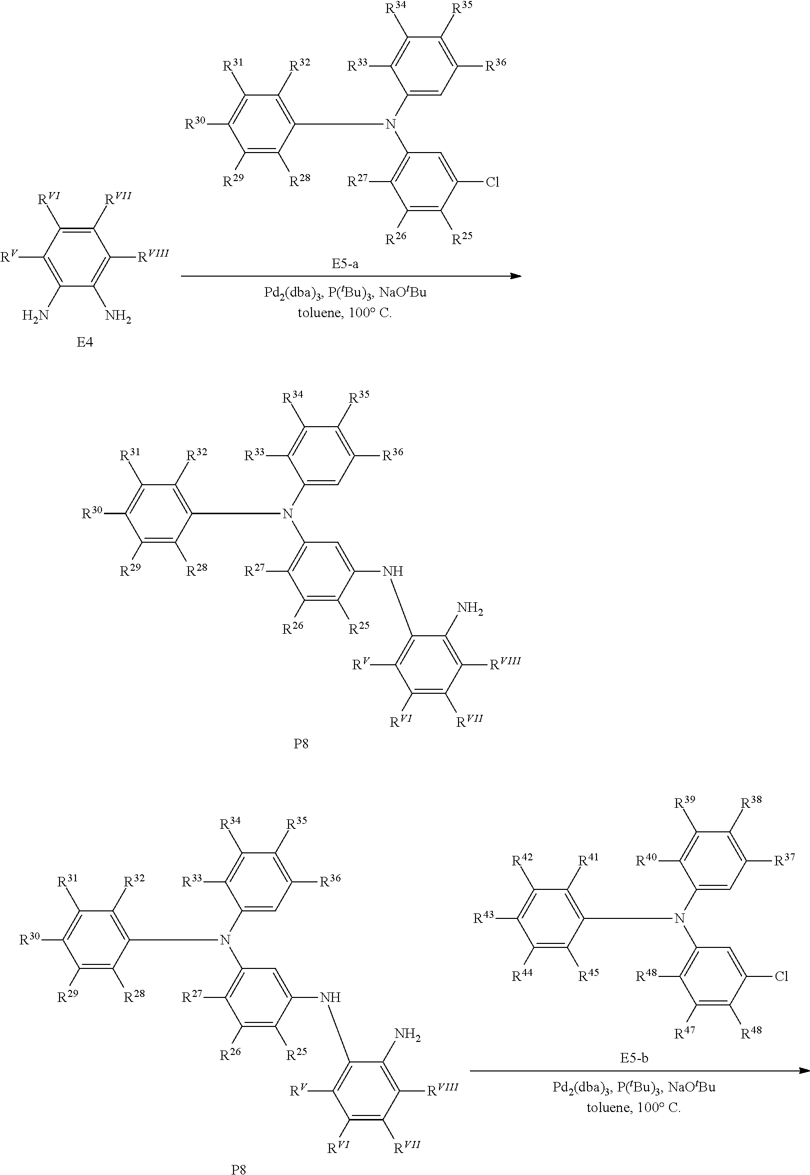

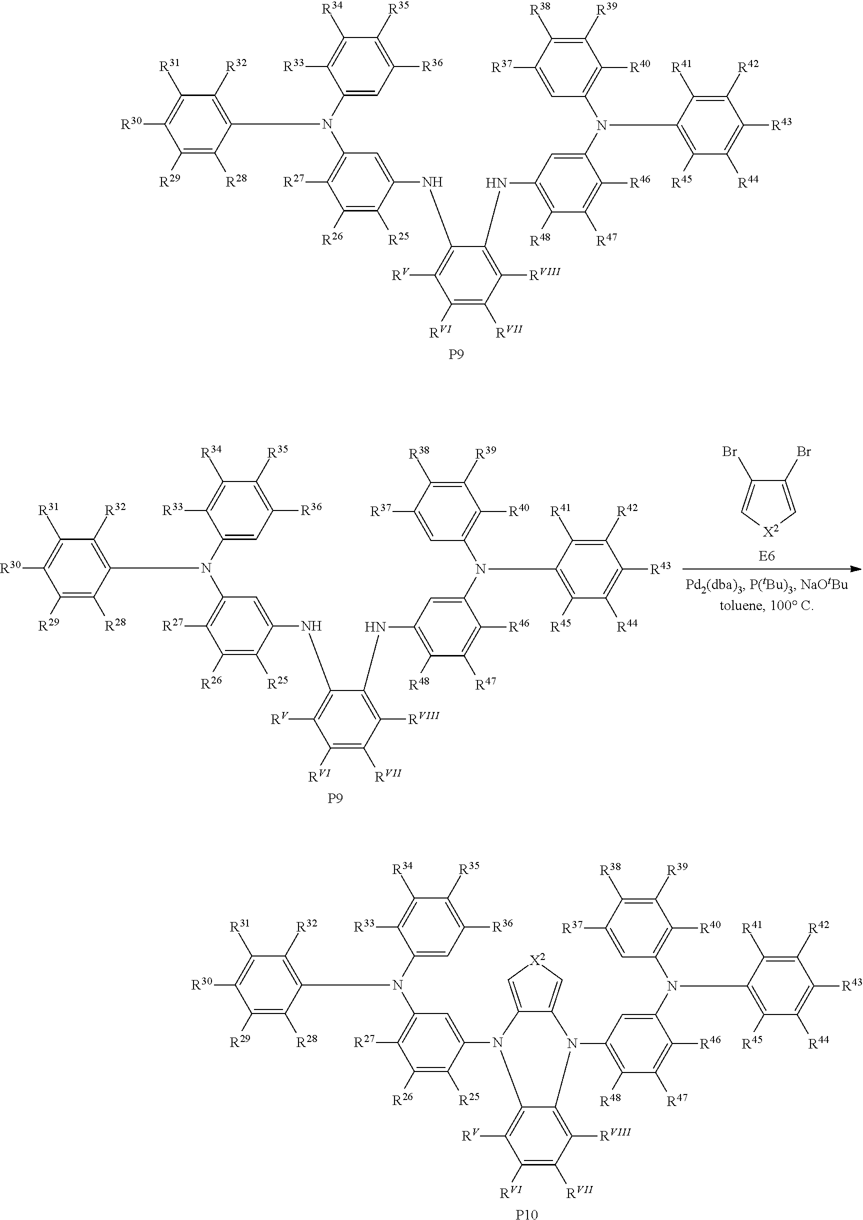

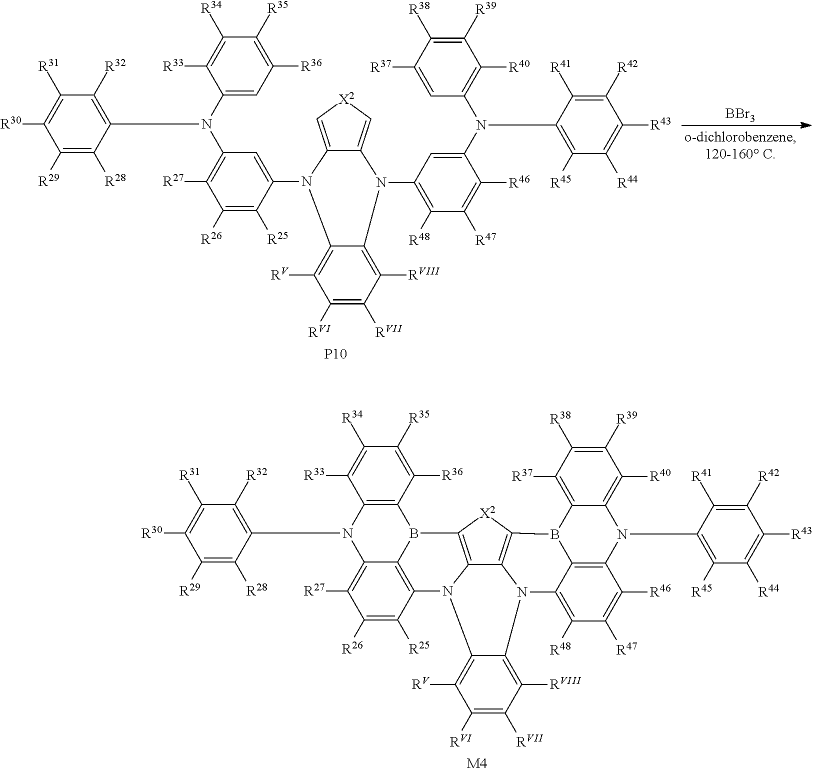

### General Procedures for Synthesis:

### Procedures for Synthesis Scheme 1a

### Procedure 1

Under nitrogen atmosphere, an o-phenylenediamine derivative E1 (1.00 equiv.), tris(dibenzylideneacetone)dipalladium(0) (Pd₂(dba)₃, CAS 51364-51-3, 0.02 equiv.), tri-tert-butylphosphine (CAS 13716-12-6, 0.08 equiv.), and sodium tert-butoxide (CAS 865-48-5, 2.50 equiv.) are dissolved in dry toluene and heated to 100° C. At this temperature, a solution of aryl chloride E2 (2.10 equiv.) in dry toluene is added dropwise and the reaction mixture is stirred overnight (approximately 15 h) at 100° C. After cooling to room temperature, the reaction is quenched by the addition of water, followed by extraction with dichloromethane and concentration under reduced pressure. The crude product is purified by MPLC or recrystallization to obtain the corresponding product P1 as a solid.

### Procedure 2

Under nitrogen atmosphere, P1 (1.00 equiv.), tris(dibenzylideneacetone)dipalladium(0) (Pd₂(dba)₃, CAS 51364-51-3, 0.02 equiv.), tri-tert-butylphosphine (CAS 13716-12-6, 0.08 equiv.), and sodium tert-butoxide (CAS 865-48-5, 2.50 equiv.) are dissolved in dry toluene and heated to 100° C. At this temperature, a solution of aryl dibromide E3 (1.10 equiv.) in dry toluene is added dropwise and the reaction mixture is stirred overnight (approximately 15 h) at 100° C. After cooling to room temperature, the reaction is quenched by the addition of water, followed by extraction with dichloromethane and concentration under reduced pressure. The crude product is purified by MPLC or recrystallization to obtain the corresponding product P2 as a solid.

### Procedure 3

Under nitrogen atmosphere, boron tribromide (CAS 10294-33-4, 3.00 equiv.) is slowly added to a solution of P2 (1.00 equiv.) in o-dichlorobenzene. The reaction mixture is stirred (approximately 15 h) at 140-180° C. and, upon cooling to room temperature, quenched by the addition of water. Extraction with dichloromethane and concentration under reduced pressure are followed by purification via MPLC or recrystallization to obtain the corresponding product M1 as a solid.

### Procedures for Synthesis Scheme 1b

### Procedure 4

Under nitrogen atmosphere, an o-phenylenediamine derivative E1 (2.00 equiv.), tris(dibenzylideneacetone)dipalladium(0) (Pd₂(dba)₃, CAS 51364-51-3, 0.01 equiv.), tri-tert-butylphosphine (CAS 13716-12-6, 0.04 equiv.), and sodium tert-butoxide (CAS 865-48-5, 1.50 equiv.) are dissolved in dry toluene and heated to 90° C. At this temperature, a solution of aryl chloride E2-a (1.00 equiv.) in dry toluene is added dropwise and the reaction mixture is stirred overnight (approximately 12 h) at 90° C. After cooling to room temperature, the reaction is quenched by the addition of water, followed by extraction with dichloromethane and concentration under reduced pressure. The crude product is purified by MPLC or recrystallization to obtain the corresponding product P3 as a solid/oil.

### Procedure 5

Under nitrogen atmosphere, P3 (1.00 equiv.), tris(dibenzylideneacetone)dipalladium(0) (Pd₂(dba)₃, CAS 51364-51-3, 0.01 equiv.), tri-tert-butylphosphine (CAS 13716-12-6, 0.04 equiv.), and sodium tert-butoxide (CAS 865-48-5, 1.50 equiv.) are dissolved in dry toluene and heated to 90° C. At this temperature, a solution of aryl chloride E2-b (1.00 equiv.) in dry toluene is added dropwise and the reaction mixture is stirred overnight (approximately 12 h) at 90° C. After cooling to room temperature, the reaction is quenched by the addition of water, followed by extraction with dichloromethane and concentration under reduced pressure. The crude product is purified by MPLC or recrystallization to obtain the corresponding product P4 as a solid.

### Procedure 6

Under nitrogen atmosphere, P4 (1.00 equiv.), tris(dibenzylideneacetone)dipalladium(0) (Pd₂(dba)₃, CAS 51364-51-3, 0.02 equiv.), tri-tert-butylphosphine (CAS 13716-12-6, 0.08 equiv.), and sodium tert-butoxide (CAS 865-48-5, 2.50 equiv.) are dissolved in dry toluene and heated to 100° C. At this temperature, a solution of aryl dibromide E3 (1.10 equiv.) in dry toluene is added dropwise and the reaction mixture is stirred overnight (approximately 15 h) at 100° C. After cooling to room temperature, the reaction is quenched by the addition of water, followed by extraction with dichloromethane and concentration under reduced pressure. The crude product is purified by MPLC or recrystallization to obtain the corresponding product P5 as a solid.

### Procedure 7

Under nitrogen atmosphere, boron tribromide (CAS 10294-33-4, 3.00 equiv.) is slowly added to a solution of P5 (1.00 equiv.) in o-dichlorobenzene. The reaction mixture is stirred (approximately 15 h) at 140-180° C. and, upon cooling to room temperature, quenched by the addition of water. Extraction with dichloromethane and concentration under reduced pressure are followed by purification via MPLC or recrystallization to obtain the corresponding product M2 as a solid.

### Procedures for Synthesis Scheme IIa

### Procedure 8

Under nitrogen atmosphere, an o-phenylenediamine derivative E4 (1.00 equiv.), tris(dibenzylideneacetone)dipalladium(0) (Pd₂(dba)₃, CAS 51364-51-3, 0.02 equiv.), tri-tert-butylphosphine (CAS 13716-12-6, 0.08 equiv.), and sodium tert-butoxide (CAS 865-48-5, 2.50 equiv.) are dissolved in dry toluene and heated to 100° C. At this temperature, a solution of aryl chloride E5 (2.10 equiv.) in dry toluene is added dropwise and the reaction mixture is stirred overnight (approximately 15 h) at 100° C. After cooling to room temperature, the reaction is quenched by the addition of water, followed by extraction with dichloromethane and concentration under reduced pressure. The crude product is purified by MPLC or recrystallization to obtain the corresponding product P6 as a solid.

### Procedure 9

Under nitrogen atmosphere, P6 (1.00 equiv.), tris(dibenzylideneacetone)dipalladium(0) (Pd₂(dba)₃, CAS 51364-51-3, 0.02 equiv.), tri-tert-butylphosphine (CAS 13716-12-6, 0.08 equiv.), and sodium tert-butoxide (CAS 865-48-5, 2.50 equiv.) are dissolved in dry toluene and heated to 100° C. At this temperature, a solution of aryl dibromide E6 (1.10 equiv.) in dry toluene is added dropwise and the reaction mixture is stirred overnight (approximately 15 h) at 100° C. After cooling to room temperature, the reaction is quenched by the addition of water, followed by extraction with dichloromethane and concentration under reduced pressure. The crude product is purified by MPLC or recrystallization to obtain the corresponding product P7 as a solid.

### Procedure 10

Under nitrogen atmosphere, boron tribromide (CAS 10294-33-4, 3.00 equiv.) is slowly added to a solution of P7 (1.00 equiv.) in o-dichlorobenzene. The reaction mixture is stirred (approximately 15 h) at 120-160° C. and, upon cooling to room temperature, quenched by the addition of water. Extraction with dichloromethane and concentration under reduced pressure are followed by purification via MPLC or recrystallization to obtain the corresponding product M3 as a solid.

### Procedures for Synthesis Scheme IIb

### Procedure 11

Under nitrogen atmosphere, an o-phenylenediamine derivative E4 (2.0 equiv.), tris(dibenzylideneacetone)dipalladium(0) (Pd₂(dba)₃, CAS 51364-51-3, 0.01 equiv.), tri-tert-butylphosphine (CAS 13716-12-6, 0.04 equiv.), and sodium tert-butoxide (CAS 865-48-5, 1.50 equiv.) are dissolved in dry toluene and heated to 90° C. At this temperature, a solution of aryl chloride E5-a (1.00 equiv.) in dry toluene is added dropwise and the reaction mixture is stirred overnight (approximately 12 h) at 90° C. After cooling to room temperature, the reaction is quenched by the addition of water, followed by extraction with dichloromethane and concentration under reduced pressure. The crude product is purified by MPLC or recrystallization to obtain the corresponding product P8 as a solid/oil.

### Procedure 12

Under nitrogen atmosphere, P8 (1.00 equiv.), tris(dibenzylideneacetone)dipalladium(0) (Pd₂(dba)₃, CAS 51364-51-3, 0.01 equiv.), tri-tert-butylphosphine (CAS 13716-12-6, 0.04 equiv.), and sodium tert-butoxide (CAS 865-48-5, 1.50 equiv.) are dissolved in dry toluene and heated to 90° C. At this temperature, a solution of aryl chloride E5-b (1.00 equiv.) in dry toluene is added dropwise and the reaction mixture is stirred overnight (approximately 12 h) at 90° C. After cooling to room temperature, the reaction is quenched by the addition of water, followed by extraction with dichloromethane and concentration under reduced pressure. The crude product is purified by MPLC or recrystallization to obtain the corresponding product P9 as a solid.

### Procedure 13

Under nitrogen atmosphere, P9 (1.00 equiv.), tris(dibenzylideneacetone)dipalladium(0) (Pd₂(dba)₃, CAS 51364-51-3, 0.02 equiv.), tri-tert-butylphosphine (CAS 13716-12-6, 0.08 equiv.), and sodium tert-butoxide (CAS 865-48-5, 2.50 equiv.) are dissolved in dry toluene and heated to 100° C. At this temperature, a solution of aryl dibromide E6 (1.10 equiv.) in dry toluene is added dropwise and the reaction mixture is stirred overnight (approximately 15 h) at 100° C. After cooling to room temperature, the reaction is quenched by the addition of water, followed by extraction with dichloromethane and concentration under reduced pressure. The crude product is purified by MPLC or recrystallization to obtain the corresponding product P10 as a solid.

### Procedure 14

Under nitrogen atmosphere, boron tribromide (CAS 10294-33-4, 3.00 equiv.) is slowly added to a solution of P10 (1.00 equiv.) in o-dichlorobenzene. The reaction mixture is stirred (approximately 15 h) at 140-180° C. and, upon cooling to room temperature, quenched by the addition of water. Extraction with dichloromethane and concentration under reduced pressure are followed by purification via MPLC or recrystallization to obtain the corresponding product M4 as a solid.

The synthesis of the 3-chloro-N,N-diphenylaniline derivatives E2, E2-a, E2-b, E-5, E-5a, and E5-b can be achieved by means of classical Pd-catalyzed cross-coupling reactions (cf. the Buchwald Hartwig coupling), which should be readily apparent to a person skilled in the art upon reviewing this disclosure.

### Cyclic Voltammetry

Cyclic voltammograms are measured from solutions having concentration of 10³ mol/L of the organic molecules in dichloromethane or a suitable solvent and a suitable supporting electrolyte (e.g., 0.1 mol/L of tetrabutylammonium hexafluorophosphate). The measurements are conducted at room temperature under nitrogen atmosphere with a three-electrode assembly (Working and counter electrodes: Pt wire, reference electrode: Pt wire) and calibrated using FeCp₂/FeCp₂⁺ as internal standard. The HOMO data was corrected using ferrocene as internal standard against a saturated calomel electrode (SCE).

### Density Functional Theory Calculation

Molecular structures are optimized employing the BP86 functional and the resolution of identity approach (RI). Excitation energies are calculated using the (BP86) optimized structures employing Time-Dependent Density Functional Theory (TD-DFT) methods. Orbital and excited state energies are calculated with the B3LYP functional. Def2-SVP basis sets (and a m4-grid for numerical integration) are used. The Turbomole program package is used for all calculations.

### Photophysical Measurements

Sample pretreatment: Spin-coating
Apparatus: Spin150, SPS euro.

The sample concentration is 0.2 mg/ml, dissolved in Toluene/DCM a suitable solvent.

Program: 7-30 sec. at 2000 U/min. After coating, the films are tried at 70° C. for 1 min.

### Photoluminescence Spectroscopy and Phosphorescence Spectroscopy

For the analysis of Phosphorescence and Photoluminescence spectroscopy a fluorescence spectrometer “Fluoromax 4P” from Horiba is used.

### Time-Resolved PL Spectroscopy in the Ps-Range and Ns-Range (FS5)

Time-resolved PL measurements were performed on a FS5 fluorescence spectrometer from Edinburgh Instruments. Compared to measurements on the HORIBA setup, better light gathering allows for an optimized signal to noise ratio, which favors the FS5 system especially for transient PL measurements of delayed fluorescence characteristics. As continuous light source, the spectrometer includes a

150W xenon arc lamp and set or specific wavelengths may be selected by a Czerny-Turner monochromator. However, the standard measurements were instead performed using an external VPLED variable pulsed LED with an emission wavelength of 310 nm. The sample emission is directed towards a sensitive R928P photomultiplier tube (PMT), allowing the detection of single photons with a peak quantum efficiency of up to 25% in the spectral range between 200 nm to 870 nm. The detector is a temperature stabilized PMT, providing dark counts below 300 cps (counts per second). Finally, to determine the transient decay lifetime of the delayed fluorescence, a tail fit using three exponential functions is applied. By weighting the specific lifetimes T, with their corresponding amplitudes Aᵢ,

$${τ}_{DF} = {\sum }_{i = 1}^{3} \frac{{A}_{i} {τ}_{i}}{{A}_{i}}$$

the delayed fluorescence lifetime T_{DF} is determined.

### Photoluminescence Quantum Yield Measurements

For photoluminescence quantum yield (PLQY) measurements an Absolute PL Quantum Yield Measurement C₉₉₂₀-03G system (Hamamatsu Photonics) is used. Quantum yields and CIE coordinates are determined using the software U6039-05 version 3.6.0.

Emission maxima are given in nm, quantum yields CD in % and CIE coordinates as x,y values.

PLQY is determined using the following protocol:

Quality assurance: Anthracene in ethanol (set concentration) is used as reference

Excitation wavelength: the absorption maximum of the organic molecule is determined and the molecule is excited using this wavelength

### Measurement

Quantum yields are measured for sample of films (2% by weight of the emitter in PMMA) under nitrogen atmosphere. The yield is calculated using the equation:

$${Φ}_{PL} = \frac{{n}_{photon} , emitted}{{n}_{photon} , absorbed} = \frac{\int \frac{λ}{hc} [ {Int}_{emitted}^{sample} ( λ ) - {Int}_{absorbed}^{sample} ( λ ) ] d λ}{\int \frac{λ}{hc} [ {Int}_{emitted}^{reference} ( λ ) - {Int}_{absorbed}^{reference} ( λ ) ] d λ}$$

wherein nₚₕₒₜₒₙ denotes the photon count and Int. the intensity.

### Production and Characterization of Optoelectronic Devices

Optoelectronic devices, such as OLED devices, including organic molecules according to embodiments of the present disclosure can be produced via vacuum-deposition methods. If a layer contains more than one compound, the weight-percentage of one or more compounds is given in %. The total weight-percentage values amount to 100%, thus if a value is not given, the fraction of this compound equals to the difference between the given values and 100%.

The (not fully optimized) OLEDs are characterized using standard methods and measuring electroluminescence spectra, the external quantum efficiency (in %) in dependency on the intensity, calculated using the light detected by the photodiode, and the current. The OLED device lifetime is extracted from the change of the luminance during operation at constant current density. The LT50 value corresponds to the time, where the measured luminance decreased to 50% of the initial luminance, analogously LT80 corresponds to the time point, at which the measured luminance decreased to 80% of the initial luminance, LT 95 to the time point, at which the measured luminance decreased to 95% of the initial luminance etc.

Accelerated lifetime measurements are performed (e.g., applying increased current densities). For example, LT80 values at 500 cd/m² are determined using the following equation:

$$LT 80 ( 500 \frac{cd}{{m}^{2}} ) = LT 80 ( {L}_{0} ) {( \frac{{L}_{0}}{500 \frac{cd}{{m}^{2}}} )}^{1.6}$$

wherein L₀ denotes the initial luminance at the applied current density.

The values correspond to the average of several pixels (generally two to eight), the standard deviation between these pixels is given.

### HPLC-MS

This analysis is performed on an HPLC-MS by Agilent (HPLC1260 Infinity) with MS-detector (Single Quadrupole).

For example, an HPLC method is as follows: a reverse phase column 3.0 mm×100 mm, particle size 2.7 μm from Agilent (Poroshell 120EC-C18, 3.0×100 mm, 2.7 μm HPLC column) is used in the HPLC. The HPLC-MS measurements are performed at 45° C. and a gradient is as follows:

| Flow rate [ml/min] | Time [min] | A[%] | B[%] | C[%] |
|---|---|---|---|---|
| 2.1 | 0.0 | 40 | 50 | 10 |
| 2.1 | 1.00 | 40 | 50 | 10 |
| 2.1 | 3.50 | 10 | 65 | 25 |
| 2.1 | 6.00 | 10 | 40 | 50 |
| 2.1 | 8.00 | 10 | 10 | 80 |
| 2.1 | 11.50 | 10 | 10 | 80 |
| 2.1 | 11.51 | 40 | 50 | 10 |
| 2.1 | 12.50 | 40 | 50 | 10 |

and the following solvent mixtures (all solvents contain 0.1% (VN) of formic acid):

| | | |
|---|---|---|
| Solvent A: | H₂O (10%) | MeCN (90%) |
| Solvent B: | H₂O (90%) | MeCN (10%) |
| Solvent C: | THF (50%) | MeCN (50%) |

An injection volume of 2 μL of a solution with a concentration of 0.5 mg/mL of the analyte is used for the measurements.

Ionization of the probe is performed using an atmospheric pressure chemical ionization (APCI) source either in positive (APCI+) or negative (APCI−) ionization mode or an atmospheric pressure photoionization (APPI) source.

### Example 1

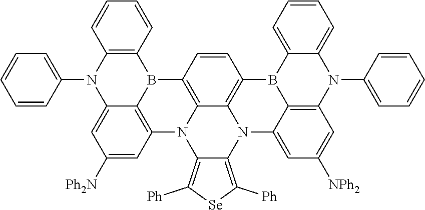

Example 1 was synthesized according to the general procedure for synthesis (according to synthesis scheme Ia), wherein o-phenylenediamine, 5-chloro-N¹,N¹,N³,N³-tetraphenyl-benzene-1,3-diamine, and 3,4-dibromo-2,5-diphenylselenophene were used as reactants E1, E2, and E3, respectively.

### Example 2

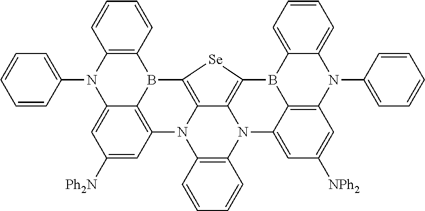

Example 1 was synthesized according to the general procedure for synthesis (according to synthesis scheme IIa), wherein o-phenylenediamine, 5-chloro-N¹,N¹,N³,N³-tetraphenyl-benzene-1,3-diamine, and 3,4-dibromoselenophene were used as reactants E4, E5, and E6, respectively.

### Additional Examples of Organic Molecules of Embodiments of the Present Disclosure

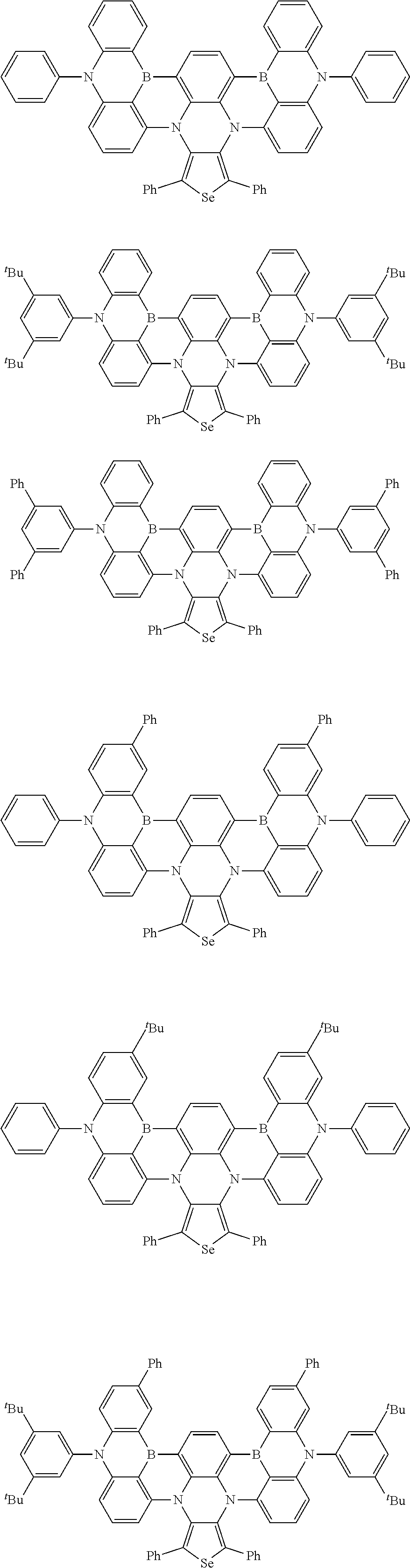

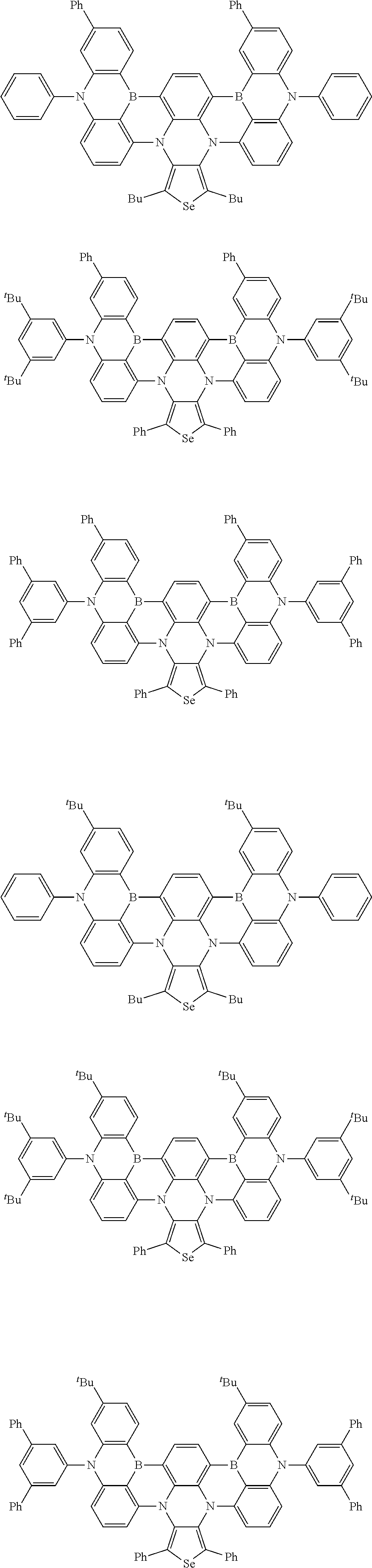

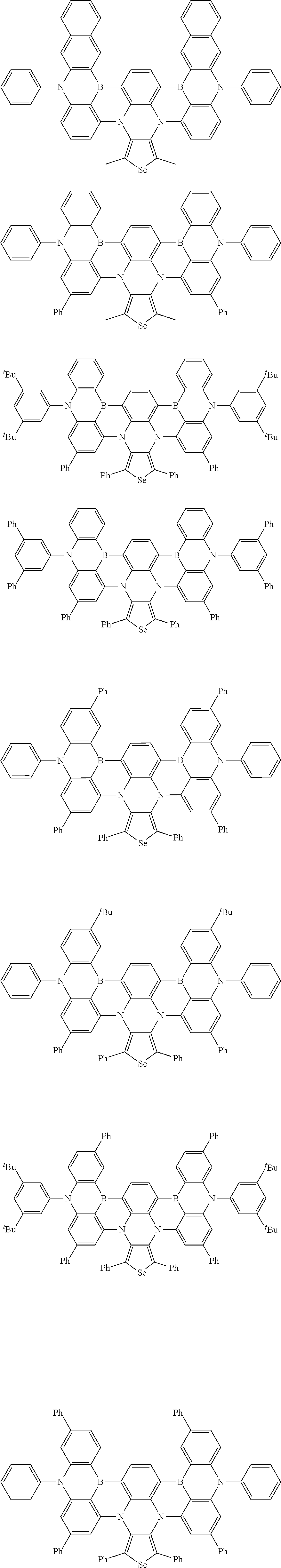

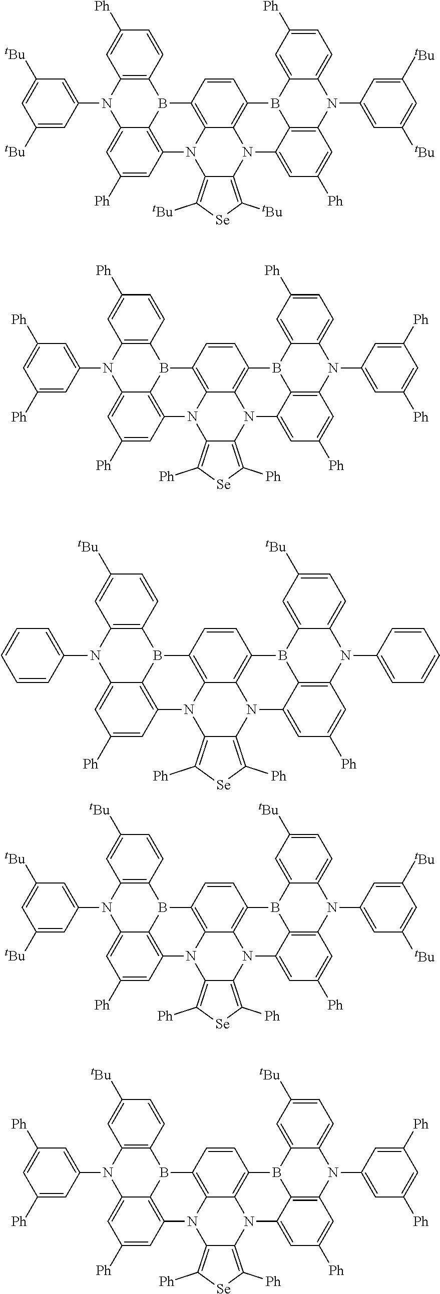

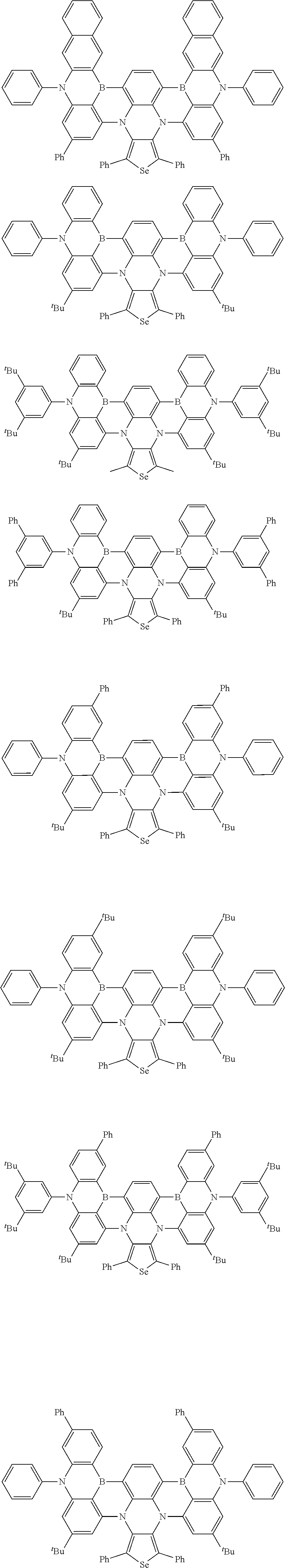

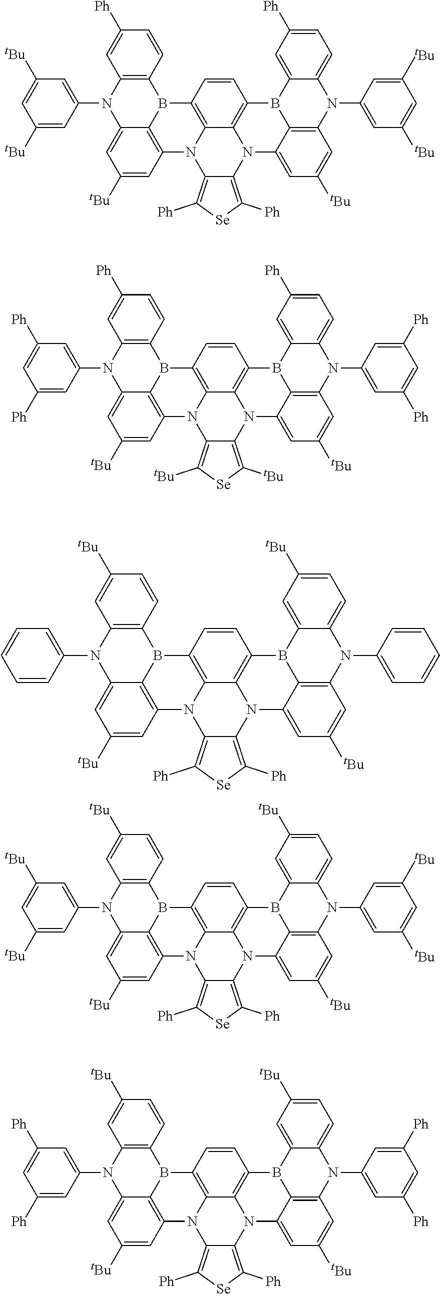

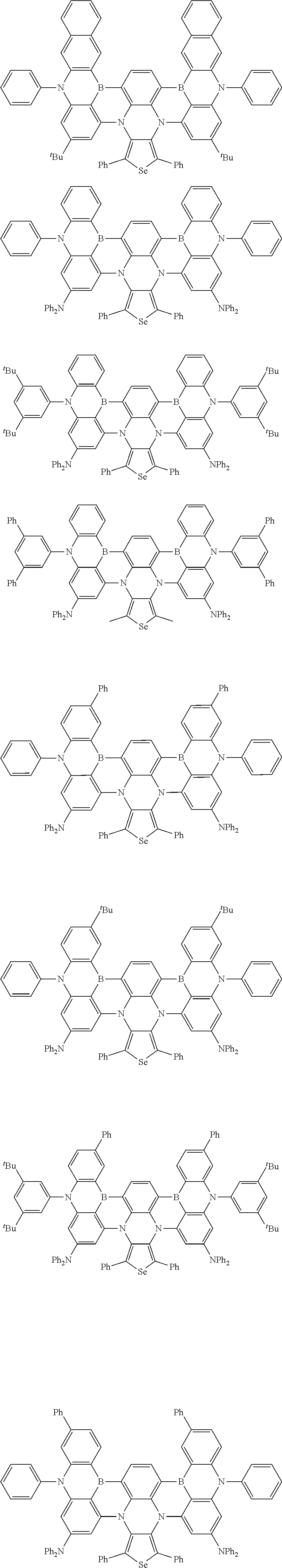

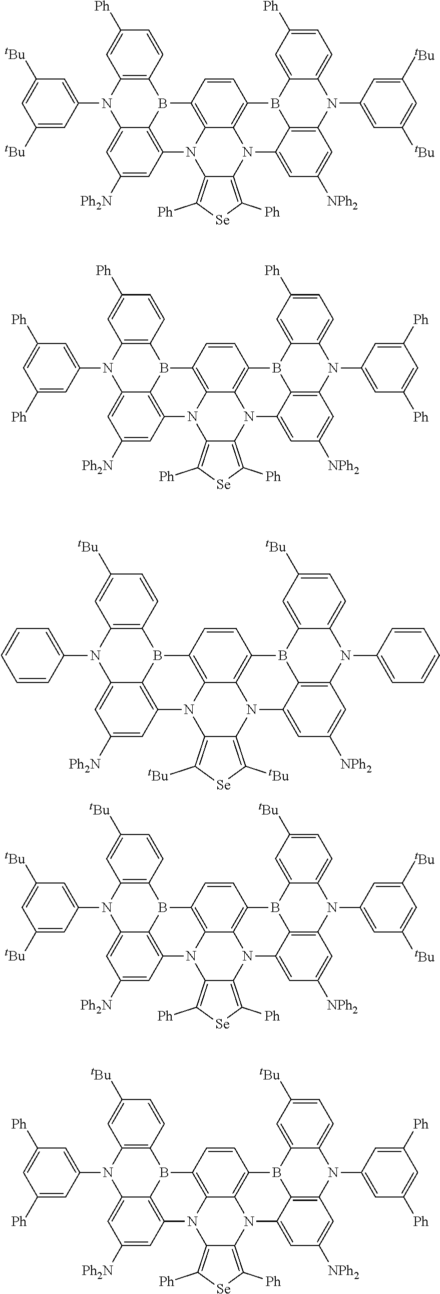

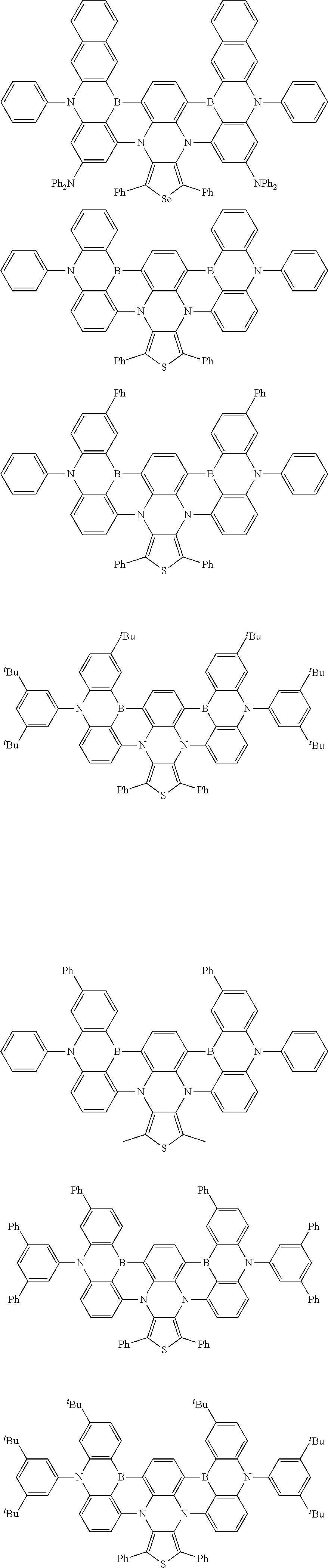

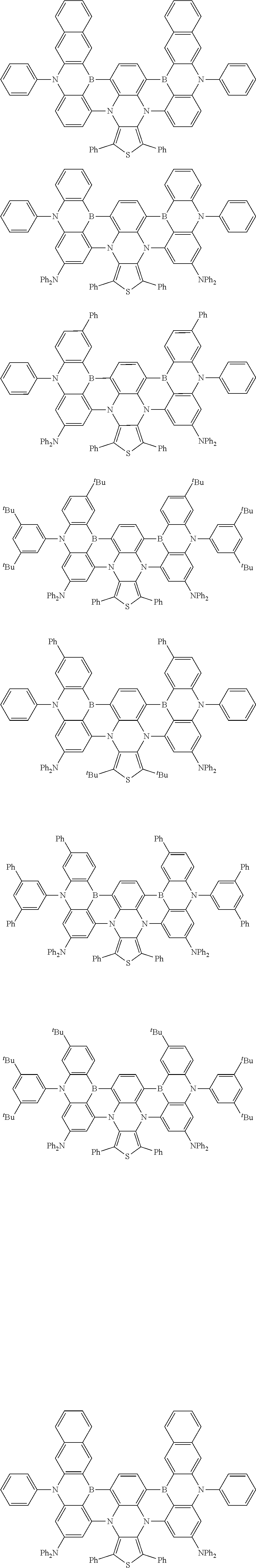

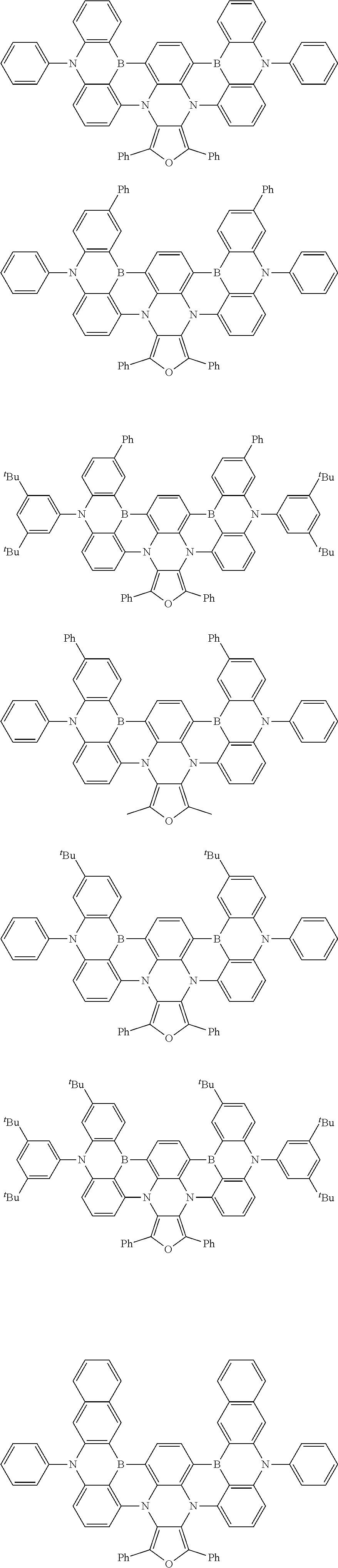

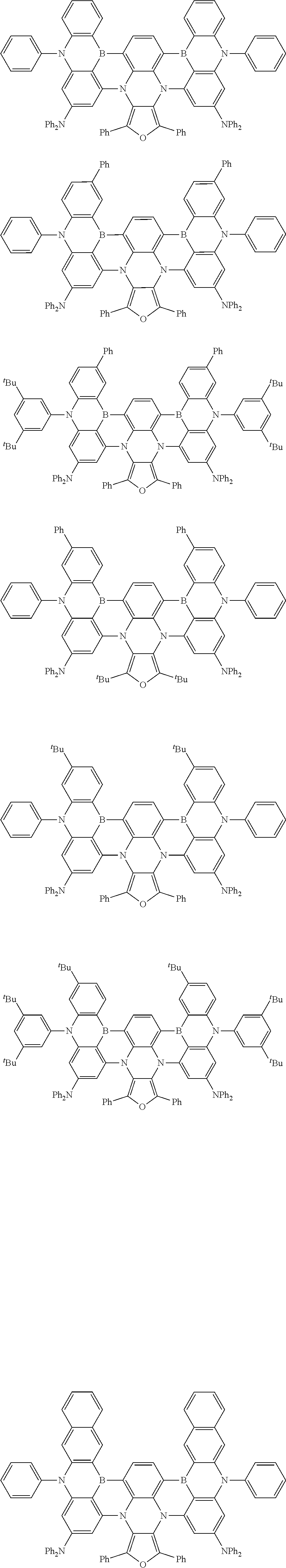

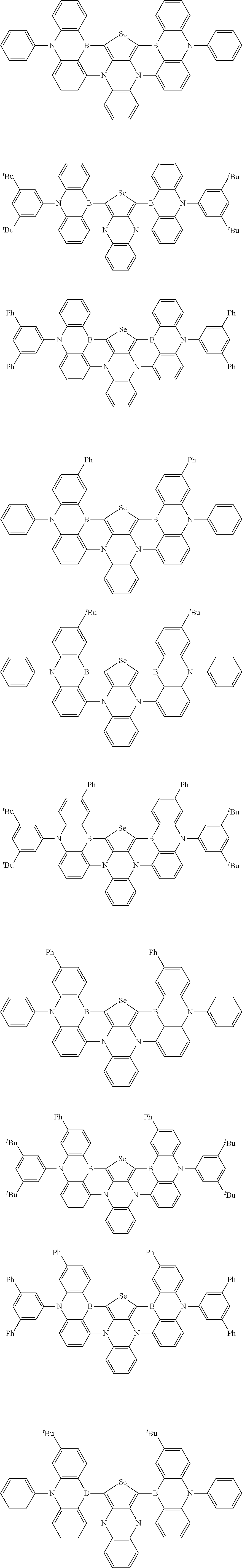

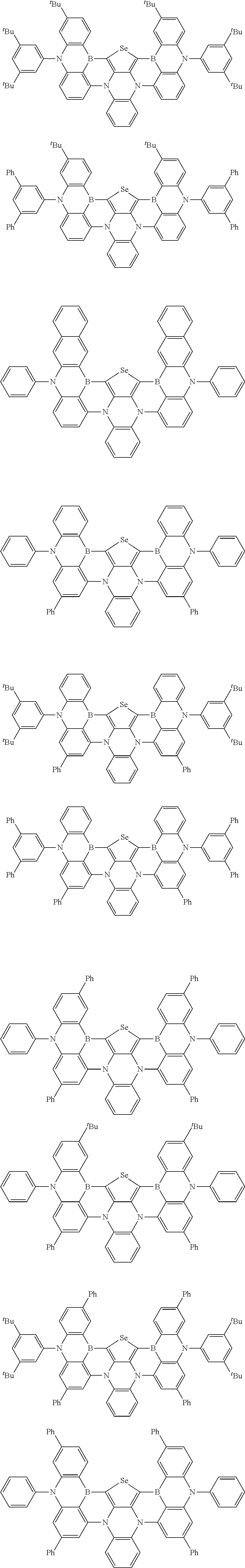

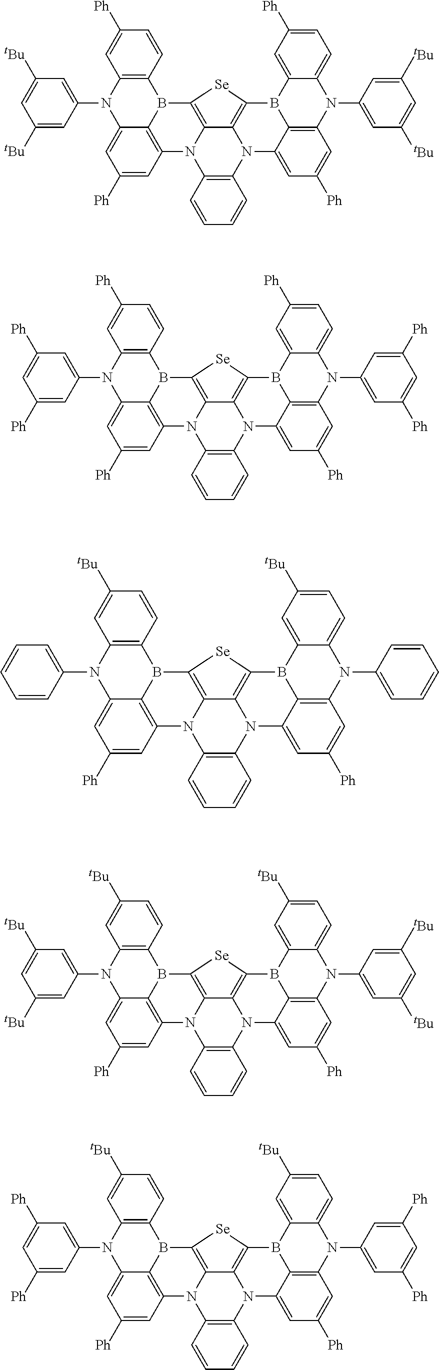

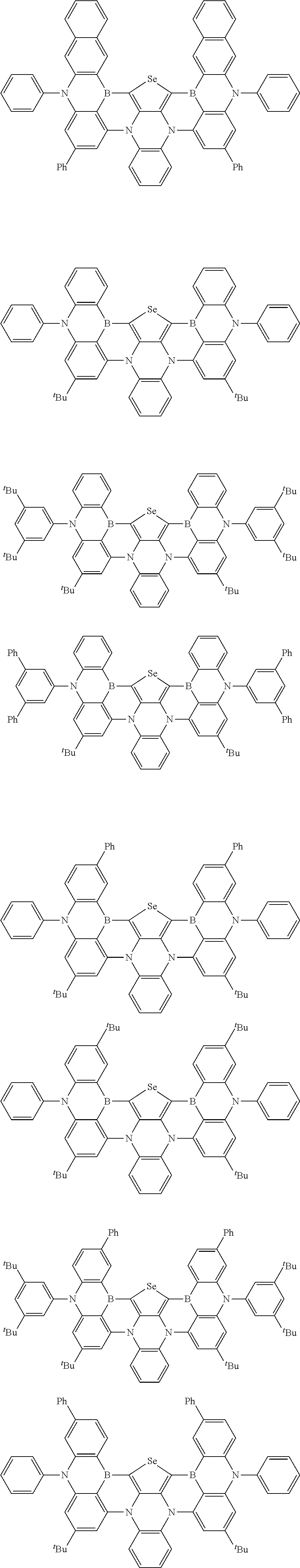

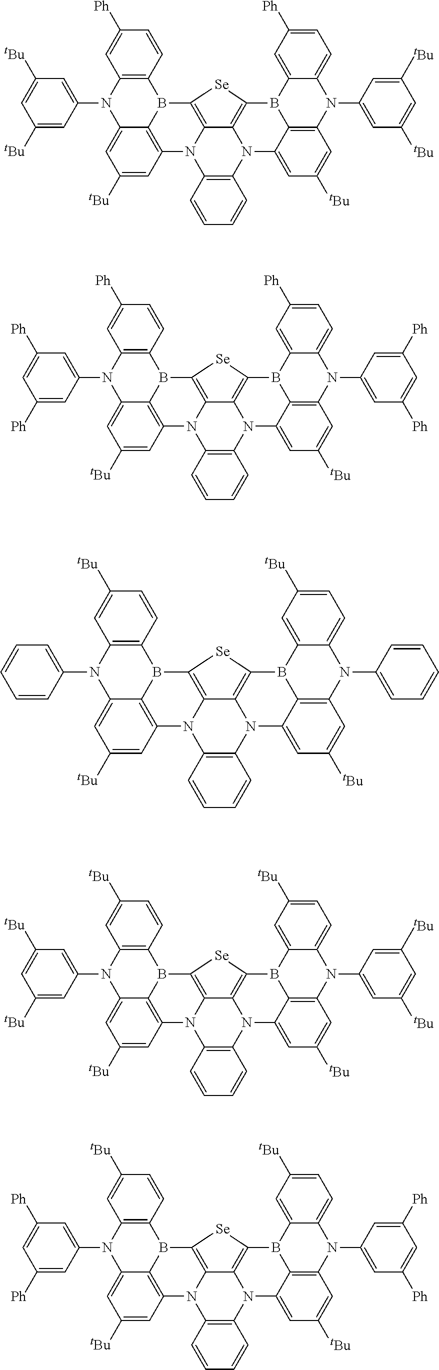

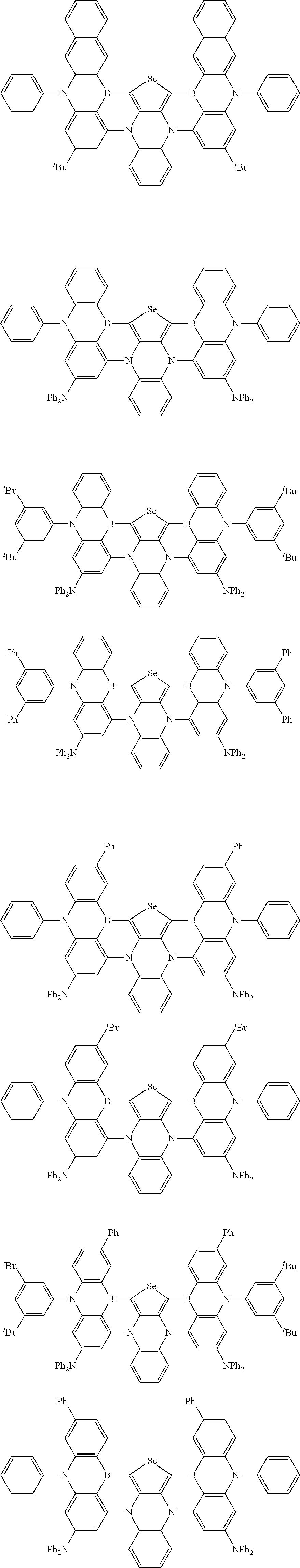

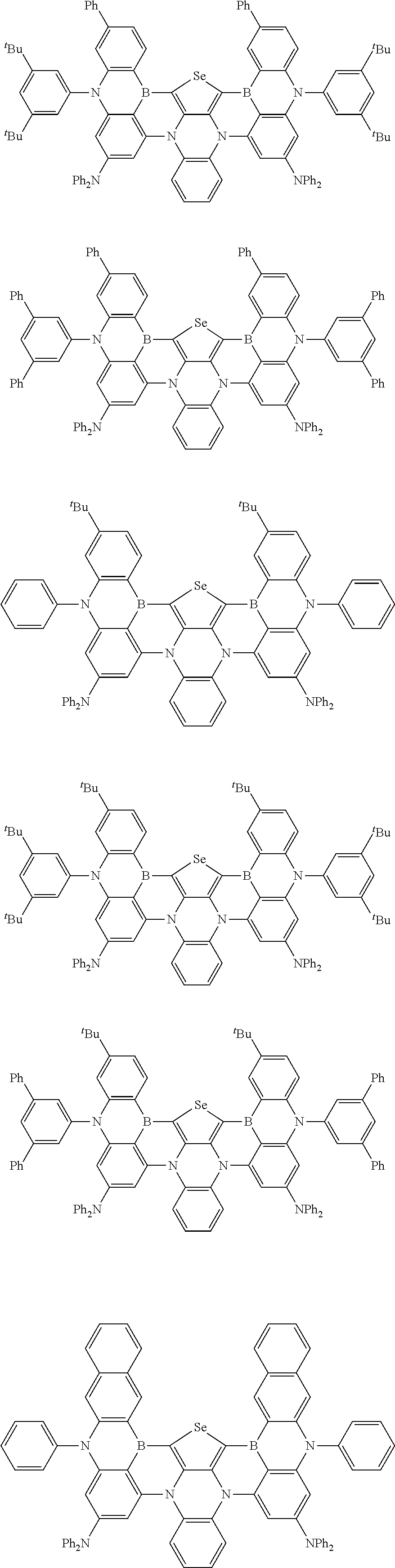

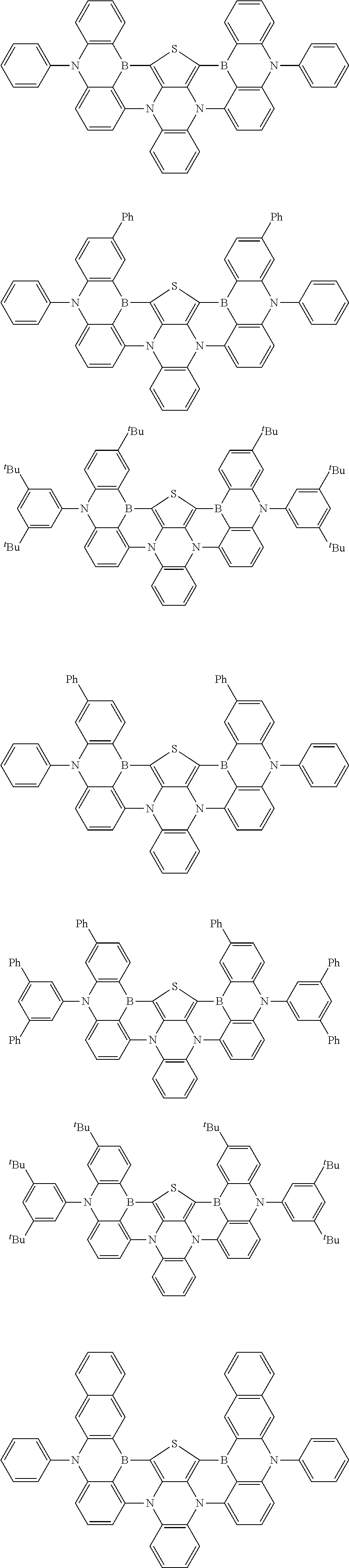

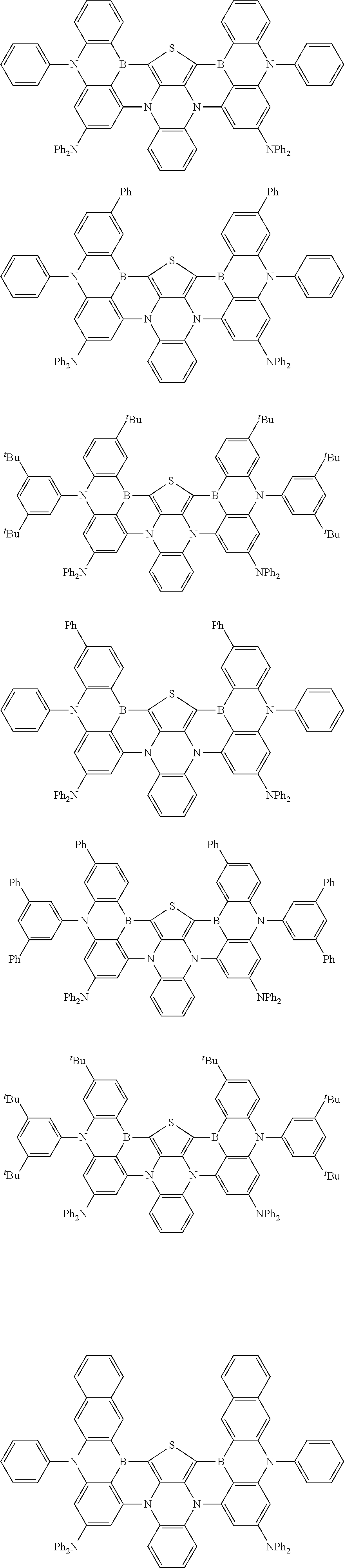

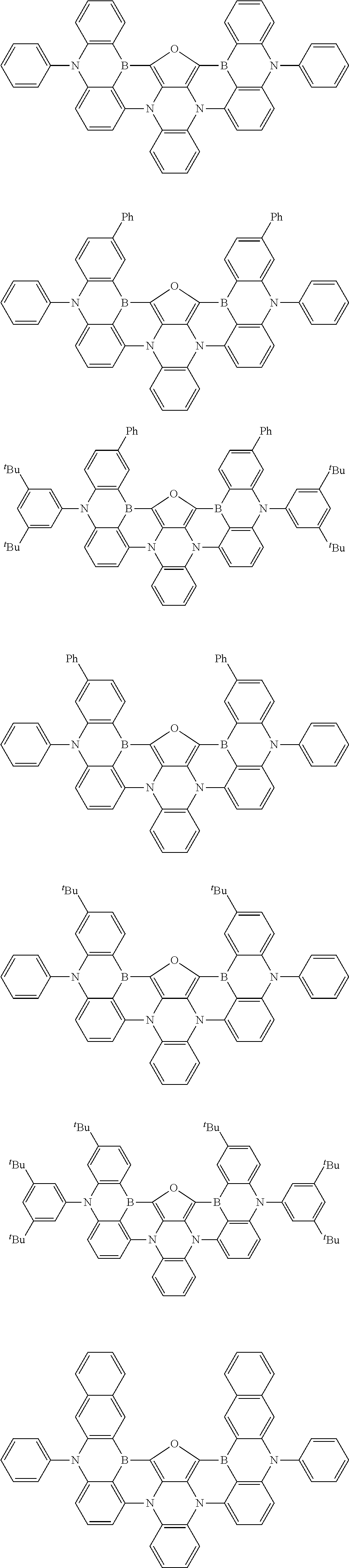

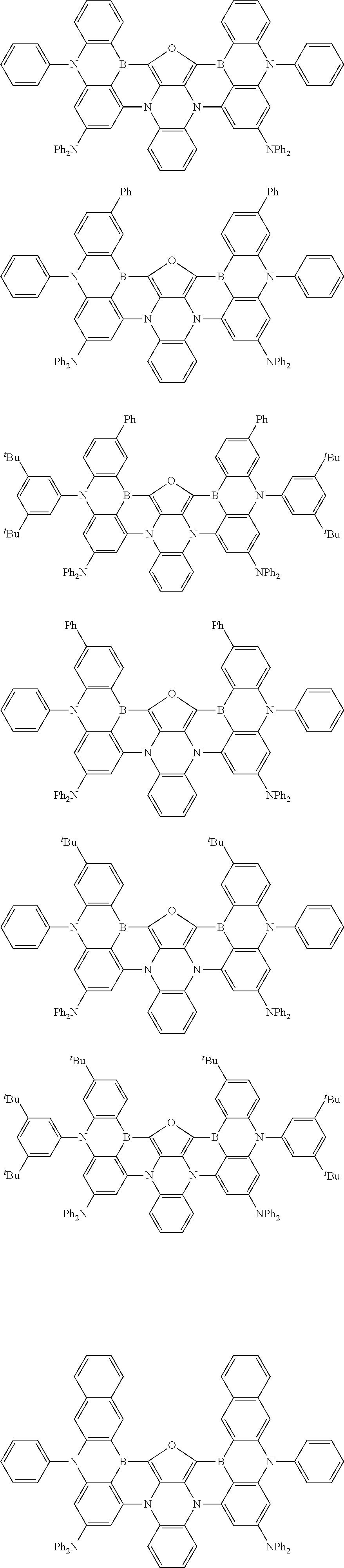

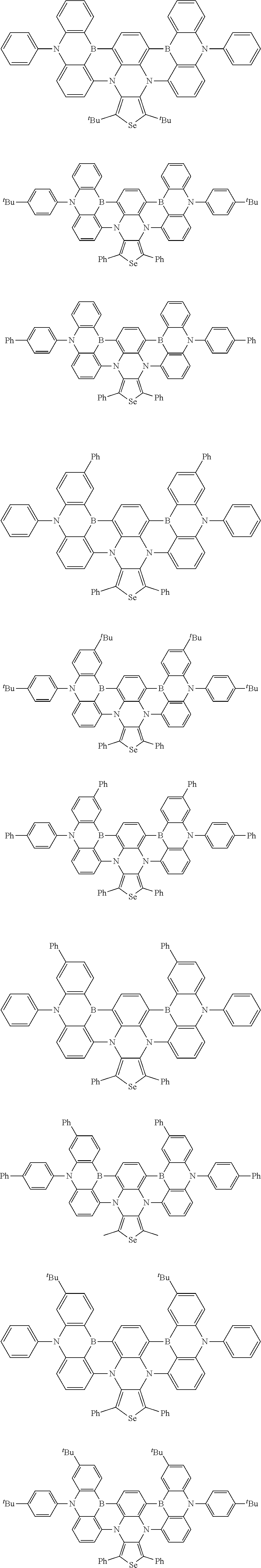

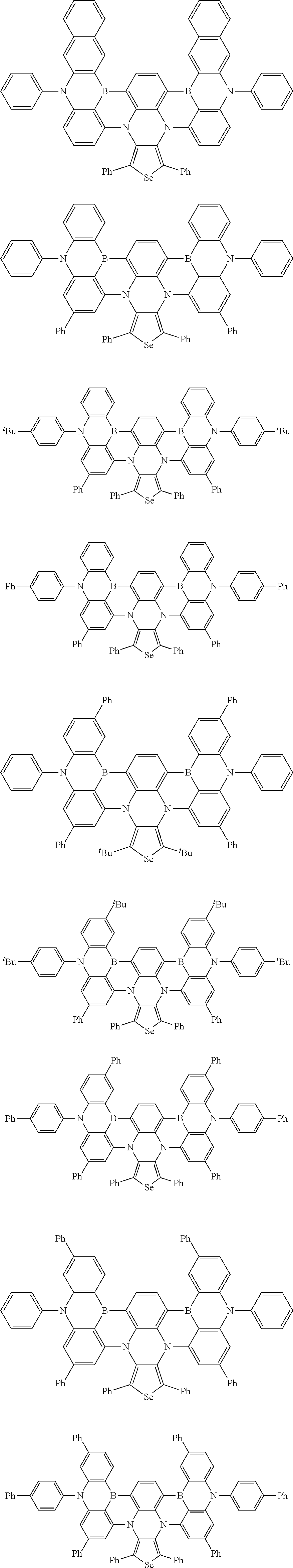

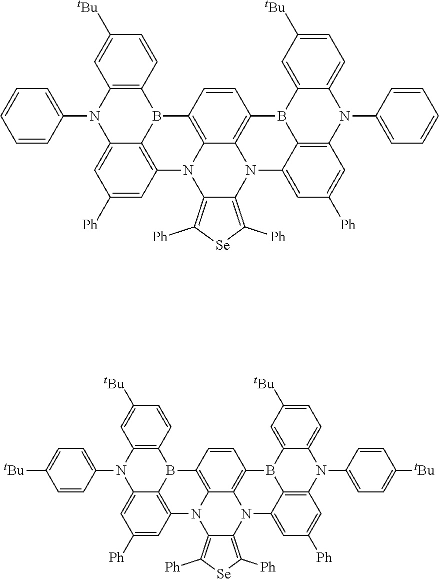 [SMILES: CC(C)(C)c1ccc2c(c1)B1c3ccc4c5c3N(c3cc(-c6ccccc6)cc(c31)N2c1ccccc1)c1c(-c2ccccc2)[se]c(-c2ccccc2)c1N5c1cc(-c2ccccc2)cc2c1B4c1ccc(C(C)(C)C)cc1N2c1ccccc1 ; CC(C)(C)c1ccc(N2c3ccc(C(C)(C)C)cc3B3c4ccc5c6c4N(c4cc(-c7ccccc7)cc2c43)c2c(-c3ccccc3)[se]c(-c3ccccc3)c2N6c2cc(-c3ccccc3)cc3c2B5c2ccc(C(C)(C)C)cc2N3c2ccc(C(C)(C)C)cc2)cc1]

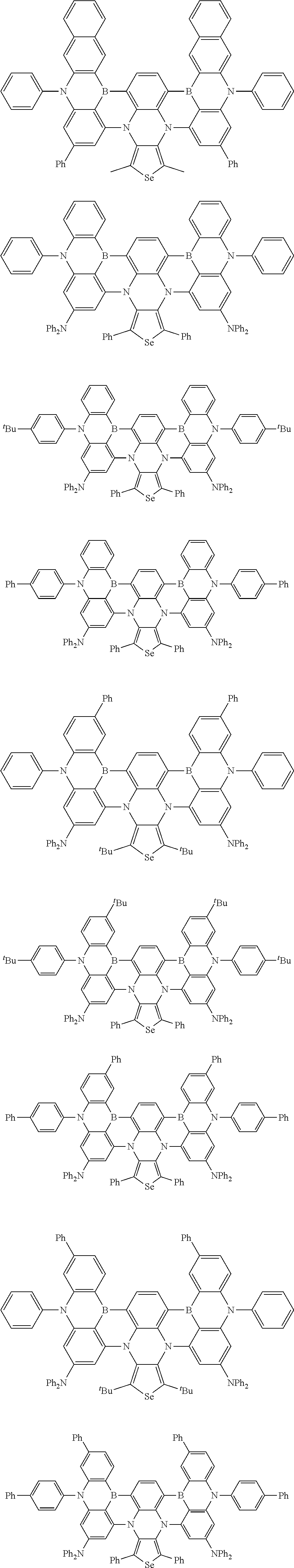

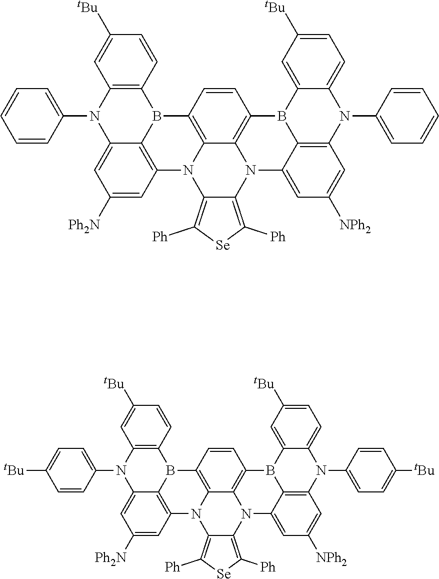

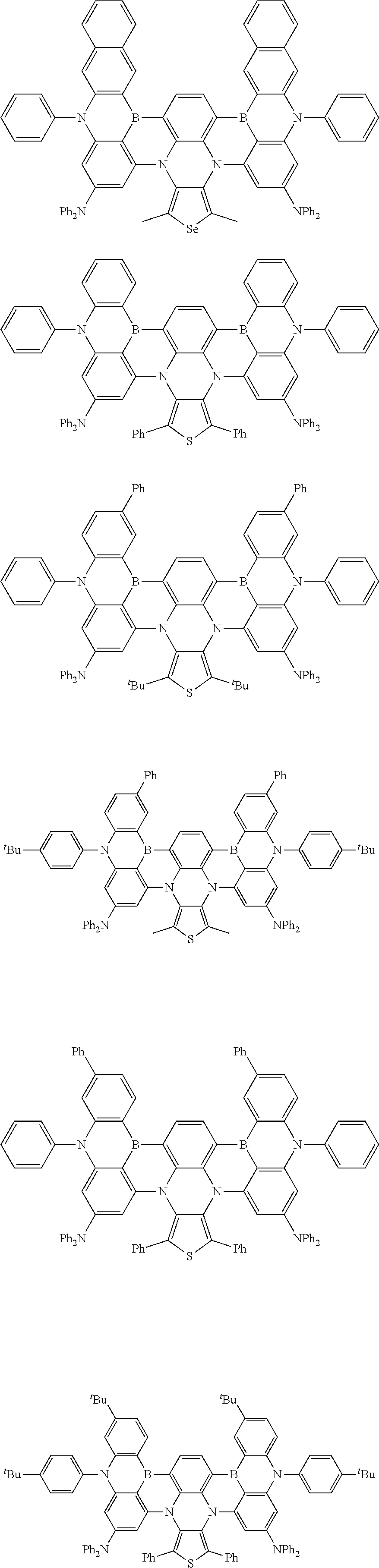

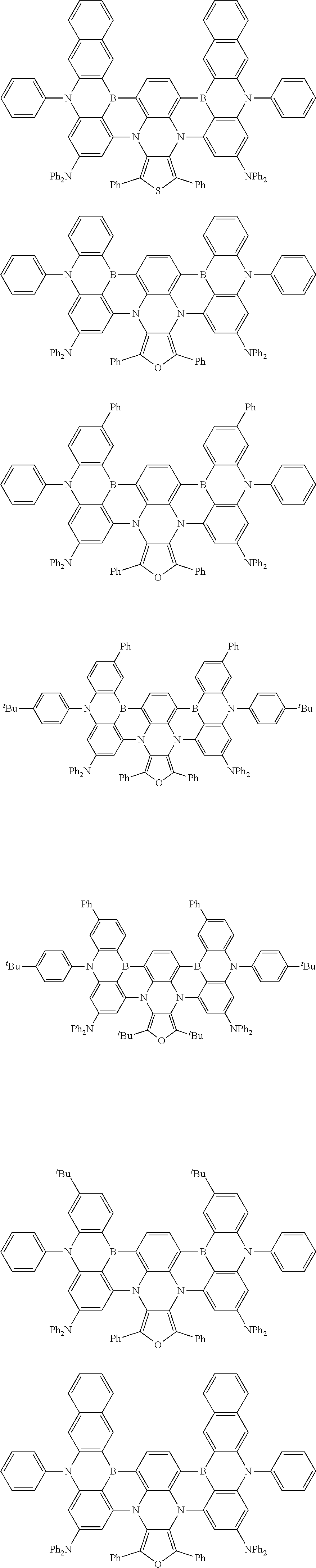

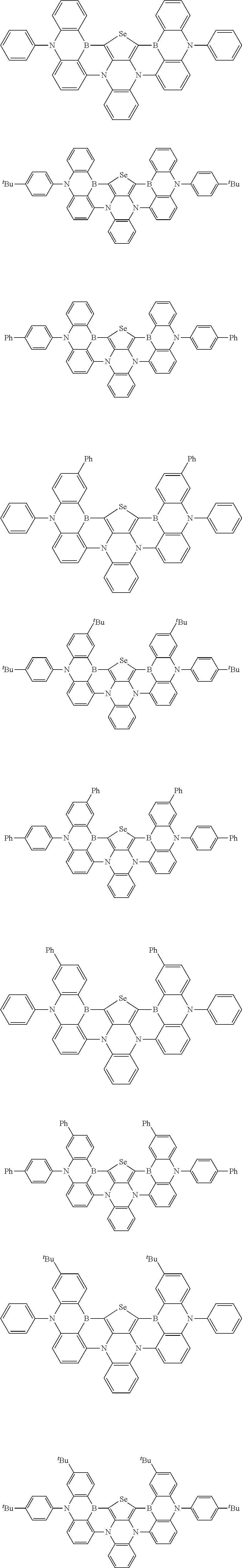

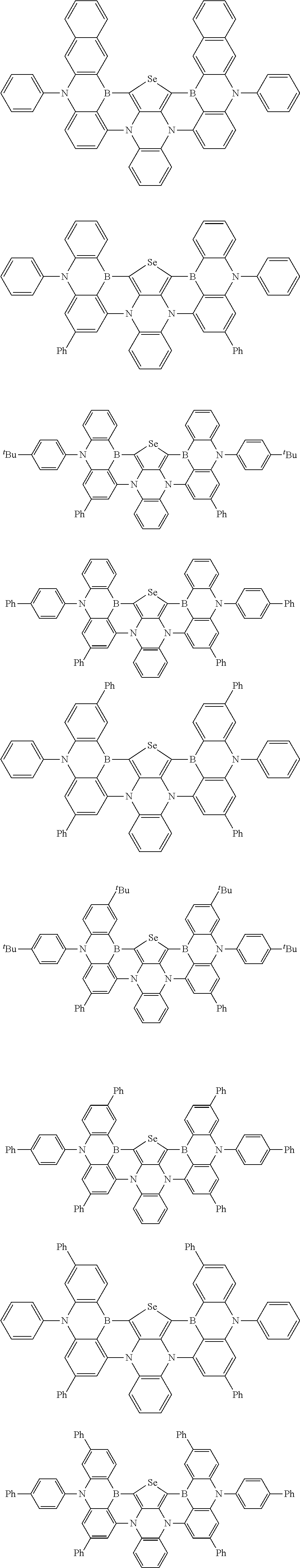

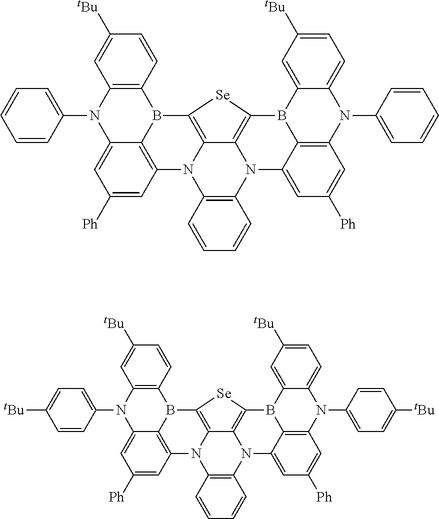 [SMILES: CC(C)(C)c1ccc2c(c1)B1c3[se]c4c5c3N(c3ccccc3N5c3cc(-c5ccccc5)cc5c3B4c3ccc(C(C)(C)C)cc3N5c3ccccc3)c3cc(-c4ccccc4)cc(c31)N2c1ccccc1 ; CC(C)(C)c1ccc(N2c3ccc(C(C)(C)C)cc3B3c4[se]c5c6c4N(c4ccccc4N6c4cc(-c6ccccc6)cc6c4B5c4ccc(C(C)(C)C)cc4N6c4ccc(C(C)(C)C)cc4)c4cc(-c5ccccc5)cc2c43)cc1]

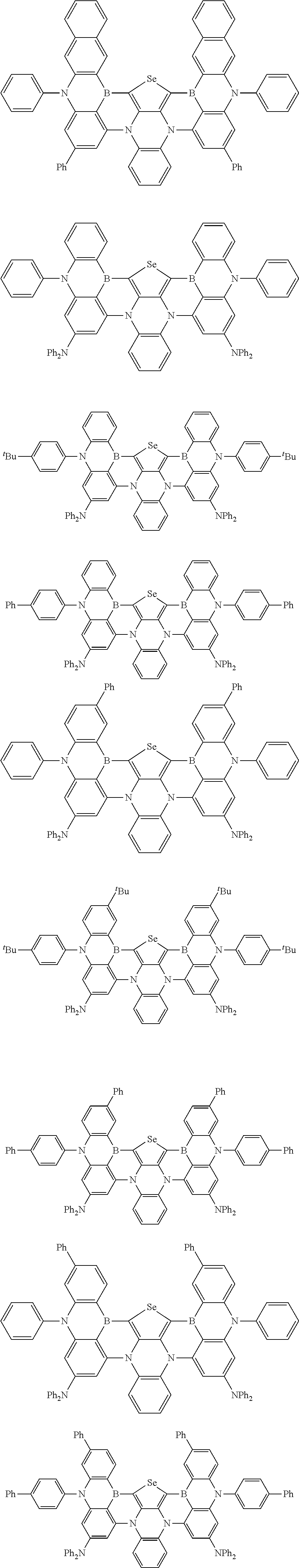

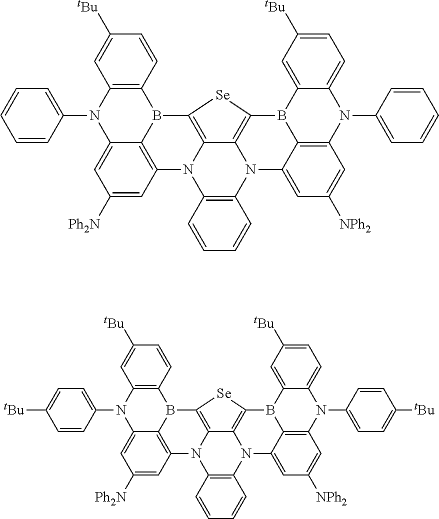

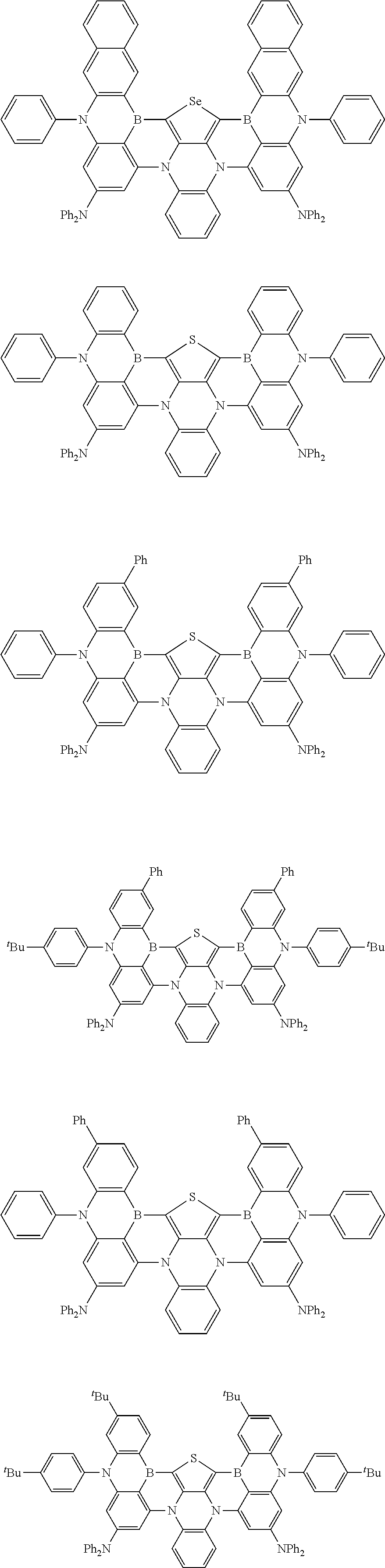

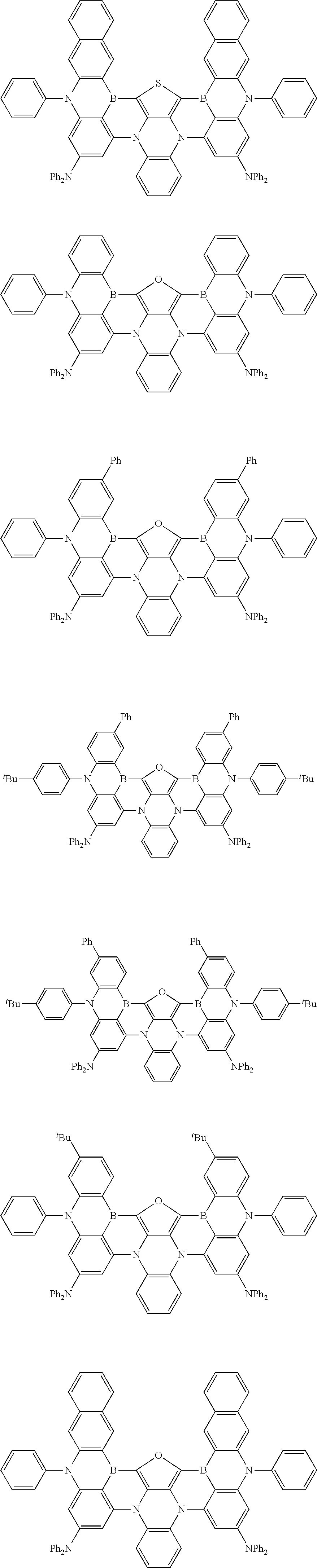

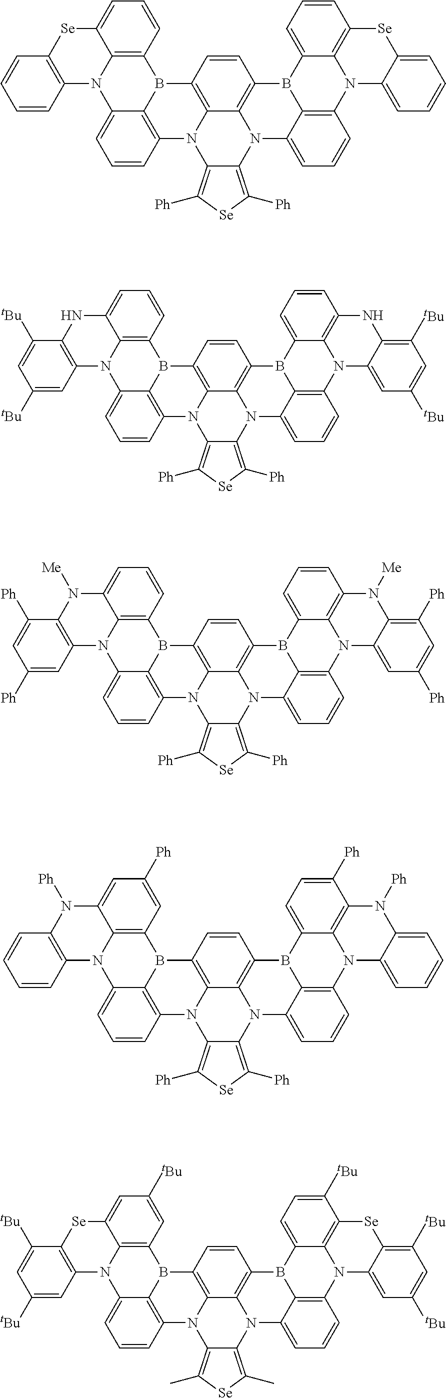

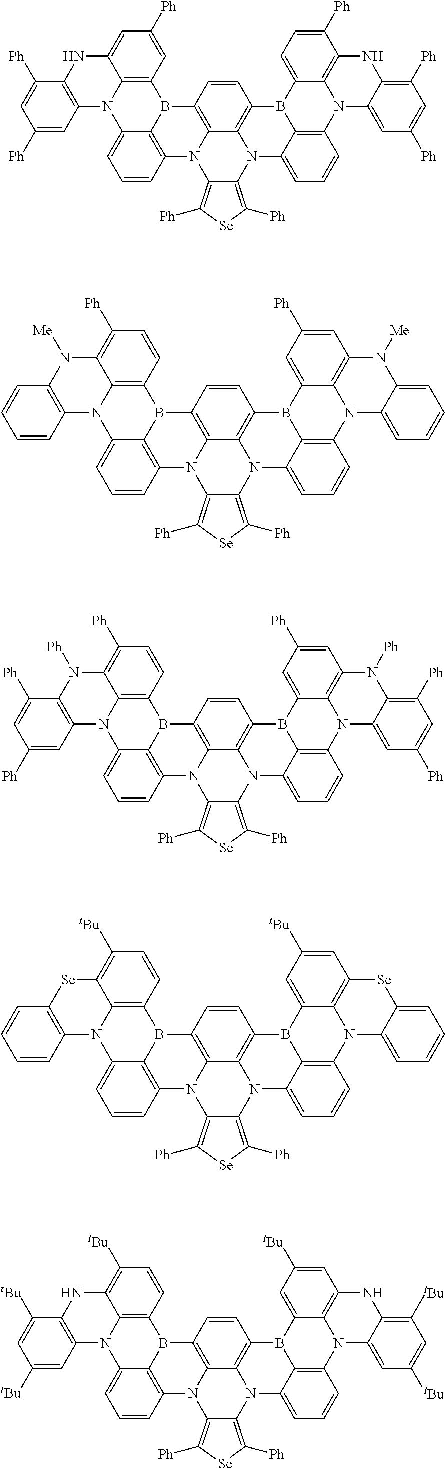

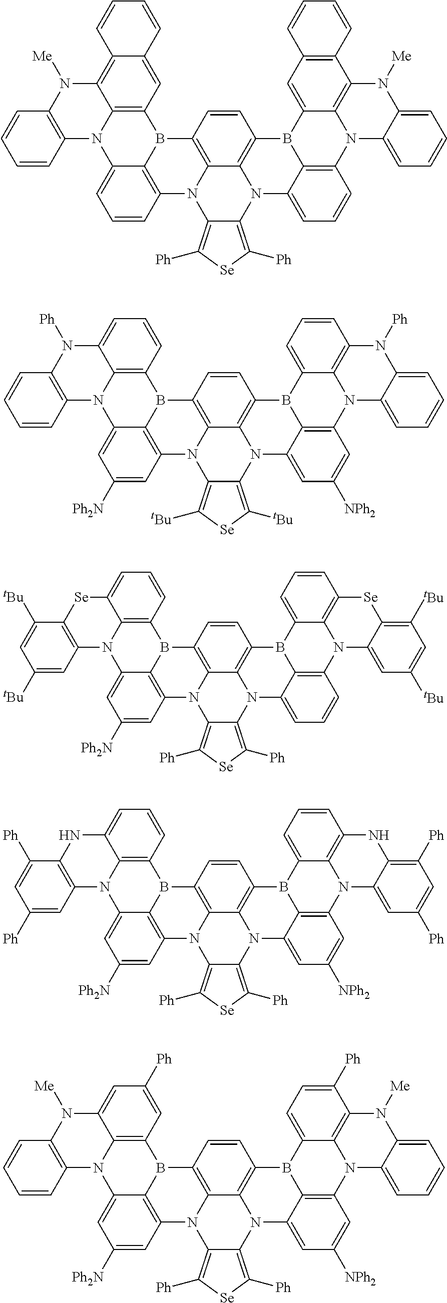

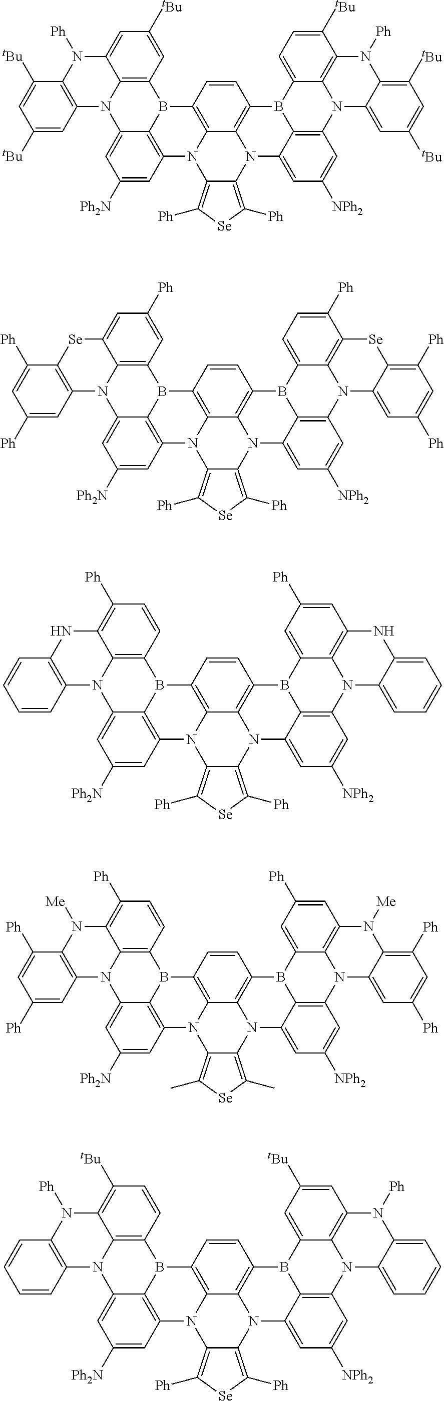

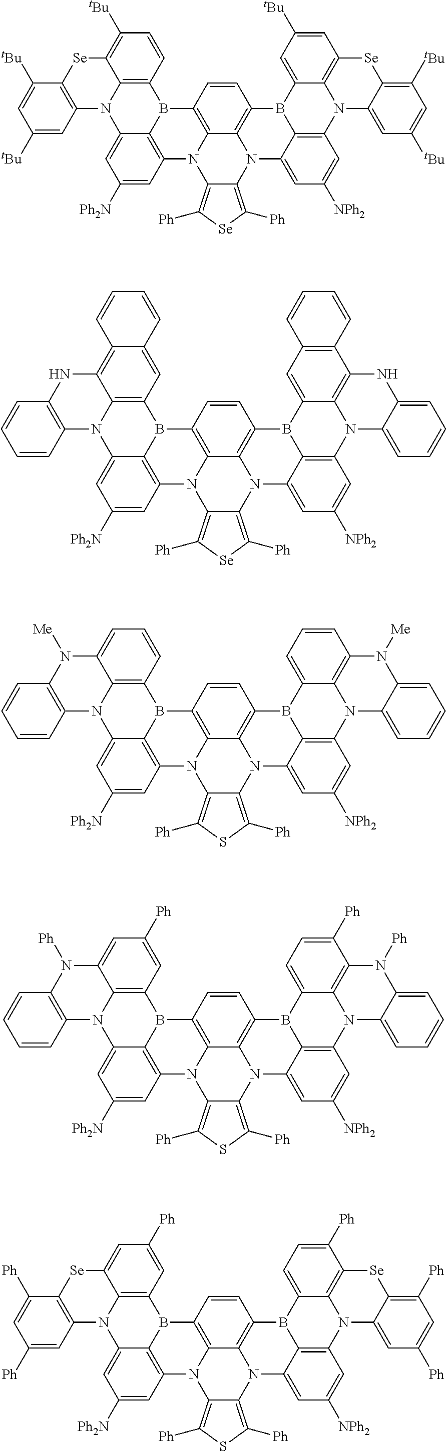

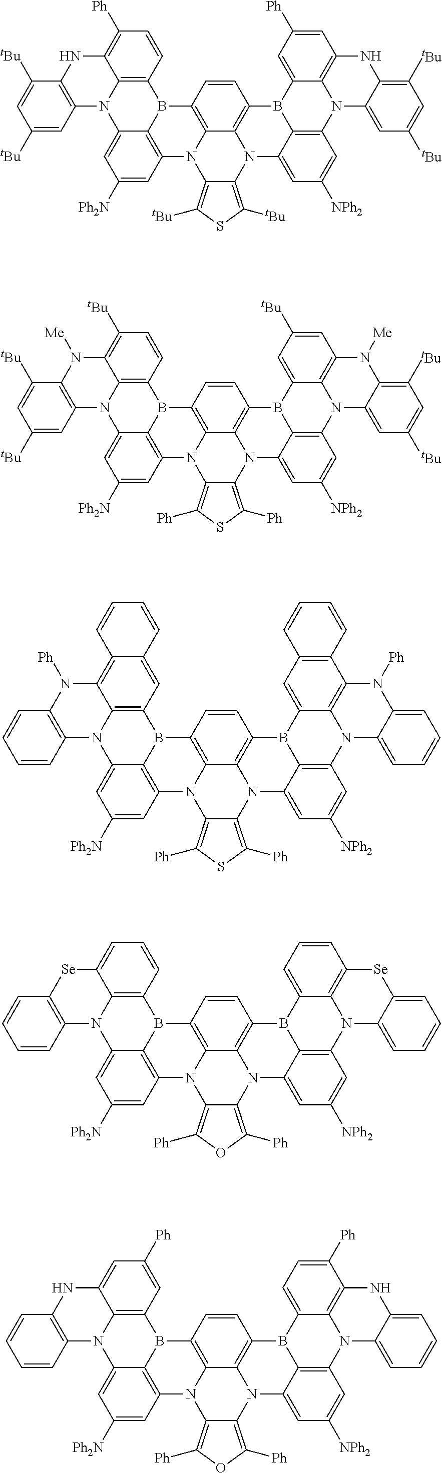

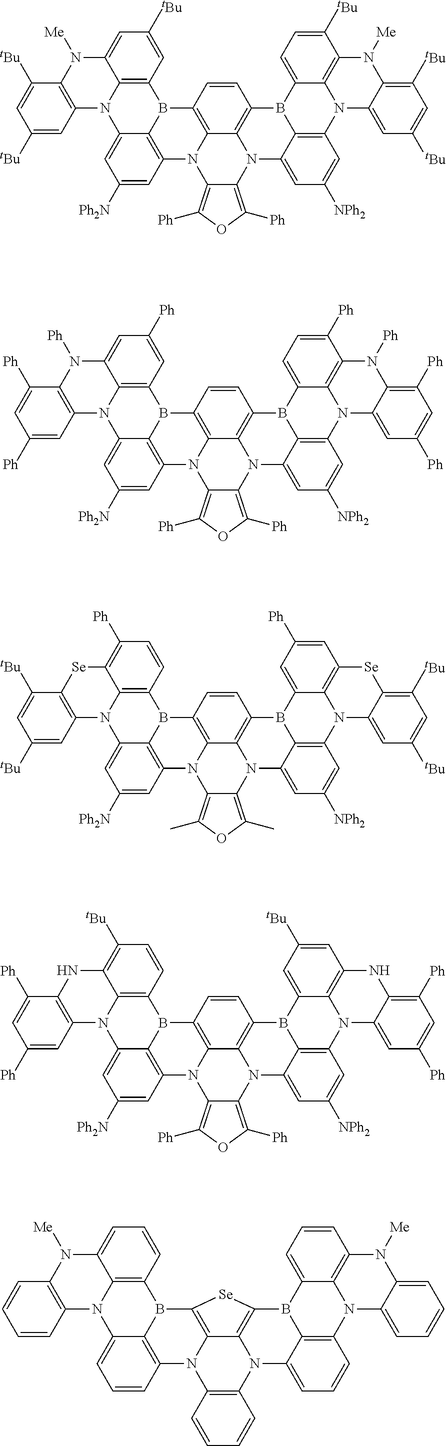

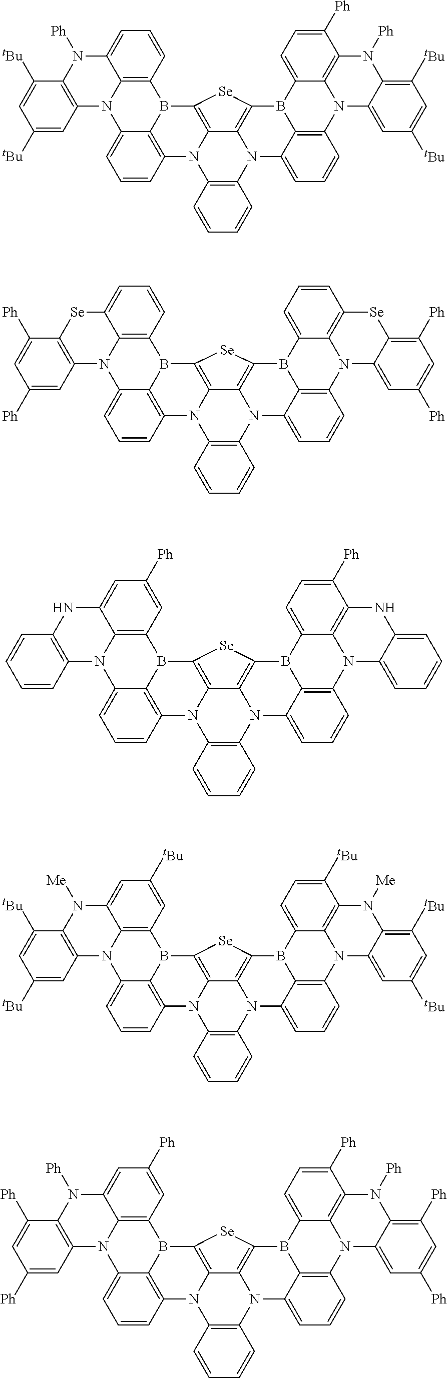

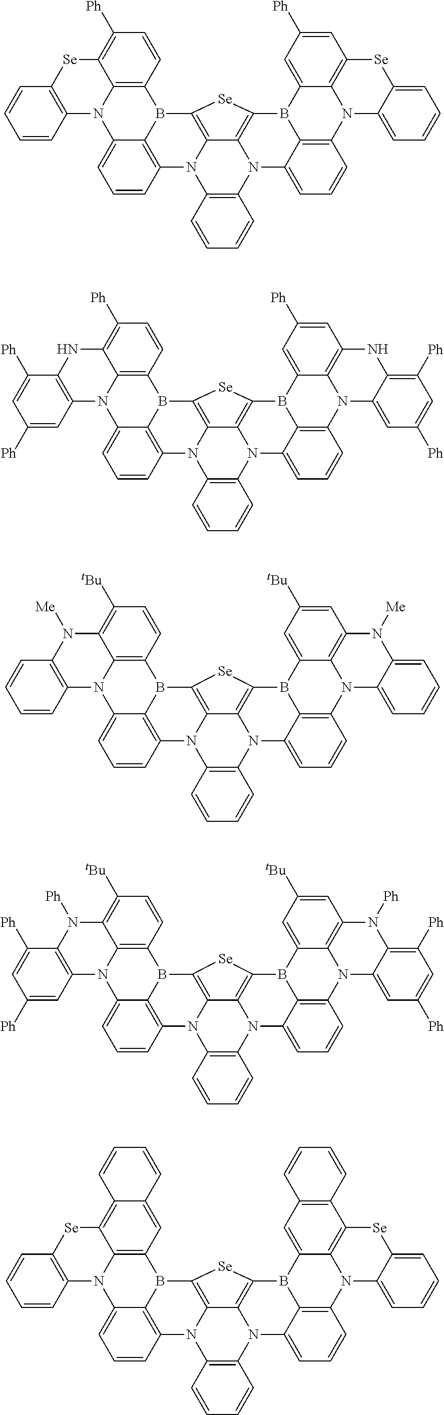

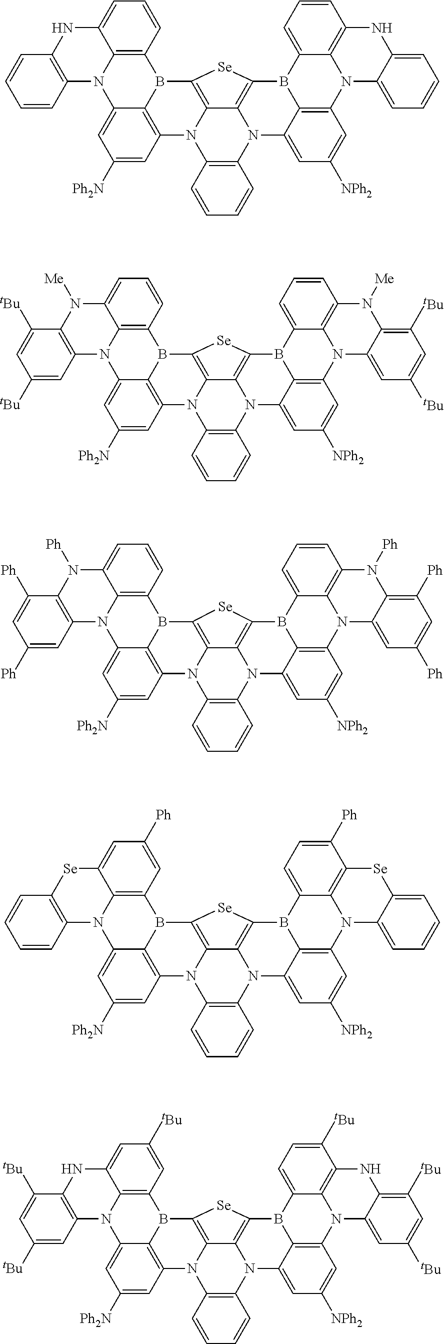

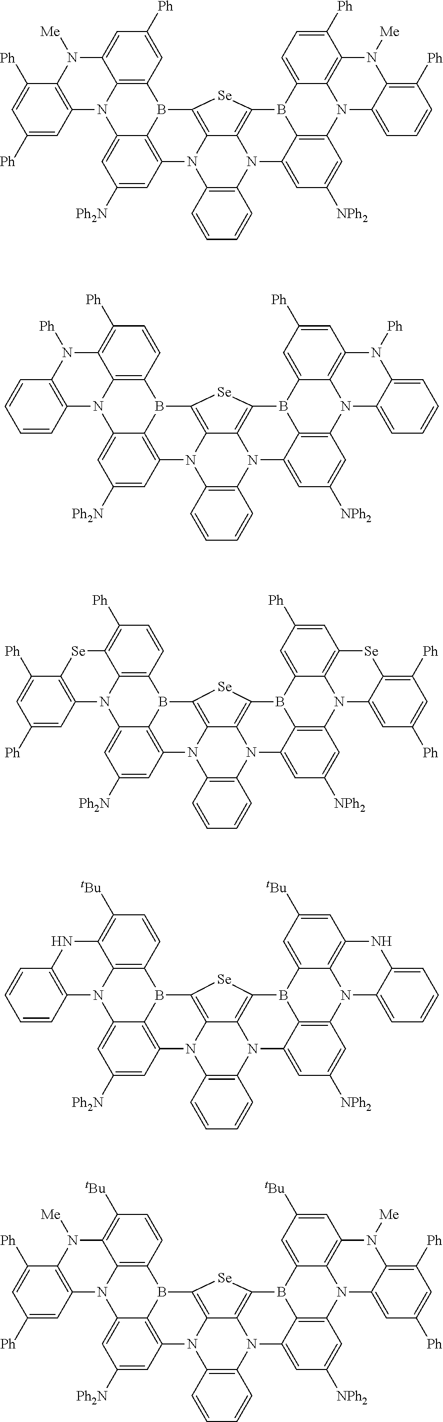

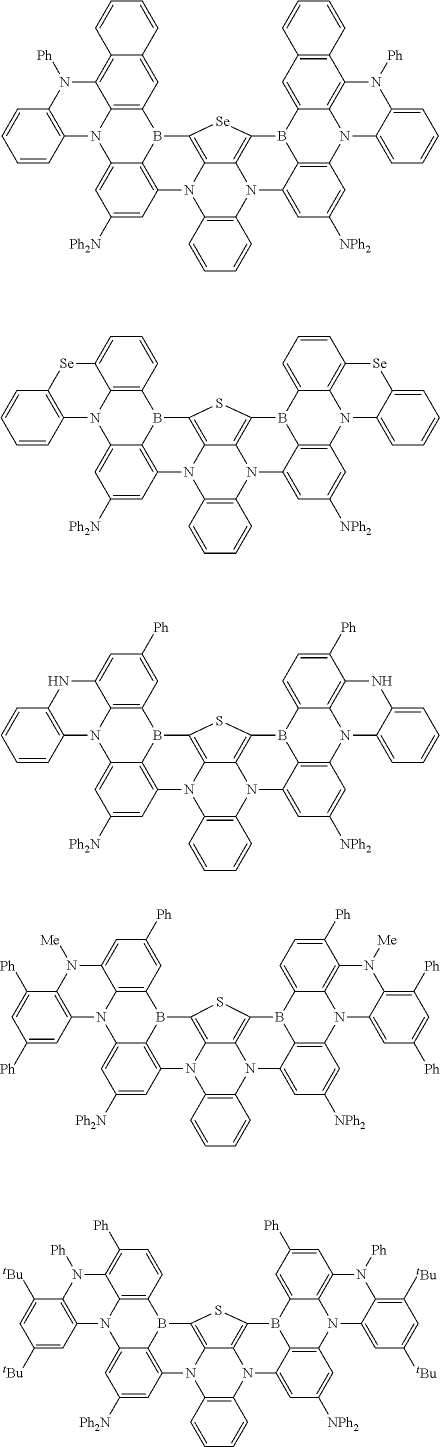

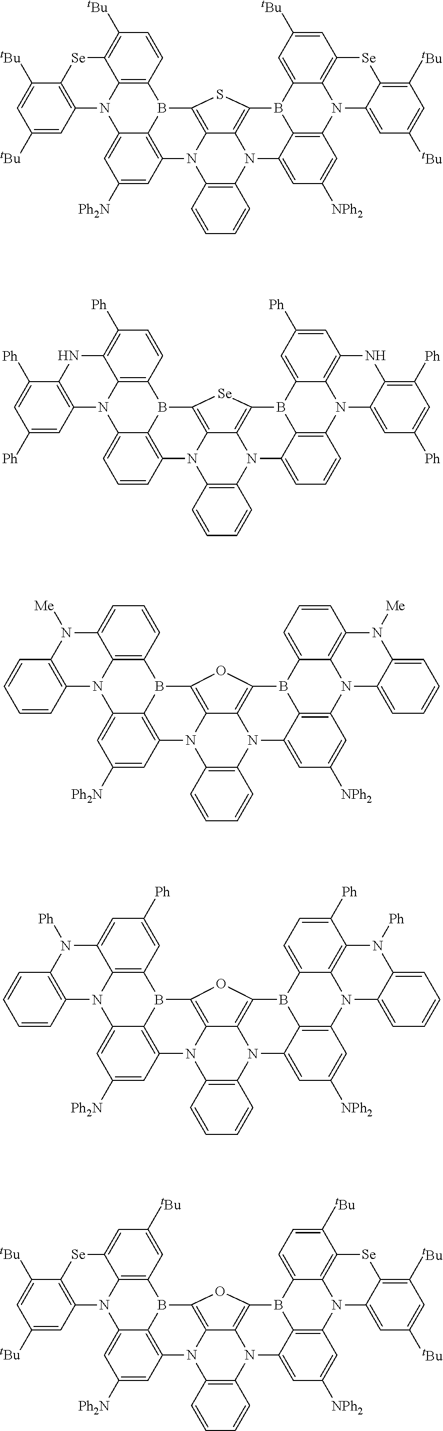

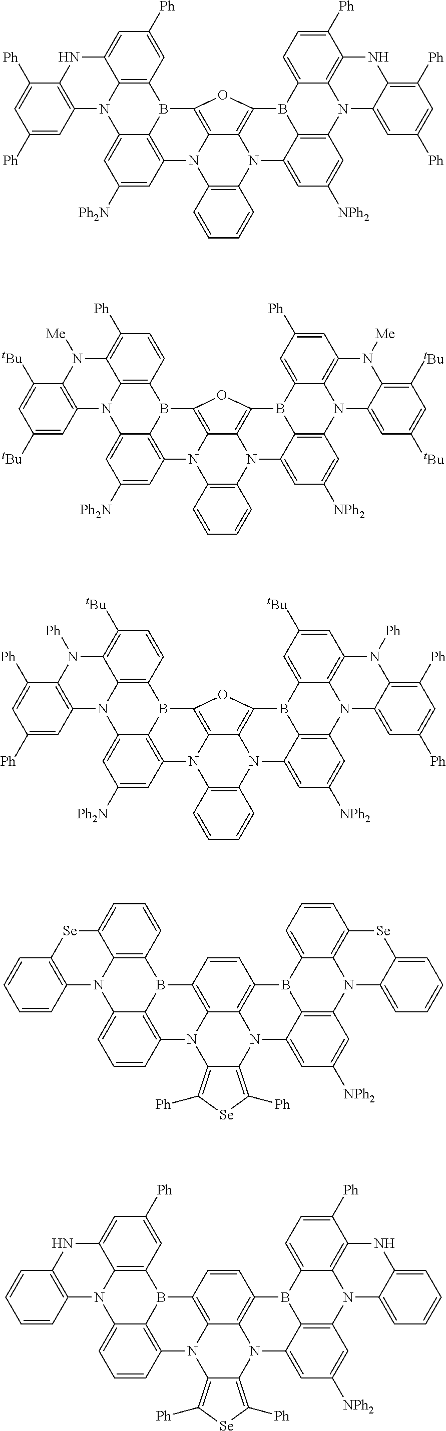

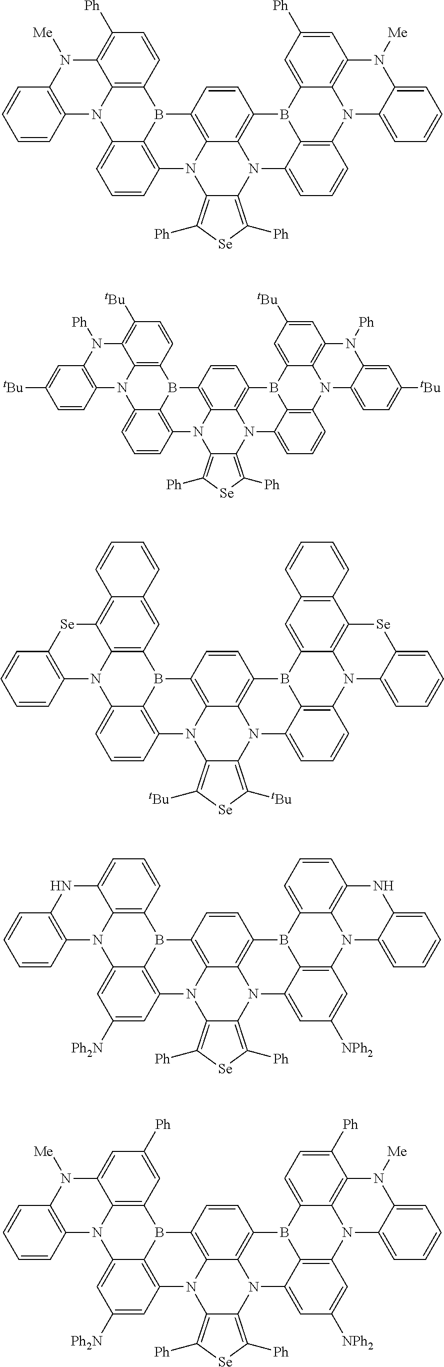

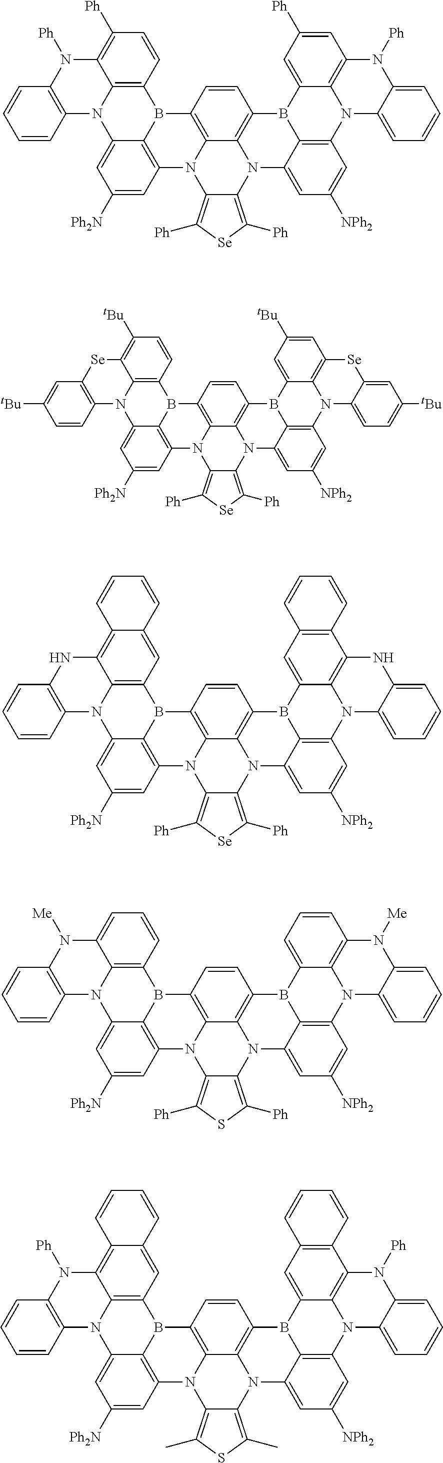

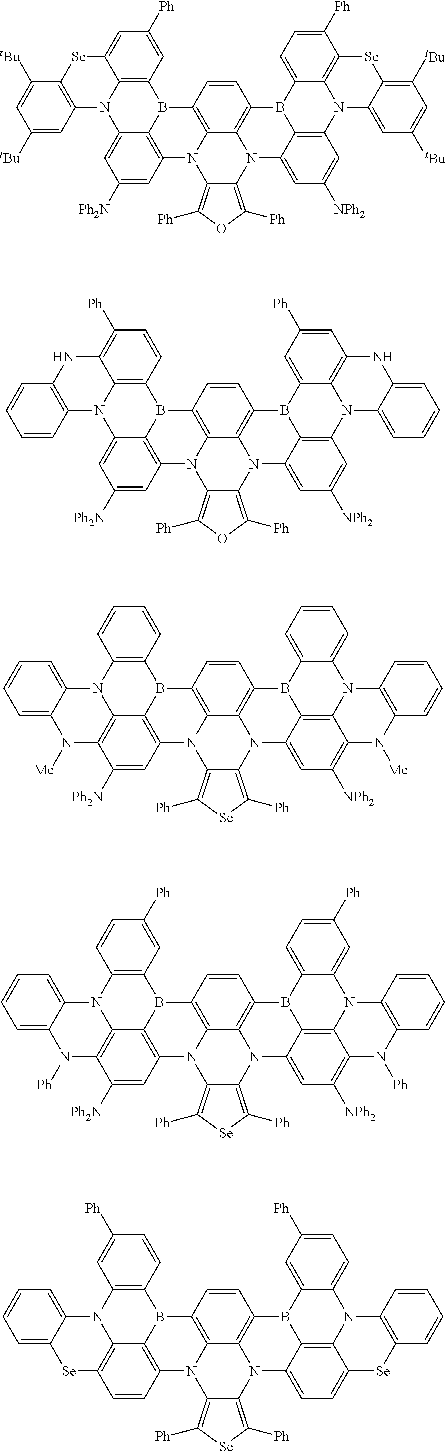

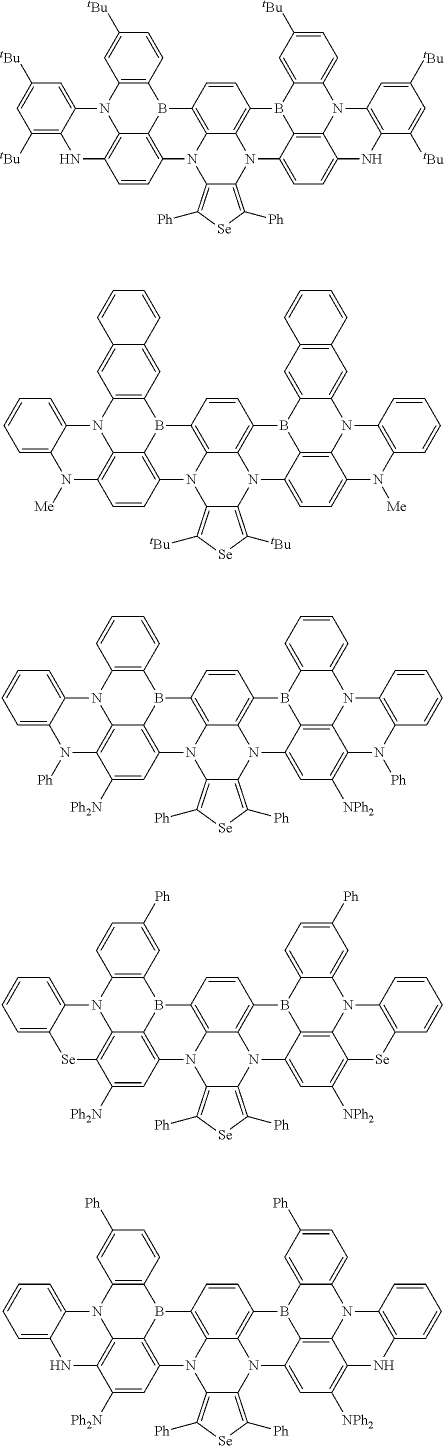

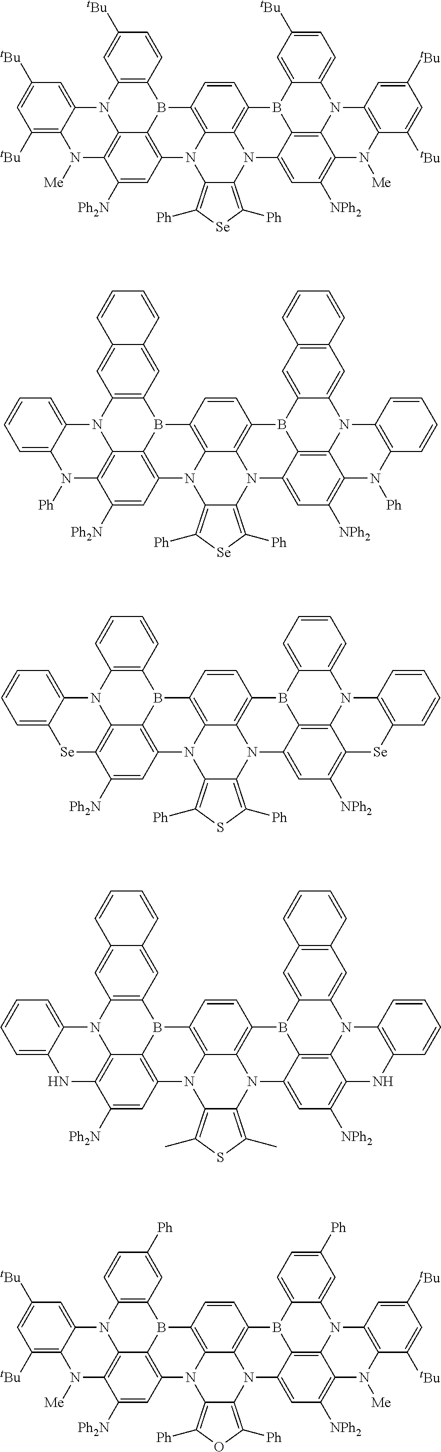

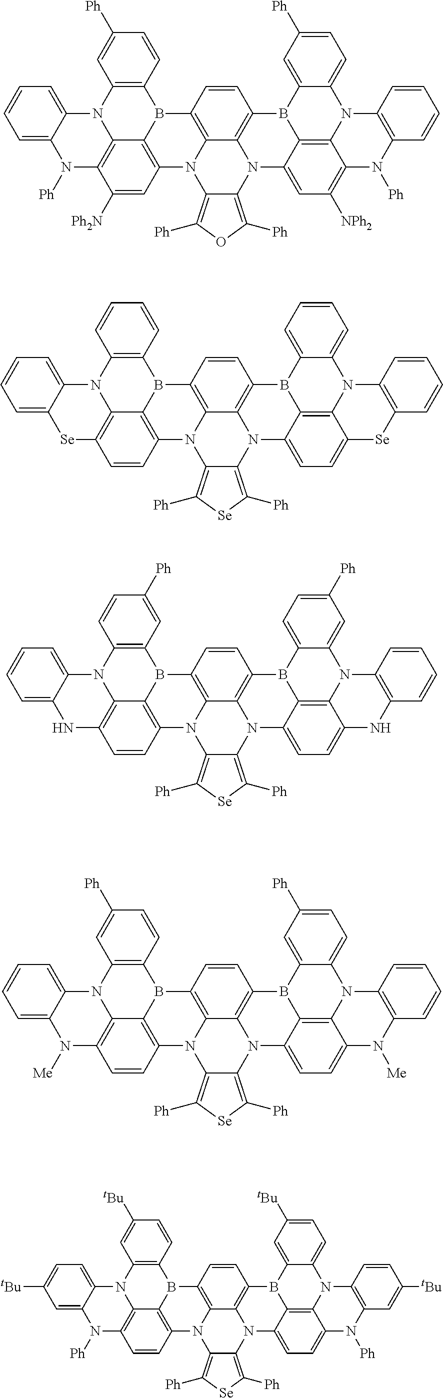

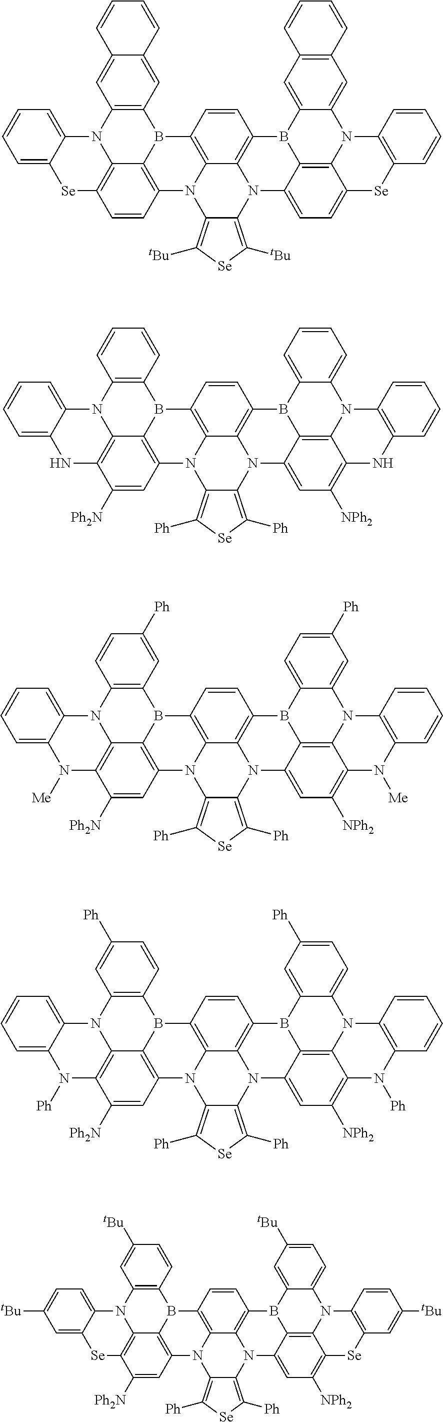

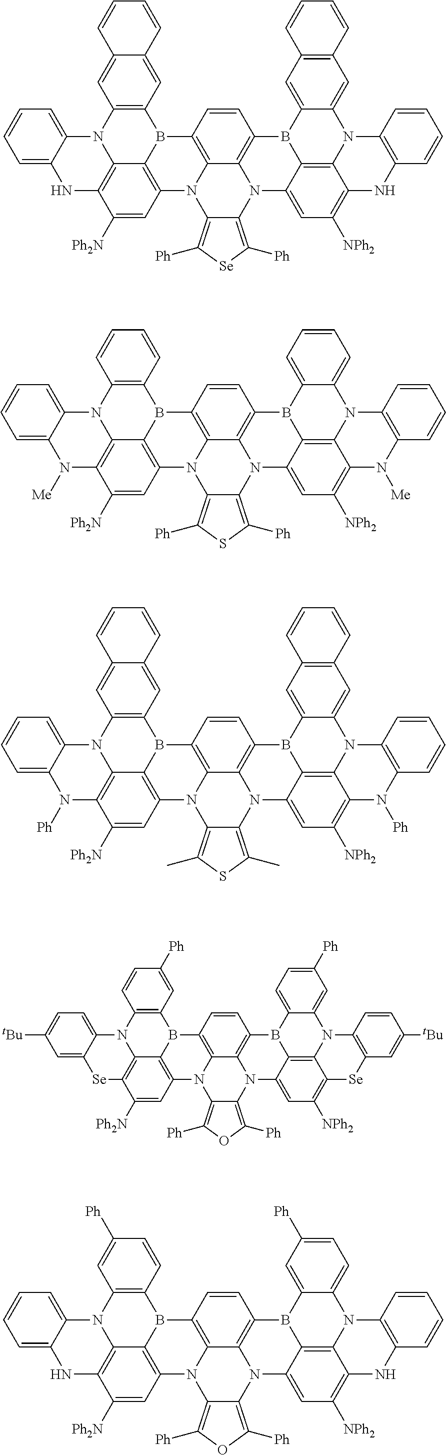

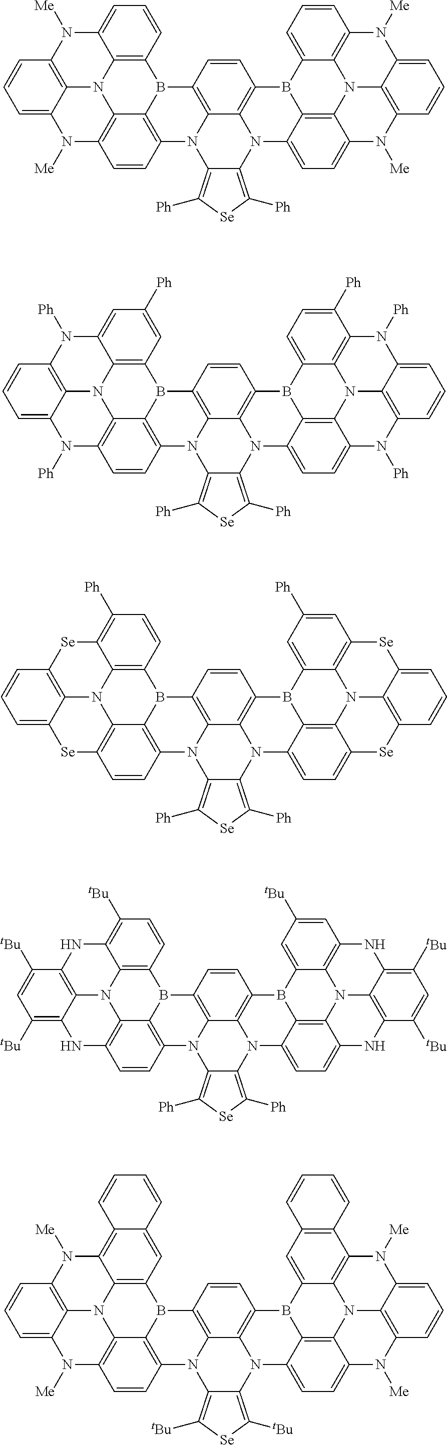

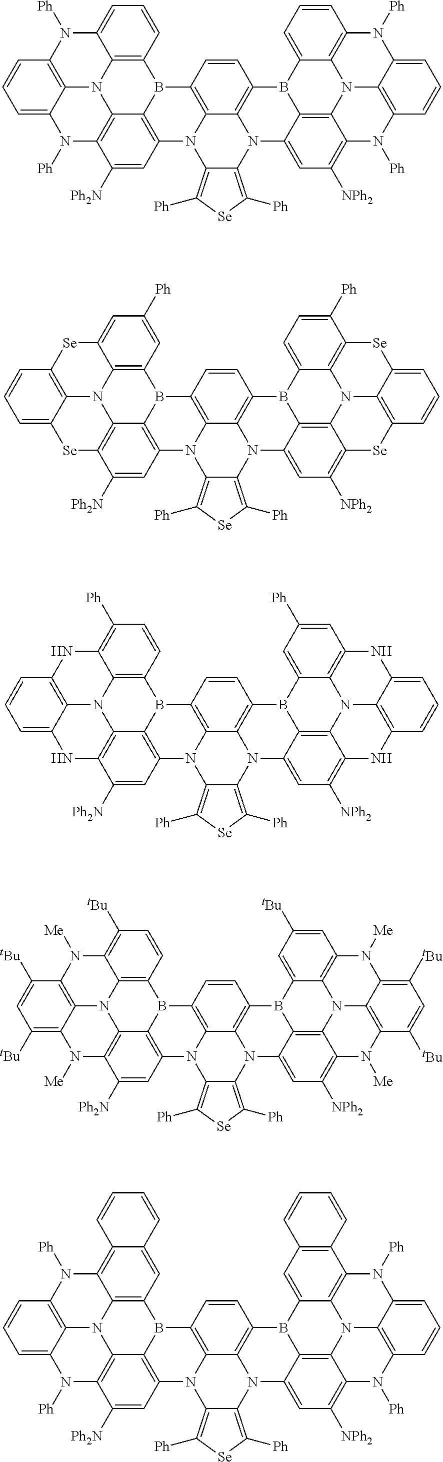

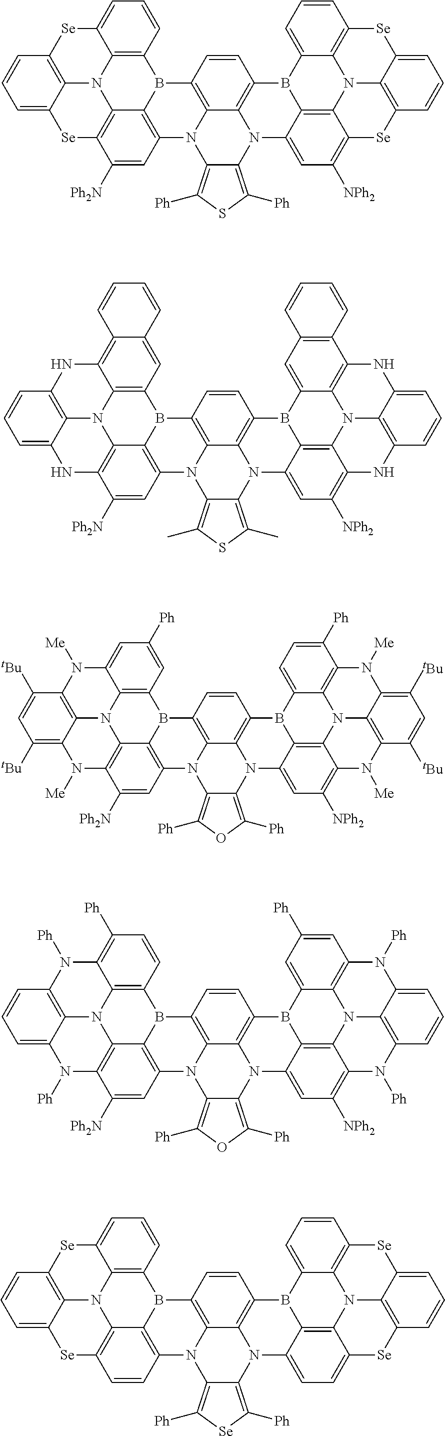

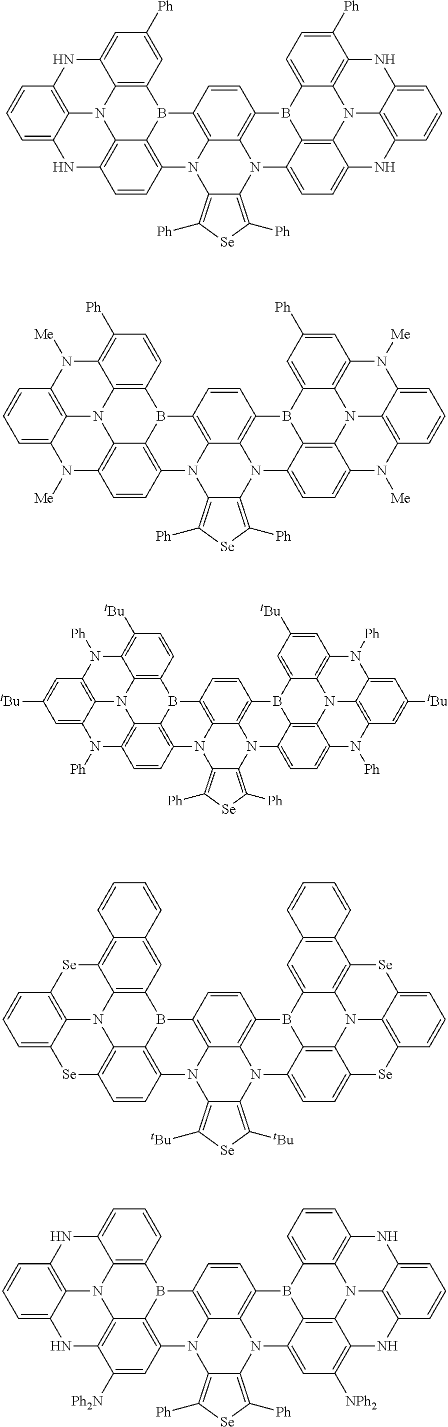

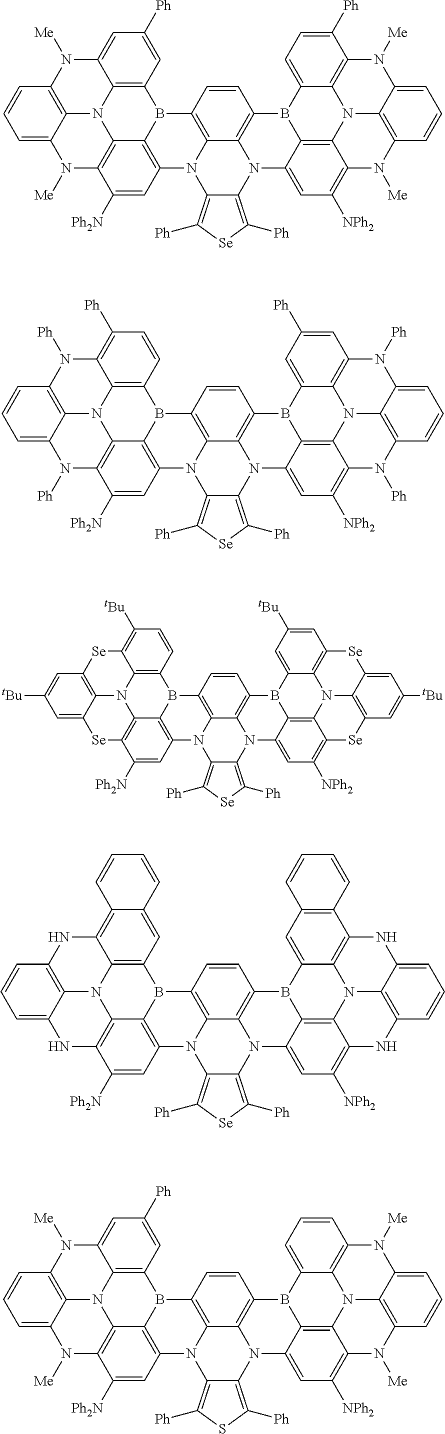

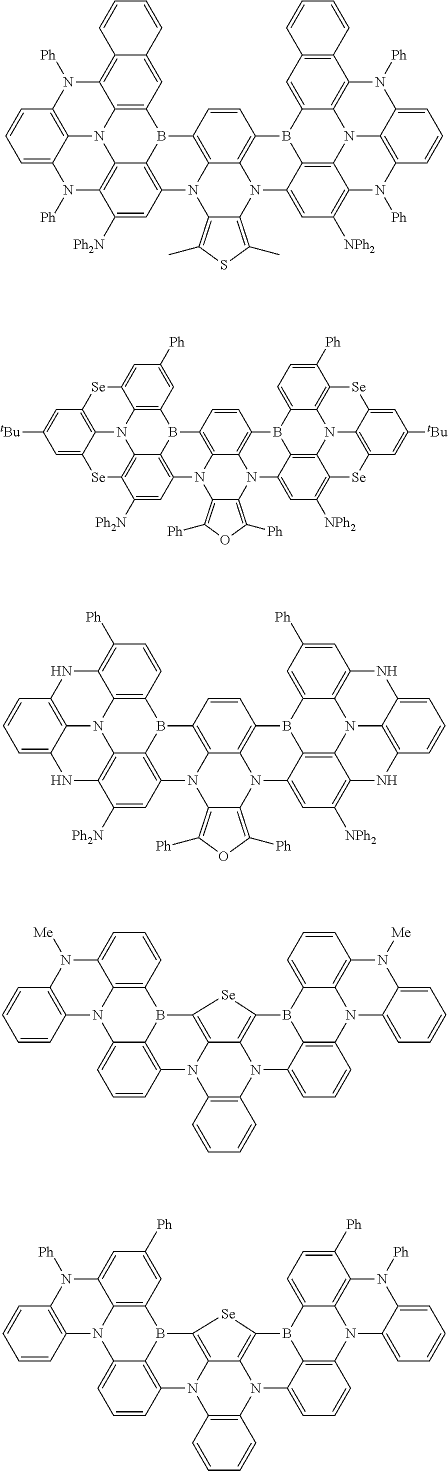

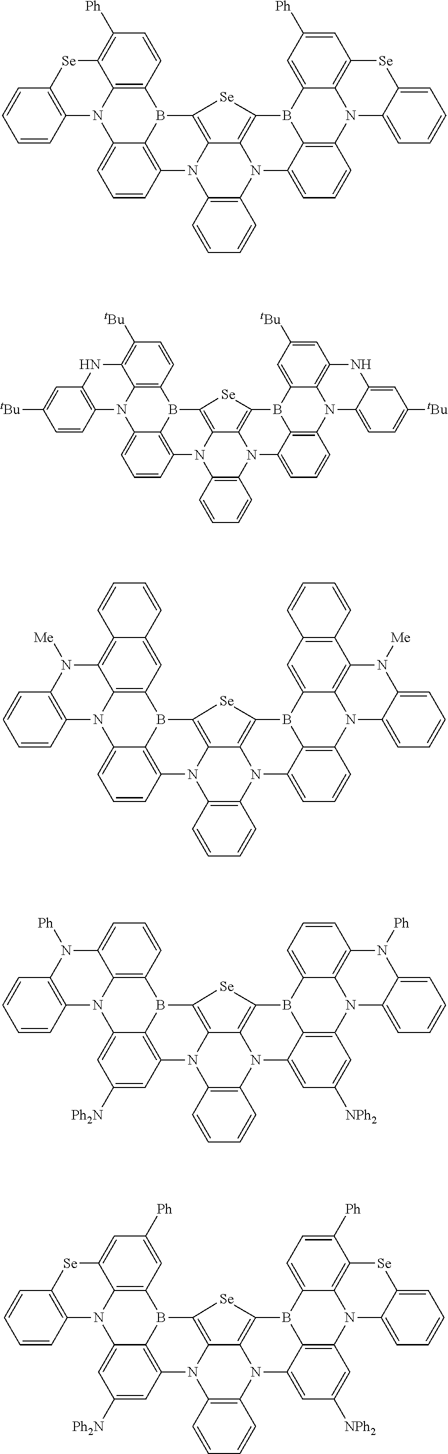

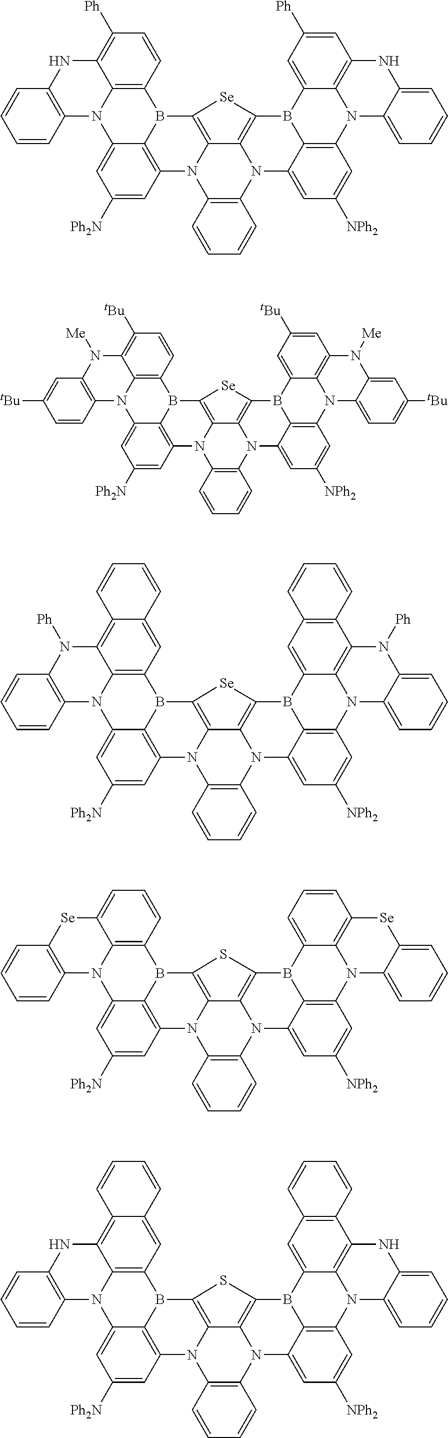

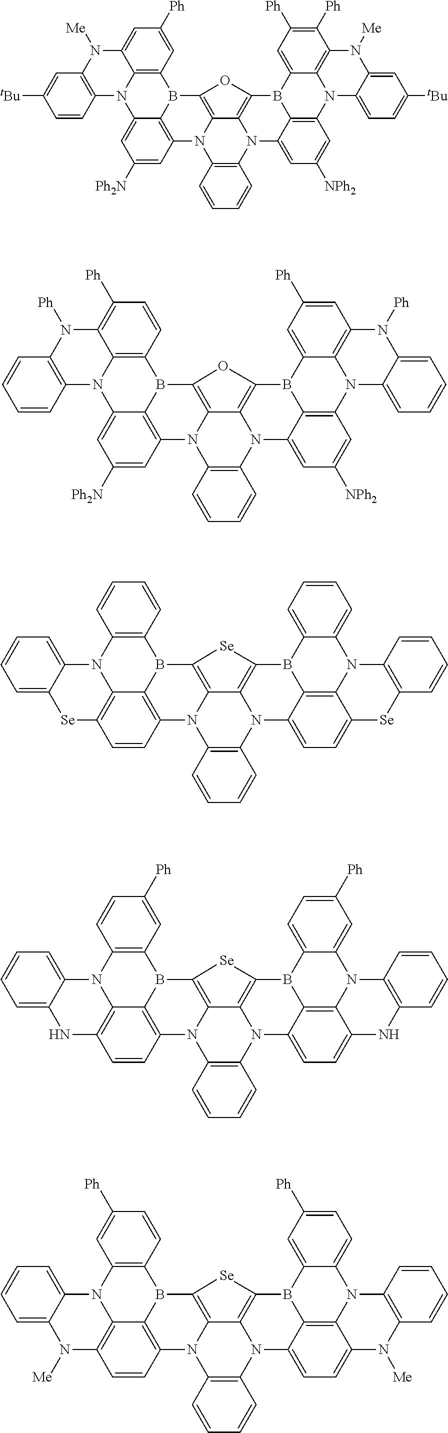

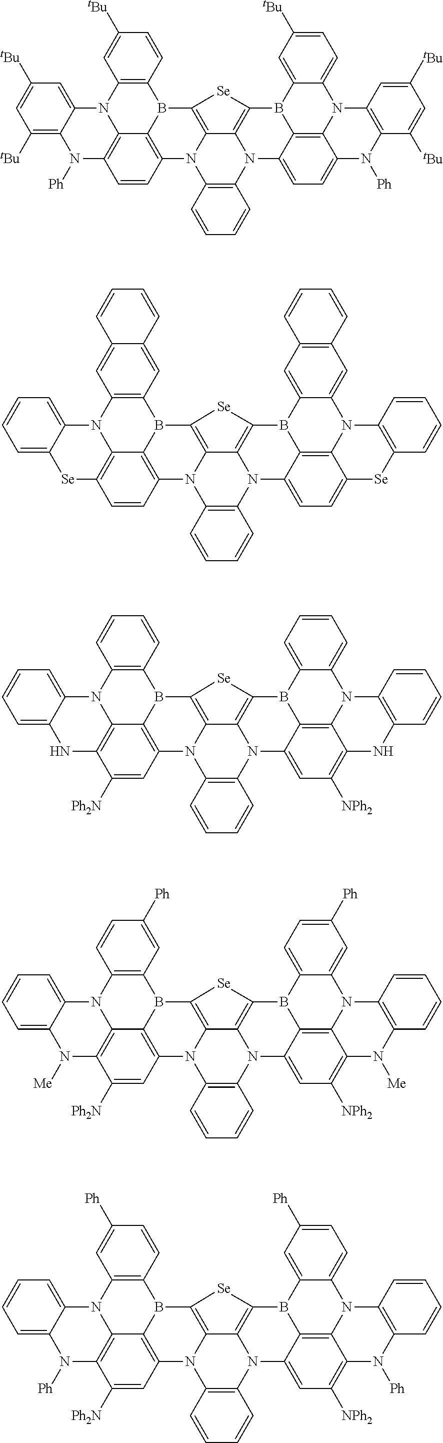

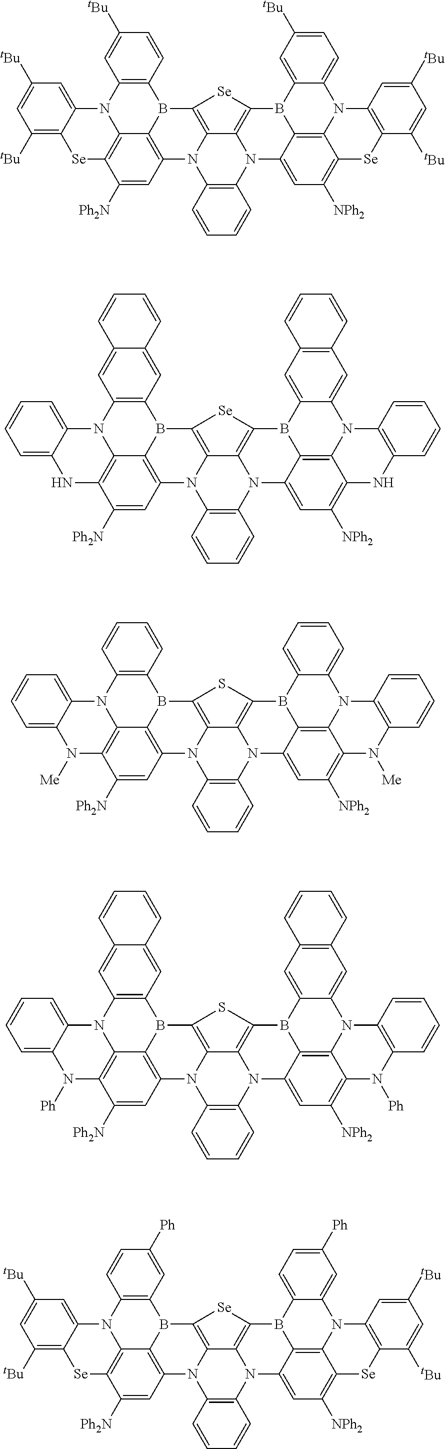

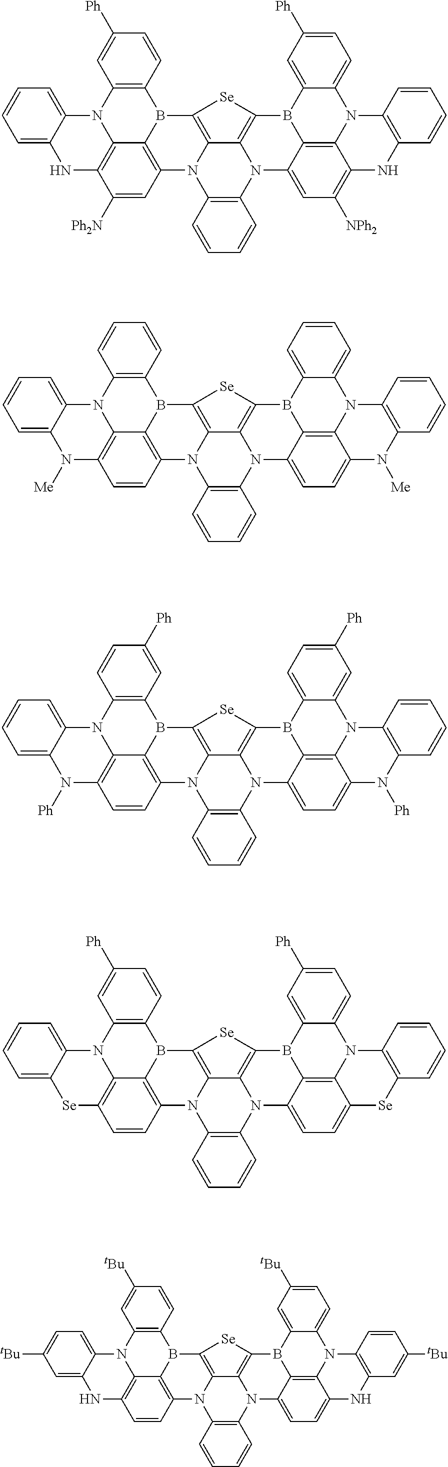

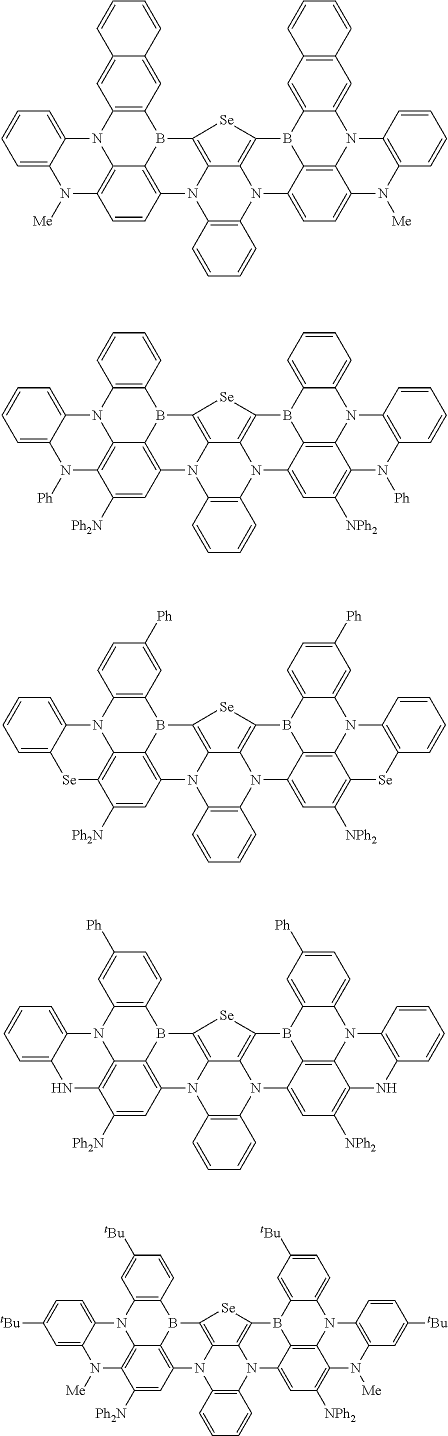

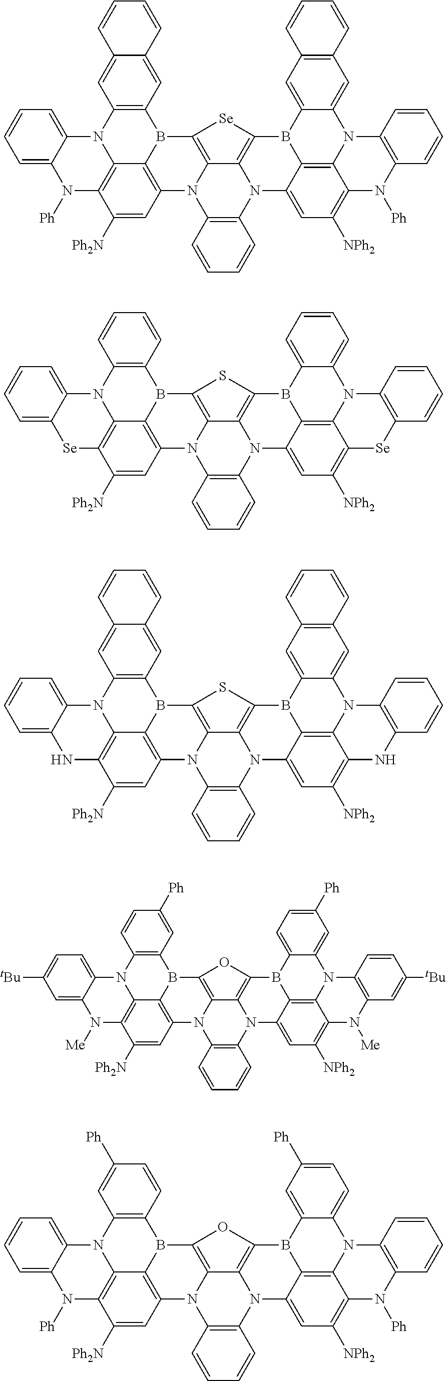

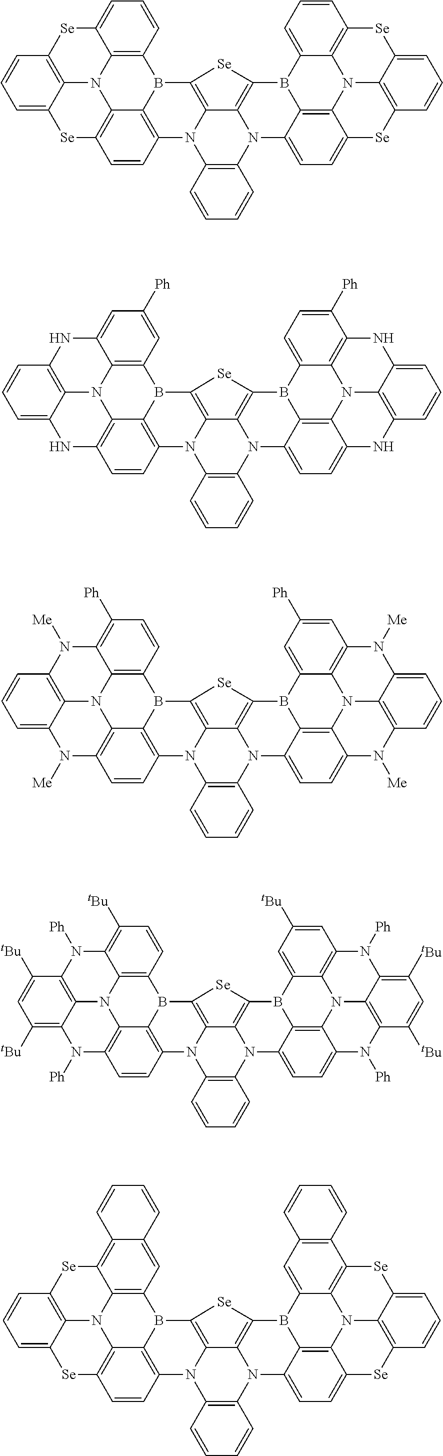

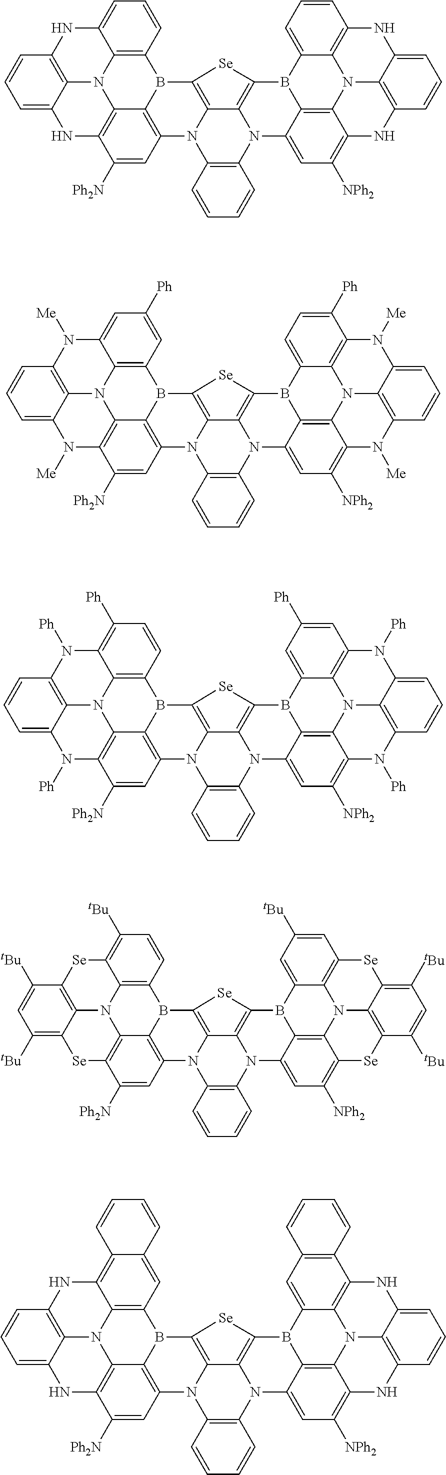

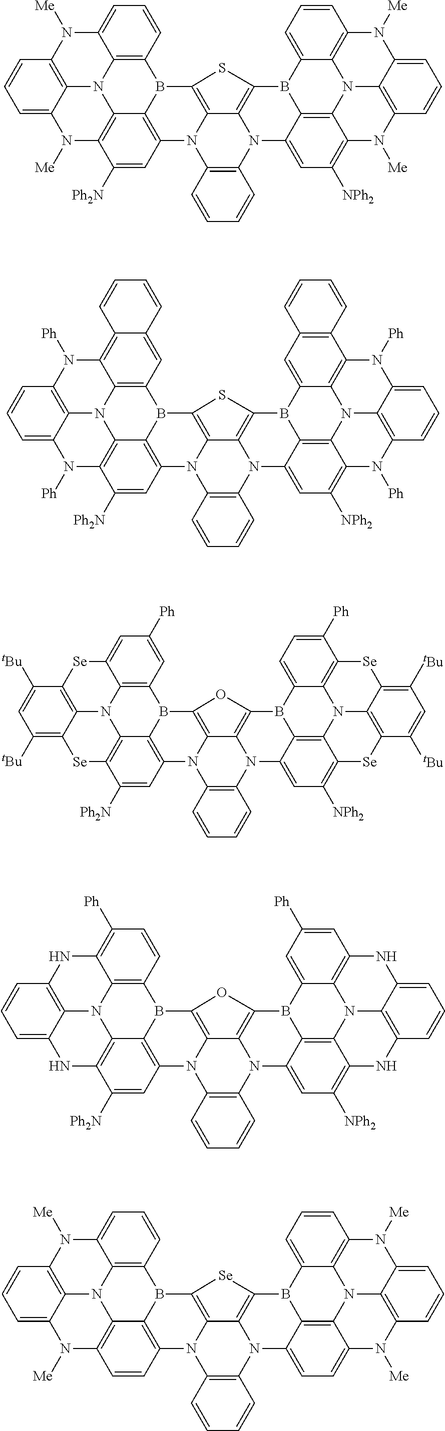

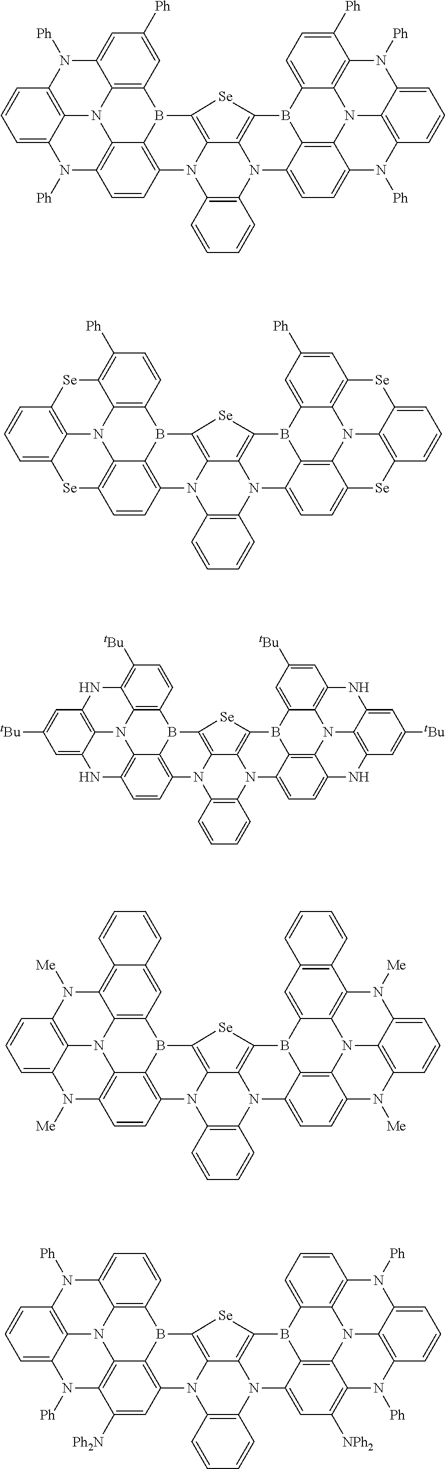

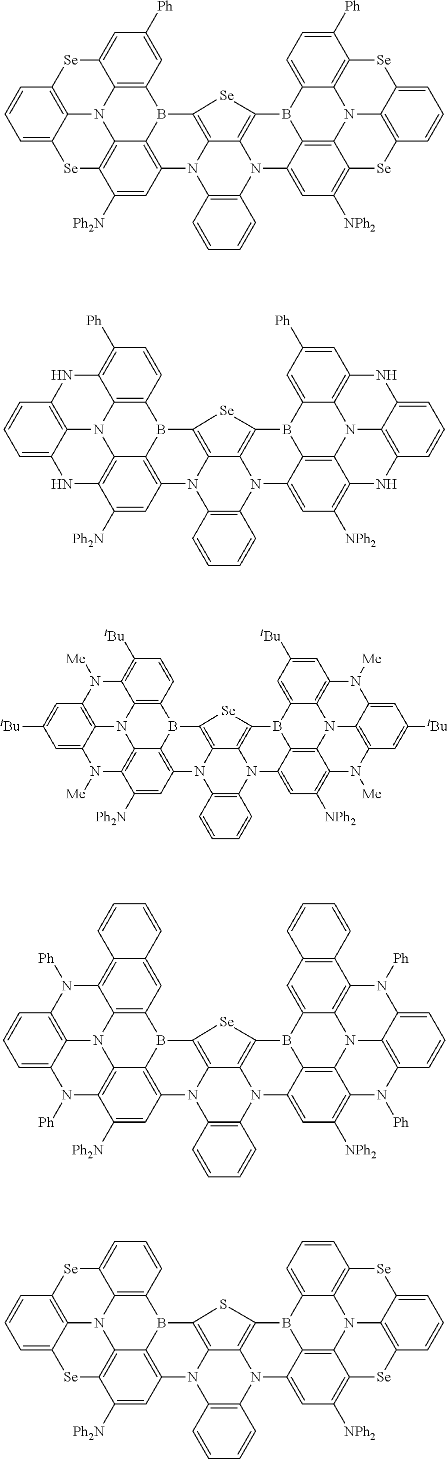

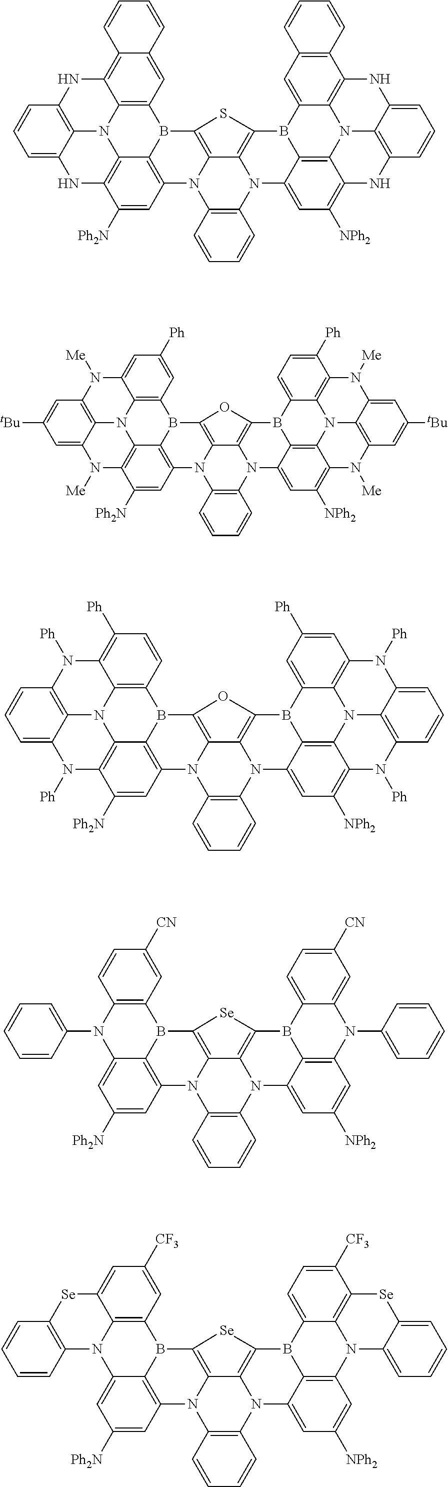

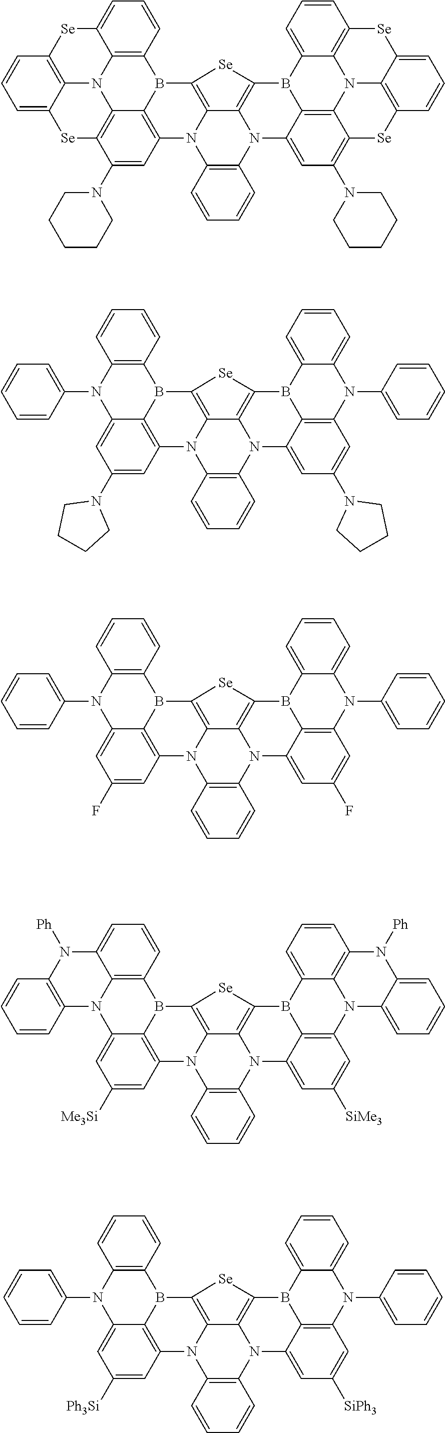

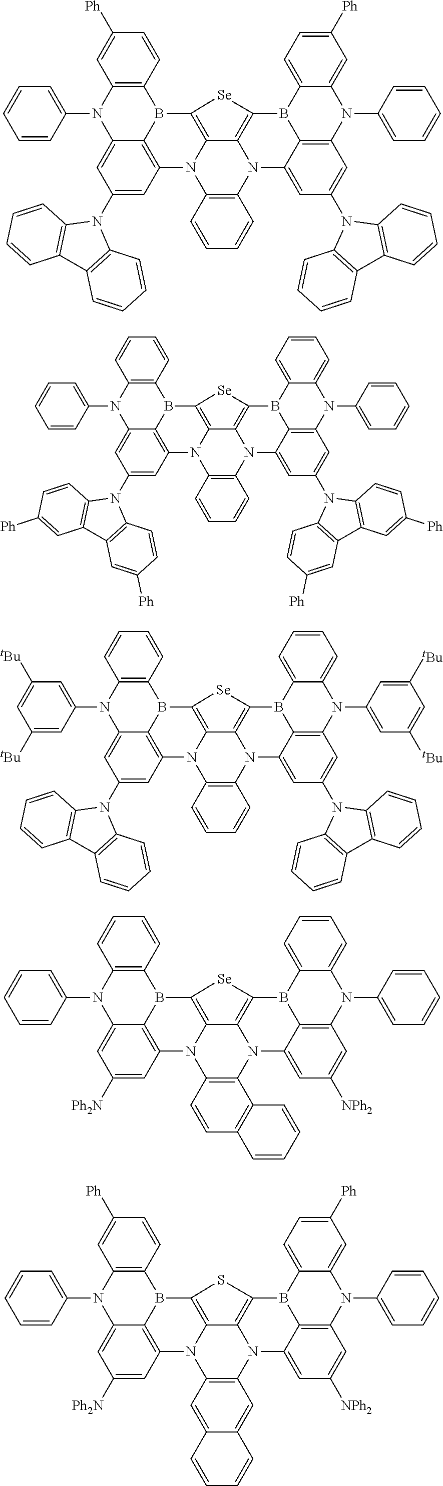

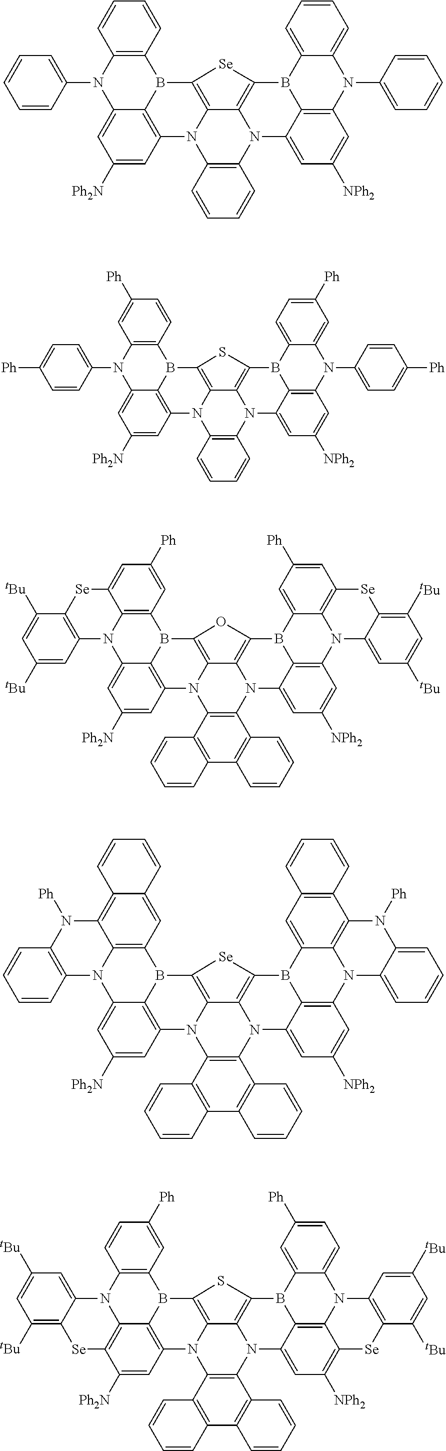

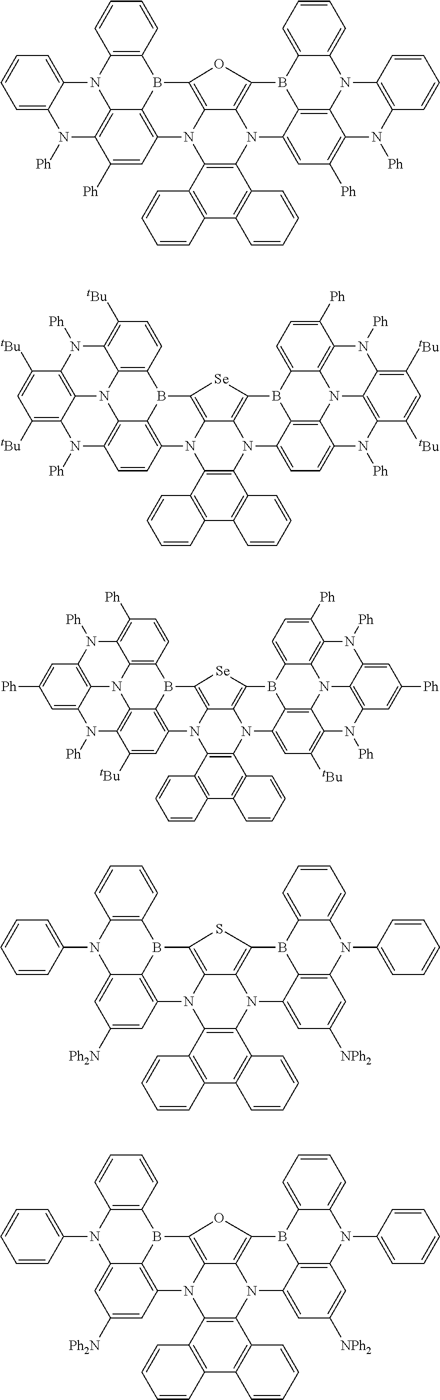

1. An organic molecule, comprising a structure of formula I: 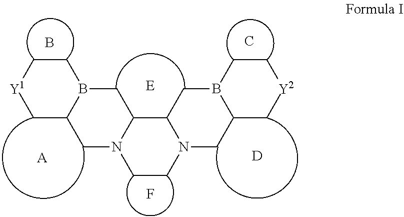
wherein
each of ring A, ring B, ring C, ring D, ring E, and ring F independently represents an aromatic or heteroaromatic ring with 5 to 18 ring atoms, wherein, in case of a heteroaromatic ring, 1 to 3 ring atoms are independently selected from the group consisting of N, O, S, and Se;
wherein one or more hydrogen atoms in each of the aromatic or heteroaromatic rings A, B, C, D, E, and F are optionally substituted by a substituent R¹, which is at each occurrence independently selected from the group consisting of: hydrogen, deuterium, N(R²)₂, OR², SR², Si(R²)₃, B(OR²)₂, OSO₂R², CF₃, CN, F, Cl, Br, I,
C₁-C₄₀-alkyl,
which is optionally substituted with one or more substituents R² and
wherein one or more non-adjacent CH₂-groups are optionally substituted by R²C═CR², C≡C, Si(R²)₂, Ge(R²)₂, Sn(R²)₂, C═O, C═S, C═Se, C═NR², P(═O)(R²), SO, SO₂, NR², O, S or CONR²;
C₁-C₄₀-alkoxy,
which is optionally substituted with one or more substituents R² and
wherein one or more non-adjacent CH₂-groups are optionally substituted by R²C═CR², C≡C, Si(R²)₂, Ge(R²)₂, Sn(R²)₂, C═O, C═S, C═Se, C═NR², P(═O)(R²), SO, SO₂, NR², O, S or CONR²;
C₁-C₄₀-thioalkoxy,
which is optionally substituted with one or more substituents R² and
wherein one or more non-adjacent CH₂-groups are optionally substituted by R²C═CR², C≡C, Si(R²)₂, Ge(R²)₂, Sn(R²)₂, C═O, C═S, C═Se, C═NR², P(═O)(R²), SO, SO₂, NR², O, S or CONR²;
C₂-C₄₀-alkenyl,
which is optionally substituted with one or more substituents R² and
wherein one or more non-adjacent CH₂-groups are optionally substituted by R²C═CR², C≡C, Si(R²)₂, Ge(R²)₂, Sn(R²)₂, C═O, C═S, C═Se, C═NR², P(═O)(R²), SO, SO₂, NR², O, S or CONR²;
C₂-C₄₀-alkynyl,
which is optionally substituted with one or more substituents R² and
wherein one or more non-adjacent CH₂-groups are optionally substituted by R²C═CR², C≡C, Si(R²)₂, Ge(R²)₂, Sn(R²)₂, C═O, C═S, C═Se, C═NR², P(═O)(R²), SO, SO₂, NR², O, S or CONR²;
C₆-C₆₀-aryl,
which is optionally substituted with one or more substituents R²
C₃-C₅₇-heteroaryl,
which is optionally substituted with one or more substituents R²
and aliphatic, cyclic amines with 4 to 18 carbon atoms and 1 to 3 nitrogen atoms;
wherein two or more adjacent substituents R¹ optionally form an aliphatic or aromatic carbocyclic or heterocyclic ring system which is fused to the adjacent ring A, B, C, D, E or F and is optionally substituted with one or more substituents R²; wherein the formed fused ring system has 8 to 30 ring atoms, of which, in case of a fused heterocyclic ring system, 1 to 5 ring atoms are independently selected from the group consisting of N, O, S, and Se;
Y¹ and Y² are at each occurrence independently selected from the group consisting of NR³, O, S, and Se;
R³ is at each occurrence independently selected from the group consisting of: hydrogen, deuterium,
C₁-C₄₀-alkyl,
which is optionally substituted with one or more substituents R⁴ and
wherein one or more non-adjacent CH₂-groups are optionally substituted by R⁴C═CR⁴, C≡C, Si(R⁴)₂, Ge(R⁴)₂, Sn(R⁴)₂, C═O, C═S, C═Se, C═NR⁴, P(═O)(R⁴), SO, SO₂, NR⁴, O, S or CONR⁴;
C₁-C₄₀-alkoxy,
which is optionally substituted with one or more substituents R⁴ and
wherein one or more non-adjacent CH₂-groups are optionally substituted by R⁴C═CR⁴, C≡C, Si(R⁴)₂, Ge(R⁴)₂, Sn(R⁴)₂, C═O, C═S, C═Se, C═NR⁴, P(═O)(R⁴), SO, SO₂, NR⁴, O, S or CONR⁴;
C₁-C₄₀-thioalkoxy,
which is optionally substituted with one or more substituents R⁴ and
wherein one or more non-adjacent CH₂-groups are optionally substituted by R⁴C═CR⁴, C≡C, Si(R⁴)₂, Ge(R⁴)₂, Sn(R⁴)₂, C═O, C═S, C═Se, C═NR⁴, P(═O)(R⁴), SO, SO₂, NR⁴, O, S or CONR⁴;
C₂-C₄₀-alkenyl,
which is optionally substituted with one or more substituents R⁴ and
wherein one or more non-adjacent CH₂-groups are optionally substituted by R⁴C═CR⁴, C≡C, Si(R⁴)₂, Ge(R⁴)₂, Sn(R⁴)₂, C═O, C═S, C═Se, C═NR⁴, P(═O)(R⁴), SO, SO₂, NR⁴, O, S or CONR⁴;
C₂-C₄₀-alkynyl,
which is optionally substituted with one or more substituents R⁴ and
wherein one or more non-adjacent CH₂-groups are optionally substituted by R⁴C═CR⁴, C≡C, Si(R⁴)₂, Ge(R⁴)₂, Sn(R⁴)₂, C═O, C═S, C═Se, C═NR⁴, P(═O)(R⁴), SO, SO₂, NR⁴, O, S or CONR⁴;
C₆-C₁₈-aryl,
which is optionally substituted with one or more substituents R¹; and
C₃-C₁₈-heteroaryl,
which is optionally substituted with one or more substituents R¹;
R² and R⁴ are at each occurrence independently selected from the group consisting of: hydrogen, deuterium, OPh, SPh, CF₃, CN, F, Si(C₁-C₅-alkyl)₃, Si(Ph)₃,
C₁-C₅-alkyl,
wherein optionally one or more hydrogen atoms are independently substituted by deuterium, Ph, CN, CF₃, or F;
C₁-C₅-alkoxy,
wherein optionally one or more hydrogen atoms are independently substituted by deuterium, CN, CF₃, or F;
C₁-C₅-thioalkoxy,
wherein optionally one or more hydrogen atoms are independently substituted by deuterium, CN, CF₃, or F;
C₂-C₅-alkenyl,
wherein optionally one or more hydrogen atoms are independently substituted by deuterium, CN, CF₃, or F;
C₂-C₅-alkynyl,
wherein optionally one or more hydrogen atoms are independently substituted by deuterium, CN, CF₃, or F;
C₆-C₁₈-aryl,
wherein optionally one or more hydrogen atoms are independently substituted by deuterium, CN, CF₃, F, C₁-C₅-alkyl, SiMe₃, SiPh₃ or C₆-C₁₈-aryl substituents;
C₃-C₁₇-heteroaryl,
wherein optionally one or more hydrogen atoms are independently substituted by deuterium, CN, CF₃, F, C₁-C₅-alkyl, SiMe₃, SiPh₃ or C₆-C₁₈-aryl substituents;
N(C₆-C₁₈-aryl)₂,
N(C₃-C₁₇-heteroaryl)₂; and
N(C₃-C₁₇-heteroaryl)(C₆-C₁₈-aryl);
wherein, if Y¹ or Y² is NR³, a substituent R³ optionally and independently bonds to:
ring A and/or ring B, if Y¹═NR³ or
ring C and/or ring D, if Y²═NR³
with the provision that the connecting atom or atom group linking R³ to another ring is in each case independently selected from Se and NR^{Y};
wherein R^{Y} is at each occurrence independently selected from the group consisting of: hydrogen, deuterium,
C₁-C₅-alkyl,
wherein optionally one or more hydrogen atoms are independently substituted by deuterium, Ph, CN, CF₃, or F;
C₆-C₁₈-aryl,
wherein optionally one or more hydrogen atoms are independently substituted by deuterium, C₁-C₅-alkyl, SiMe₃, SiPh₃, CN, CF₃, F or C₆-C₁₈-aryl substituents;
C₃-C₁₇-heteroaryl,
wherein optionally one or more hydrogen atoms are independently substituted by deuterium, C₁-C₅-alkyl, SiMe₃, SiPh₃, CN, CF₃, F or C₆-C₁₈-aryl substituents; and
wherein at least one ring from the group consisting of ring A, ring B, ring C, ring D, ring E, and ring F is a heteroaromatic ring.

2. The organic molecule according to claim 1, wherein R¹ is independently selected from the group consisting of: hydrogen, deuterium, OPh, SPh, CF₃, CN, F, Si(C₁-C₅-alkyl)₃, Si(Ph)₃, pyrrolidinyl, piperidinyl,
C₁-C₅-alkyl,
wherein optionally one or more hydrogen atoms are independently substituted by deuterium, Ph, CN, CF₃, or F;
C₁-C₅-alkoxy,
wherein optionally one or more hydrogen atoms are independently substituted by deuterium, CN, CF₃, or F;
C₁-C₅-thioalkoxy,
wherein optionally one or more hydrogen atoms are independently substituted by deuterium, CN, CF₃, or F;
C₂-C₅-alkenyl,
wherein optionally one or more hydrogen atoms are independently substituted by deuterium, CN, CF₃, or F;
C₂-C₅-alkynyl,
wherein optionally one or more hydrogen atoms are independently substituted by deuterium, CN, CF₃, or F;
C₆-C₁₈-aryl,
wherein optionally one or more hydrogen atoms are independently substituted by deuterium, CN, CF₃, F, C₁-C₅-alkyl, SiMe₃, SiPh₃ or C₆-C₁₈-aryl substituents;
C₃-C₁₇-heteroaryl,
wherein optionally one or more hydrogen atoms are independently substituted by deuterium, CN, CF₃, F, C₁-C₅-alkyl, SiMe₃, SiPh₃ or C₆-C₁₈-aryl substituents;
N(C₆-C₁₈-aryl)₂,
N(C₃-C₁₇-heteroaryl)₂; and
N(C₃-C₁₇-heteroaryl)(C₆-C₁₈-aryl);
wherein adjacent groups R¹ do not form an additional ring system;
Y¹ and Y² are both NR³;
R³ is at each occurrence independently selected from the group consisting of: hydrogen, deuterium,
C₁-C₅-alkyl,
wherein optionally one or more hydrogen atoms are independently substituted by deuterium, Ph, CN, CF₃, or F;
C₆-C₁₈-aryl,
wherein optionally one or more hydrogen atoms are independently substituted by deuterium, CN, CF₃, F, C₁-C₅-alkyl, SiMe₃, SiPh₃ or C₆-C₁₈-aryl substituents;
C₃-C₁₇-heteroaryl,
wherein optionally one or more hydrogen atoms are independently substituted by deuterium, CN, CF₃, F, C₁-C₅-alkyl, SiMe₃, SiPh₃ or C₆-C₁₈-aryl substituents;
and wherein R^{Y} is independently selected from the group consisting of: hydrogen, deuterium, Me, benzyl, ⁱPr, ^{t}Bu, and
Ph, which is optionally substituted with one or more substituents independently selected from the group consisting of deuterium, CN, CF₃, F, C₁-C₅-alkyl, SiMe₃, SiPh₃, and Ph.

3. The organic molecule according to claim 1, wherein R¹ is at each occurrence independently selected from the group consisting of: hydrogen, deuterium, Me, benzyl, ⁱPr, ^{t}Bu, CN, CF₃, N(Ph)₂,
Ph, which is optionally substituted with one or more substituents independently selected from the group consisting of deuterium, Me, ⁱPr, ^{t}Bu, CN, CF₃, and Ph; and
carbazolyl, which is optionally substituted with one or more substituents independently selected from the group consisting of deuterium and Ph;
wherein adjacent groups R¹ do not form an additional ring system;
wherein Y¹ and Y² are both NR³;
wherein R³ is at each occurrence independently selected from the group consisting of: hydrogen, deuterium, Me, benzyl, ⁱPr, ^{t}Bu, and
Ph, which is optionally substituted with one or more substituents independently selected from the group consisting of deuterium, Me, ⁱPr, ^{t}Bu, CN, CF₃, and Ph;
and wherein R^{Y} is at each occurrence independently selected from the group consisting of hydrogen, deuterium, Me, benzyl, ⁱPr, ^{t}Bu; and
Ph, which is optionally substituted with one or more substituents independently selected from deuterium, CN, CF₃, Me, ⁱPr, ^{t}Bu, and Ph.

4. The organic molecule according to claim 1, comprising a structure of formula II or formula III: 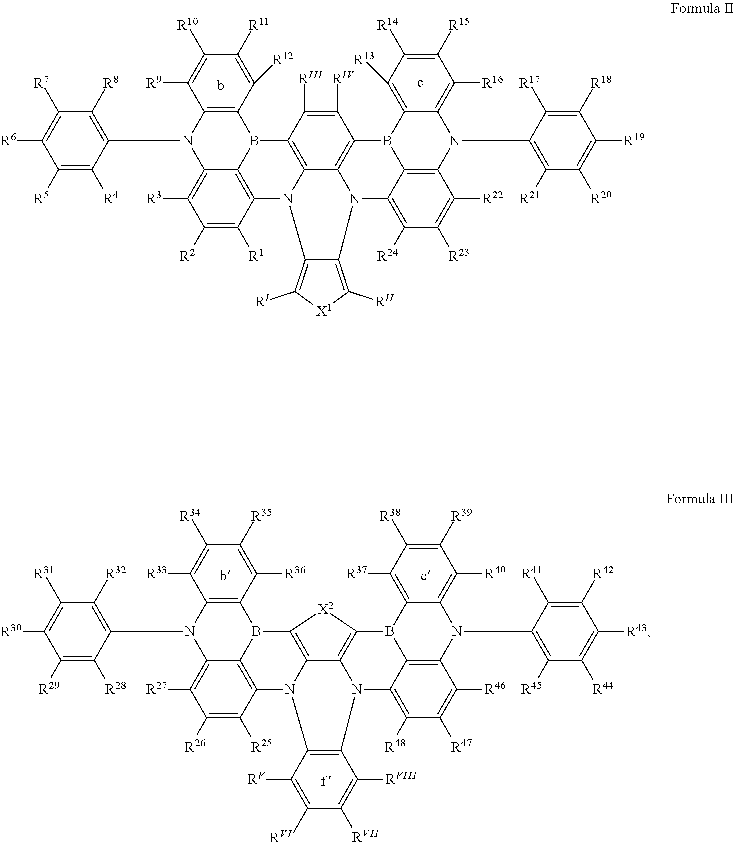
wherein
X¹ and X² are selected from the group consisting of O, S, and Se;
R^{I}-R^{VIII} and R¹-R⁴⁸ are independently selected from the group consisting of:
hydrogen, deuterium, N(R⁴⁹)₂, OR⁴⁹, SR⁴⁹, Si(R⁴⁹)₃, B(OR⁴⁹)₂, OSO₂R⁴⁹, CF₃, CN, F, Cl, Br, I,
C₁-C₄₀-alkyl,
which is optionally substituted with one or more substituents R⁴⁹ and
wherein one or more non-adjacent CH₂-groups are optionally substituted by R⁴⁹C═CR⁴⁹, C≡C, Si(R⁴⁹)₂, Ge(R⁴⁹)₂, Sn(R⁴⁹)₂, C═O, C═S, C═Se, C═NR⁴⁹, P(═O)(R⁴⁹), SO, SO₂, NR⁴⁹, O, S or CONR⁴⁹;
C₁-C₄₀-alkoxy,
which is optionally substituted with one or more substituents R⁴⁹ and
wherein one or more non-adjacent CH₂-groups are optionally substituted by R⁴⁹C═CR⁴⁹, C≡C, Si(R⁴⁹)₂, Ge(R⁴⁹)₂, Sn(R⁴⁹)₂, C═O, C═S, C═Se, C═NR⁴⁹, P(═O)(R⁴⁹), SO, SO₂, NR⁴⁹, O, S or CONR⁴⁹;
C₁-C₄₀-thioalkoxy,
which is optionally substituted with one or more substituents R⁴⁹ and
wherein one or more non-adjacent CH₂-groups are optionally substituted by R⁴⁹C═CR⁴⁹, C≡C, Si(R⁴⁹)₂, Ge(R⁴⁹)₂, Sn(R⁴⁹)₂, C═O, C═S, C═Se, C═NR⁴⁹, P(═O)(R⁴⁹), SO, SO₂, NR⁴⁹, O, S or CONR⁴⁹;
C₂-C₄₀-alkenyl,
which is optionally substituted with one or more substituents R⁴⁹ and
wherein one or more non-adjacent CH₂-groups are optionally substituted by R⁴⁹C═CR⁴⁹, C≡C, Si(R⁴⁹)₂, Ge(R⁴⁹)₂, Sn(R⁴⁹)₂, C═O, C═S, C═Se, C═NR⁴⁹, P(═O)(R⁴⁹), SO, SO₂, NR⁴⁹, O, S or CONR⁴⁹;
C₂-C₄₀-alkynyl,
which is optionally substituted with one or more substituents R⁴⁹ and
wherein one or more non-adjacent CH₂-groups are optionally substituted by R⁴⁹C═CR⁴⁹, C≡C, Si(R⁴⁹)₂, Ge(R⁴⁹)₂, Sn(R⁴⁹)₂, C═O, C═S, C═Se, C═NR⁴⁹, P(═O)(R⁴⁹), SO, SO₂, NR⁴⁹, O, S or CONR⁴⁹;
C₆-C₆₀-aryl,
which is optionally substituted with one or more substituents R⁴⁹; and
C₃-C₅₇-heteroaryl,
which is optionally substituted with one or more substituents R⁴⁹;
and an aliphatic, cyclic amine with 4 to 18 carbon atoms and 1 to 3 nitrogen atoms;
wherein one or both pairs of adjacent substituents R¹⁰ and R¹¹ as well as R¹⁴ and R¹⁵ optionally form an aromatic or heteroaromatic ring system, which is fused to the adjacent benzene ring b or c and is optionally substituted with one or more substituents R⁴⁹; wherein the formed fused ring system has 8 to 24 ring atoms of which, in case of a fused heterocyclic ring system, 1 to 3 ring atoms are independently selected from the group consisting of N, O, S, and Se;
wherein one or both pairs of adjacent substituents R³⁴ and R³⁵ as well as R³⁸ and R³⁹ optionally form an aromatic or heteroaromatic ring system, which is fused to the adjacent benzene ring b′ or c′ and is optionally substituted with one or more substituents R⁴⁹; wherein the formed fused ring system has 8 to 24 ring atoms of which, in case of a fused heterocyclic ring system, 1 to 3 ring atoms are independently selected from group consisting of N, O, S, and Se;
wherein one or more pair of adjacent substituents R^{V} and R^{VI}, R^{VI} and R^{VII} as well as R^{VII} and R^{VIII} optionally form an aromatic ring system, which is fused to the adjacent benzene ring f′ and is optionally substituted with one or more substituents R⁴⁹; wherein the formed fused ring system has 8 to 24 ring atoms;
R⁴⁹ is at each occurrence independently selected from the group consisting of: hydrogen, deuterium, OPh, SPh, CF₃, CN, F, Si(C₁-C₅-alkyl)₃, Si(Ph)₃,
C₁-C₅-alkyl,
wherein optionally one or more hydrogen atoms are independently substituted by deuterium, Ph, CN, CF₃, or F;
C₁-C₅-alkoxy,
wherein optionally one or more hydrogen atoms are independently substituted by deuterium, CN, CF₃, or F;
C₁-C₅-thioalkoxy,
wherein optionally one or more hydrogen atoms are independently substituted by deuterium, CN, CF₃, or F;
C₂-C₅-alkenyl,
wherein optionally one or more hydrogen atoms are independently substituted by deuterium, CN, CF₃, or F;
C₂-C₅-alkynyl,
wherein optionally one or more hydrogen atoms are independently substituted by deuterium, CN, CF₃, or F;
C₆-C₁₈-aryl,
wherein optionally one or more hydrogen atoms are independently substituted by deuterium, CN, CF₃, F, C₁-C₅-alkyl, SiMe₃, SiPh₃ or C₆-C₁₈-aryl substituents;
C₃-C₁₇-heteroaryl,
wherein optionally one or more hydrogen atoms are independently substituted by deuterium, CN, CF₃, F, C₁-C₅-alkyl, SiMe₃, SiPh₃ or C₆-C₁₈-aryl substituents;
N(C₆-C₁₈-aryl)₂,
N(C₃-C₁₇-heteroaryl)₂; and
N(C₃-C₁₇-heteroaryl)(C₆-C₁₈-aryl);
wherein one or more pairs selected from R³ and R⁴, R⁸ and R⁹, R¹⁶ and R¹⁷, R²¹ and R²² optionally form a group Z¹, which is at each occurrence independently selected from selenium (Se) and NR^{X};
wherein one or more pairs selected from R²⁷ and R²⁸, R³² and R³³, R⁴⁰ and R⁴¹, R⁴⁵ and R⁴⁶ optionally form a group Z², which is at each occurrence independently selected from selenium (Se) and NR^{X};
wherein R^{X} is at each occurrence independently selected from the group consisting of: hydrogen, deuterium,
C₁-C₅-alkyl,
wherein optionally one or more hydrogen atoms are independently substituted by deuterium, Ph, CN, CF₃, or F;
C₆-C₁₈-aryl,
wherein optionally one or more hydrogen atoms are independently substituted by deuterium, CN, CF₃, F, C₁-C₅-alkyl, SiMe₃, SiPh₃ or C₆-C₁₈-aryl substituents;
C₃-C₁₇-heteroaryl,
wherein optionally one or more hydrogen atoms are independently substituted by deuterium, CN, CF₃, F, C₁-C₅-alkyl, SiMe₃, SiPh₃ or C₆-C₁₈-aryl substituents.

5. The organic molecule according to claim 4, wherein:
R^{I} and R^{II} are independently selected from the group consisting of: Me, ⁱPr, ^{t}Bu, CN, CF₃, and
Ph, wherein optionally one or more hydrogen atoms are independently substituted by deuterium, Me, ⁱPr, ^{t}Bu, CN, or CF₃;
R^{III}-R^{VIII} and R¹-R⁴⁸ are independently selected from the group consisting of:
hydrogen, deuterium, Me, benzyl, ⁱPr, ^{t}Bu, CF₃, CN, F, SiMe₃, Si(Ph)₃, N(Ph)₂, pyrrolidinyl, piperidinyl,
Ph, wherein optionally one or more hydrogen atoms are independently substituted by deuterium, CN, CF₃, Me, ⁱPr, ^{t}Bu or Ph substituents;
carbazolyl, wherein optionally one or more hydrogen atoms are independently substituted by deuterium, CN, CF₃, Me, ⁱPr, ^{t}Bu, or Ph substituents;
wherein one or both pairs of adjacent substituents R¹⁰ and R¹¹ as well as R¹⁴ and R¹⁵ optionally form an aromatic ring system, which is fused to the adjacent benzene ring b or ring c and is optionally substituted with one or more substituents independently selected from the group consisting of: hydrogen, deuterium, Me, ⁱPr, ^{t}Bu, CN, CF₃, and Ph, wherein the so formed fused ring system has 8 to 24 ring atoms;
wherein one or both pairs of adjacent substituents R³⁴ and R³⁵ as well as R³⁸ and R³⁹ in formula III optionally form an aromatic system, which is fused to the adjacent benzene ring b′ or c′ and optionally substituted with one or more substituents independently selected from the group consisting of: hydrogen, deuterium, Me, ⁱPr, ^{t}Bu, CN, CF₃, and Ph, wherein the so formed fused ring system has 8 to 24 ring atoms;
wherein one or more pairs of adjacent substituents R^{V} and R^{VI}, R^{VI} and R^{VII} as well as R^{VII} and R^{VIII} optionally form an aromatic ring system which is fused to the adjacent benzene ring f′ of formula III and optionally substituted with one or more substituents independently selected from the group consisting of: hydrogen, deuterium, Me, ⁱPr, ^{t}Bu, CN, CF₃, and Ph, wherein the so formed fused ring system has 8 to 24 ring atoms;
wherein one or more pairs selected from R³ and R⁴, R⁸ and R⁹, R¹⁶ and R¹⁷, R²¹ and R²² optionally form a group Z¹, which is selected from Se and NR^{X}, with the provision that all optionally so formed groups Z¹ are identical;
wherein one or more pairs selected from R²⁷ and R²⁸, R³² and R³³, R⁴⁰ and R⁴¹, R⁴⁵ and R⁴⁶ optionally form a group Z², which is selected from Se and NR^{X}, with the provision that all optionally so formed groups Z² are identical;
wherein R^{X} is selected from the group consisting of: hydrogen, deuterium, Me, benzyl, ⁱPr, ^{t}Bu, and
Ph, wherein optionally one or more hydrogen atoms are independently substituted by deuterium, Me, ⁱPr, ^{t}Bu, or Ph substituents.

6. The organic molecule according to claim 4, wherein
R^{I} and R^{II} are independently selected from the group consisting of: Me, ⁱPr, ^{t}Bu, and
Ph, wherein optionally one or more hydrogen atoms are independently substituted by deuterium, Me, ⁱPr, ^{t}Bu, and Ph;
R^{III}-R^{VIII} and R¹-R⁴⁸ are independently selected from the group consisting of: hydrogen, deuterium, Me, ⁱPr, ^{t}Bu, CN, CF₃, N(Ph)₂, and
Ph, wherein optionally one or more hydrogen atoms are independently substituted by deuterium, Me, ⁱPr, ^{t}Bu or Ph substituents;
wherein one or both pairs of adjacent substituents R¹⁰ and R¹¹ as well as R¹⁴ and R¹⁵ optionally form an aromatic ring system, which is fused to the adjacent benzene ring b or ring c of formula II and optionally substituted with one or more substituents independently selected from the group consisting of: hydrogen, deuterium, Me, ⁱPr, ^{t}Bu, CN, CF₃, and Ph, wherein the formed fused ring system has 8 to 24 ring atoms;
wherein one or both pairs of adjacent substituents R³⁴ and R³⁵ as well as R³⁸ and R³⁹ in formula III optionally form an aromatic system, which is fused to the adjacent benzene ring b′ or ring c′ and optionally substituted with one or more substituents independently selected from the group consisting of: hydrogen, deuterium, Me, ⁱPr, ^{t}Bu, CN, CF₃, and Ph, wherein the formed fused ring system has 8 to 24 ring atoms;
wherein one or more pairs of adjacent substituents R^{V} and R^{VI}, R^{VI} and R^{VII} as well as R^{VII} and R^{VIII} in formula III optionally form an aromatic ring system which is fused to the adjacent benzene ring f′ of formula III and optionally substituted with one or more substituents independently selected from the group consisting of: hydrogen, deuterium, Me, ⁱPr, ^{t}Bu, CN, CF₃, and Ph, wherein the formed fused ring system has 8 to 24 ring atoms;
wherein one or more pairs selected from R³ and R⁴, R⁸ and R⁹, R¹⁶ and R¹⁷, R²¹ and R²² optionally form a group Z¹, which is selected from selenium (Se) and NR^{X}, with the provision that all formed groups Z¹ are identical;
wherein one or more pairs selected from R²⁷ and R²⁸, R³² and R³³, R⁴⁰ and R⁴¹, R⁴⁵ and R⁴⁶ optionally form a group Z², which is selected from selenium (Se) and NR^{X}, with the provision that all formed groups Z² are identical;
wherein R^{X} is selected from the group consisting of: hydrogen, deuterium, Me, ⁱPr, ^{t}Bu, and
Ph, wherein optionally one or more hydrogen atoms are independently substituted by deuterium, Me, ⁱPr, ^{t}Bu or Ph substituents.

7. The organic molecule according to claim 4, the organic molecule comprising a structure according to any of formulas II-a, II-b, II-c, II-d, II-e, II-f, II-g, II-h, III-a, III-b, III-c, III-d, III-e, III-f, III-g, and III-h:

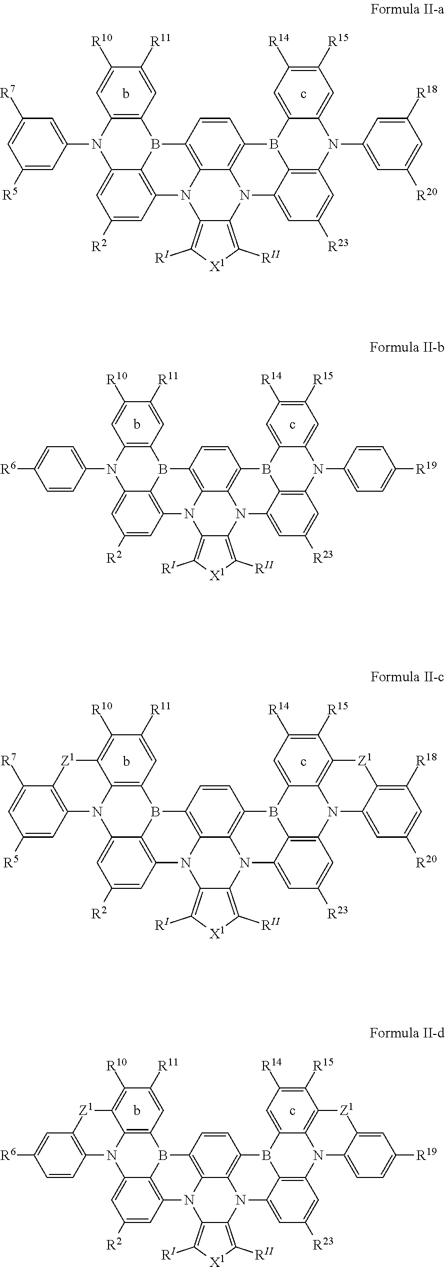

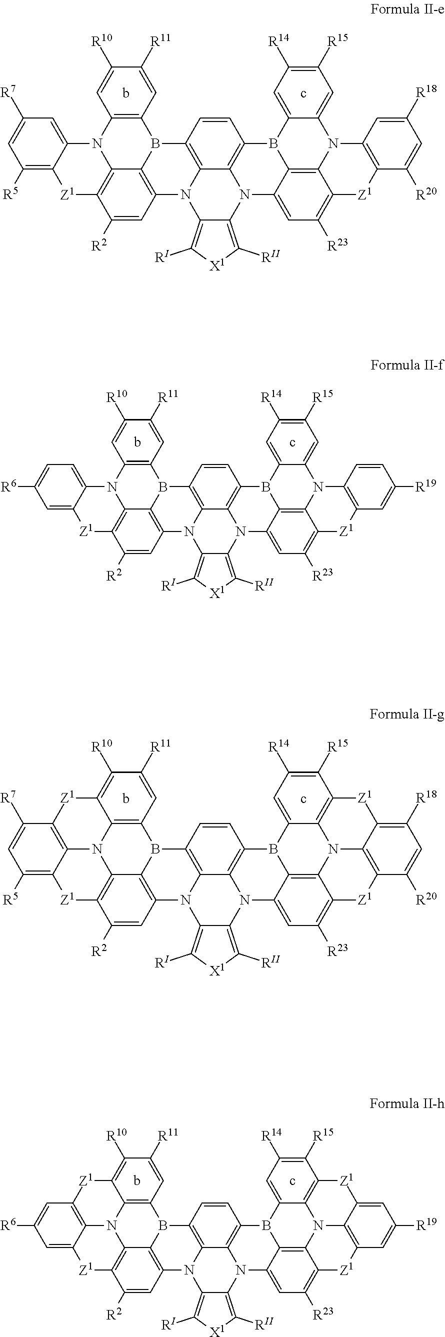

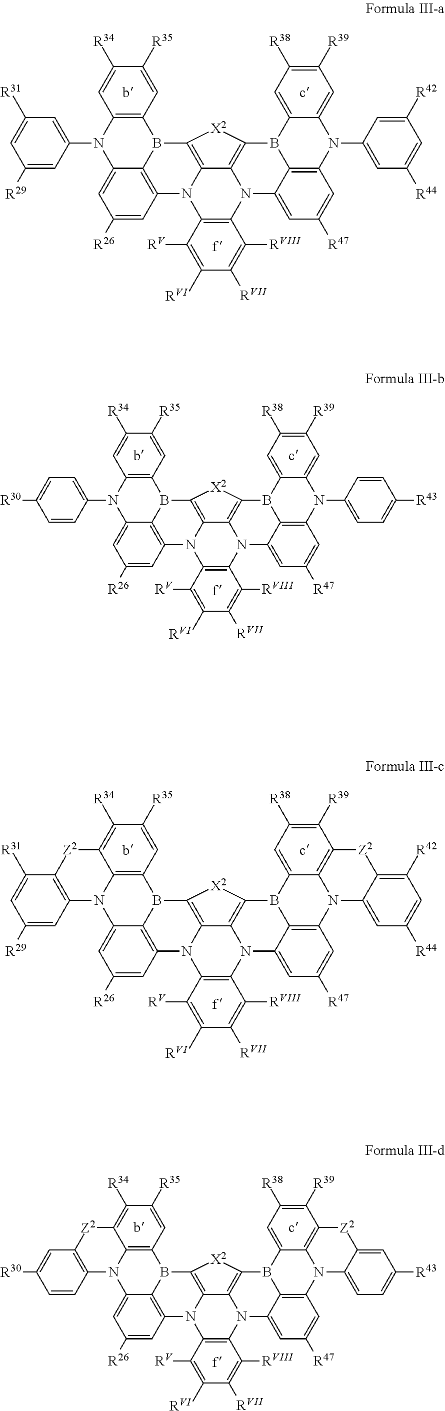

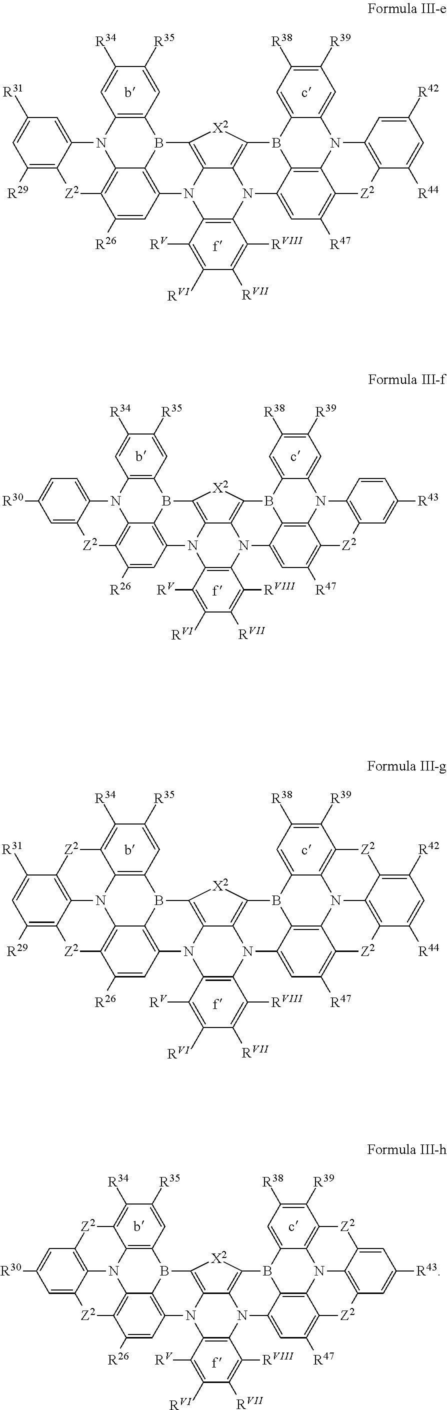

8. The organic molecule according to claim 4, wherein X¹ and X² are Se.

9.-10. (canceled)

11. A composition, comprising:
(a) an organic molecule according to claim 1 in the form of an emitter and/or a host, and
(b) an emitter and/or a host material, which differs from the organic molecule, and
(c) optionally, a dye and/or a solvent.

12. An optoelectronic device, comprising an organic molecule according to claim 1.

13. The optoelectronic device according to claim 12 in the form of a device selected from the group consisting of organic light-emitting diode (OLED), light-emitting electrochemical cell, OLED-sensor, organic diode, organic solar cell, organic transistor, organic field-effect transistor, organic laser, and down-conversion element.

14. The optoelectronic device according to claim 12, comprising:
a substrate,
an anode, and
a cathode, wherein the anode or the cathode is on the substrate, and
a light-emitting layer, which is between the anode and the cathode and which comprises the organic molecule or the composition.

15. A method for producing an optoelectronic device, wherein an organic molecule according to claim 1 is used, the method comprising the processing of the organic molecule by a vacuum evaporation method or from a solution.
